(19) United States
(12) Patent Application Publication
(10) Pub. No.: US 2026/0333727 A1
(43) Pub. Date: Oct. 22, 2026

(54) SEMICONDUCTOR DEVICE AND POWER CONVERSION APPARATUS

(71) Applicant: Mitsubishi Electric Corporation, Tokyo (JP)

(72) Inventors: Tetsuya HIGASHI, Tokyo (JP); Kazuya KONISHI, Tokyo (JP); Shinya SONEDA, Tokyo (JP); Kosuke SAKAGUCHI, Tokyo (JP)

(73) Assignee: Mitsubishi Electric Corporation, Tokyo (JP)

(21) Appl. No.: 19/650,999

(22) Filed: Apr. 17, 2026

(30) Foreign Application Priority Data
Apr. 22, 2025 (JP) 2025-070490
Mar. 23, 2026 (JP) 2026-047163

(51) Int. Cl. H10D 12/00; H02M 1/08; H02P 27/08; H03K 17/567; H10D 62/10; H10D 64/00; H10D 84/00

(52) U.S. Cl. CPC H10D 12/481; H10D 12/415; H10D 62/107; H10D 62/109; H10D 62/127; H10D 64/117; H10D 84/161; H02M 1/08; H02P 27/08; H03K 17/567

(57) ABSTRACT

In a case where a position of a lower end of a base layer is defined as a position E1 and a position of a lower end of a recess portion is defined as a position E2, in a case where a distance from a first main surface to the position E1 is defined as a distance E1d and a distance from the first main surface to the position E2 is defined as a distance E2d, in a case where an area of a p-type base layer in a range from a lower end of a third semiconductor layer to the position E1 is defined as an area S1, and in a case where an area of the recess portion of a gate trench electrode formed in a region of the area S1 is defined as an area S2, a gate capacitance ratio is linearly controlled by changing the area S2.

### BACKGROUND

### Technical Field

The present disclosure relates to a semiconductor device, and particularly to a semiconductor device including a trench gate.

### Description of the Background Art

A typical example of a semiconductor device including a trench gate is an insulated gate bipolar transistor (IGBT).

An IGBT basically has a configuration in which a trench is provided in a main surface of a semiconductor substrate, an inner surface of the trench is covered with a gate insulating film, and a plurality of trench gates obtained by embedding gate electrodes are provided in the trench of which the inner surface is covered with the gate insulating film.

On the other hand, in an IGBT disclosed in Japanese Patent Application Laid-Open No. 2022-78755, there is disclosed a configuration in which, in addition to the trench gate (active trench) described above, a two-stage dummy active trench is provided inside the trench of which the inner surface is covered with a gate insulating film, the two-stage dummy active trench including an upper dummy portion which is not connected to the gate electrode in an upper stage and a lower active portion which is connected to the gate electrode in a lower stage.

By adopting such a configuration, gate-collector capacitance (feedback capacitance) Cgc between a gate and a collector of the IGBT is increased. The reason for increasing the feedback capacitance Cgc is to reduce a turn-on loss under a condition in which dV/dt, which is a variation of a drain voltage V with respect to time t, is constant, and to increase a gate capacitance ratio Cgc/Cge, which is defined as a capacitance ratio of the feedback capacitance Cgc to gate-emitter capacitance Cge.

In the technique in the related art that is described in Japanese Patent Application Laid-Open No. 2022-78755, since Cgc/Cge is determined by an arrangement ratio of the two-stage dummy active trench and the active trench, controllability of Cgc/Cge is poor, and different dV/dt is required for each product. For this reason, for example, in a case where Cge is set to be too low, there is a problem that it is difficult to perform optimum design that achieves both avoidance of erroneous firing due to dV/dt during reverse recovery of a free wheeling diode (FWD) and noise reduction.

### SUMMARY

An object of the present disclosure is to provide a semiconductor device capable of achieving both avoidance of erroneous firing and noise reduction.

According to the present disclosure, there is provided a semiconductor device in which a transistor is formed on a semiconductor substrate having a first main surface and a second main surface, the semiconductor device including: a first main electrode that is electrically connected to the first main surface; a second main electrode that is electrically connected to the second main surface; a first semiconductor layer that has a first conductivity type; a second semiconductor layer that has a second conductivity type and is provided on an upper layer portion of the first semiconductor layer; a plurality of third semiconductor layers that have a first conductivity type, are selectively provided on an upper layer portion of the second semiconductor layer, and are electrically connected to the first main electrode; and a plurality of trench gates that are provided so as to penetrate the third semiconductor layer and the second semiconductor layer from the first main surface in a thickness direction and reach into the first semiconductor layer, in which the trench gate includes a gate trench insulating film that covers an inner surface of a trench, a gate trench electrode that is provided in the trench via the gate trench insulating film, and an upper insulating film that covers the gate trench electrode, the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode, an upper end of the protrusion portion is located at a position higher than a lower end of the third semiconductor layer, a lower end of the recess portion is located at a position lower than the lower end of the third semiconductor layer, in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where a size relationship between the distance E1d and the distance E2d corresponds to a predetermined case, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2, a gate capacitance ratio is linearly controlled by changing the area S2.

According to the semiconductor device according to the present disclosure, it is possible to obtain a semiconductor device capable of achieving both avoidance of erroneous firing during reverse recovery of a free wheeling diode and noise reduction.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIGS. 1 and 2 are plan views each illustrating a semiconductor device that is an RC-IGBT;

FIG. 3 is a partial plan view of an IGBT region in an RC-IGBT;

FIGS. 4 and 5 are each a partial cross-sectional view of an IGBT region in an RC-IGBT;

FIG. 6 is a partial plan view of a diode region in an RC-IGBT;

FIGS. 7 and 8 are each a partial cross-sectional view of a diode region in an RC-IGBT;

FIG. 9 is a cross-sectional view of a boundary portion between an IGBT region and a diode region of an RC-IGBT;

FIGS. 10 and 11 are each a cross-sectional view of a boundary portion between an IGBT region and a termination region of an RC-IGBT;

FIG. 12 is a partially-enlarged plan view illustrating a configuration of an IGBT region of a semiconductor device that is an RC-IGBT;

FIGS. 13 and 14 are cross-sectional views each illustrating a configuration of an IGBT region of a semiconductor device that is an RC-IGBT;

FIGS. 15 and 16 are cross-sectional perspective views each illustrating a configuration of an RC-IGBT according to a first preferred embodiment;

FIGS. 17 and 18 are diagrams each illustrating an effect according to the first preferred embodiment;

FIG. 19 is a cross-sectional perspective view illustrating a configuration of an RC-IGBT according to a second preferred embodiment;

FIG. 20 is a diagram illustrating an effect according to the second preferred embodiment;

FIG. 21 is a cross-sectional perspective view illustrating a configuration of an RC-IGBT according to a third preferred embodiment;

FIG. 22 is a cross-sectional perspective view illustrating a configuration of an RC-IGBT according to a fourth preferred embodiment;

FIG. 23 is a cross-sectional perspective view illustrating a configuration of an RC-IGBT according to a fifth preferred embodiment;

FIG. 24 is a cross-sectional perspective view illustrating a configuration of an RC-IGBT according to a sixth preferred embodiment;

FIG. 25 is a cross-sectional perspective view illustrating a configuration of an RC-IGBT according to a seventh preferred embodiment;

FIG. 26 is a cross-sectional perspective view illustrating a configuration of an RC-IGBT according to an eighth preferred embodiment;

FIG. 27 is a cross-sectional perspective view illustrating a configuration of an RC-IGBT according to a ninth preferred embodiment;

FIG. 28 is a cross-sectional perspective view illustrating a configuration of an RC-IGBT according to a tenth preferred embodiment;

FIG. 29 is a cross-sectional perspective view illustrating a configuration of an RC-IGBT according to an eleventh preferred embodiment;

FIG. 30 is a cross-sectional perspective view illustrating a configuration of an RC-IGBT according to a twelfth preferred embodiment;

FIG. 31 is a cross-sectional perspective view illustrating a configuration of an RC-IGBT according to a thirteenth preferred embodiment;

FIG. 32 is a circuit diagram of a circuit that supplies a gate potential and a control gate potential to an RC-IGBT according to the thirteenth preferred embodiment;

FIG. 33 is a cross-sectional perspective view illustrating a configuration of an RC-IGBT according to a fourteenth preferred embodiment;

FIG. 34 is a cross-sectional perspective view illustrating a configuration of an RC-IGBT according to a fifteenth preferred embodiment;

FIG. 35 is a cross-sectional perspective view illustrating a configuration of an RC-IGBT according to a sixteenth preferred embodiment;

FIG. 36 is a diagram illustrating an effect according to the sixteenth preferred embodiment;

FIGS. 37 and 38 are cross-sectional perspective views each illustrating a configuration of an RC-IGBT according to a seventeenth preferred embodiment;

FIGS. 39 and 40 are cross-sectional perspective views each illustrating a configuration of an RC-IGBT according to an eighteenth preferred embodiment;

FIG. 41 is a cross-sectional perspective view illustrating a configuration of an RC-IGBT according to a nineteenth preferred embodiment;

FIG. 42 is a cross-sectional perspective view illustrating a configuration of an RC-IGBT according to a twentieth preferred embodiment;

FIG. 43 is a cross-sectional perspective view illustrating a configuration of an RC-IGBT according to a twenty-first preferred embodiment;

FIG. 44 is a cross-sectional perspective view illustrating a configuration of an RC-IGBT according to a twenty-second preferred embodiment;

FIG. 45 is a cross-sectional perspective view illustrating a configuration of an RC-IGBT according to a twenty-third preferred embodiment;

FIG. 46 is a cross-sectional perspective view illustrating a configuration of an RC-IGBT according to a twenty-fourth preferred embodiment;

FIG. 47 is a cross-sectional perspective view illustrating a configuration of an RC-IGBT according to a twenty-fifth preferred embodiment;

FIG. 48 is a cross-sectional perspective view illustrating a configuration of an RC-IGBT according to a twenty-sixth preferred embodiment;

FIG. 49 is a cross-sectional perspective view illustrating a configuration of an RC-IGBT according to a twenty-seventh preferred embodiment;

FIG. 50 is a cross-sectional perspective view illustrating a configuration of an RC-IGBT according to a twenty-eighth preferred embodiment;

FIG. 51 is a cross-sectional perspective view illustrating a configuration of an RC-IGBT according to a twenty-ninth preferred embodiment;

FIG. 52 is a cross-sectional perspective view illustrating a configuration of an RC-IGBT according to a thirtieth preferred embodiment;

FIG. 53 is a cross-sectional perspective view illustrating a configuration of an RC-IGBT according to a thirty-first preferred embodiment;

FIG. 54 is a cross-sectional perspective view illustrating a configuration of an RC-IGBT according to a thirty-second preferred embodiment;

FIG. 55 is a cross-sectional perspective view illustrating a configuration of an RC-IGBT according to a thirty-third preferred embodiment;

FIG. 56 is a cross-sectional perspective view illustrating a configuration of an RC-IGBT according to a thirty-fourth preferred embodiment;

FIG. 57 is a cross-sectional perspective view illustrating a configuration of an RC-IGBT according to a thirty-fifth preferred embodiment;

FIG. 58 is a cross-sectional perspective view illustrating a configuration of an RC-IGBT according to a thirty-sixth preferred embodiment;

FIGS. 59 to 62 are cross-sectional perspective views each illustrating a configuration of an RC-IGBT according to a thirty-seventh preferred embodiment;

FIG. 63 is a cross-sectional perspective view illustrating a configuration of an RC-IGBT according to a thirty-eighth preferred embodiment;

FIG. 64 is a cross-sectional perspective view illustrating a configuration of an RC-IGBT according to a thirty-ninth preferred embodiment;

FIG. 65 is a cross-sectional perspective view illustrating a configuration of an RC-IGBT according to a fortieth preferred embodiment;

FIG. 66 is a cross-sectional perspective view illustrating a configuration of an RC-IGBT according to a forty-first preferred embodiment;

FIG. 67 is a cross-sectional perspective view illustrating a configuration of an RC-IGBT according to a forty-second preferred embodiment;

FIG. 68 is a cross-sectional perspective view illustrating a configuration of an RC-IGBT according to a forty-third preferred embodiment;

FIG. 69 is a cross-sectional perspective view illustrating a configuration of an RC-IGBT according to a forty-fourth preferred embodiment;

FIG. 70 is a cross-sectional perspective view illustrating a configuration of an RC-IGBT according to a forty-fifth preferred embodiment; and

FIG. 71 is a block diagram illustrating a configuration of a power conversion system to which a power conversion apparatus according to a forty-sixth preferred embodiment is applied.

### DESCRIPTION OF THE PREFERRED EMBODIMENTS

### Introduction

In the following description, an n-type and a p-type indicate conductivity types of a semiconductor. In the present disclosure, a first conductivity type is described as the n-type, and a second conductivity type is described as the p-type. On the other hand, the first conductivity type may be the p-type, and the second conductivity type may be the n-type. In addition, an n⁻-type indicates that an impurity concentration is lower than an impurity concentration of the n-type, and an n⁺-type indicates that an impurity concentration is higher than an impurity concentration of the n-type. Similarly, a p⁻-type indicates that an impurity concentration is lower than an impurity concentration of the p-type, and a p⁺-type indicates that an impurity concentration is higher than an impurity concentration of the p-type.

In addition, the drawings are schematically illustrated, and a mutual relationship between sizes and positions of images illustrated in different drawings is not necessarily accurately described, and can be appropriately changed. Further, in the following description, similar components are denoted by the same reference numerals, and names and functions of the components are also similar. Therefore, a detailed description of the components may be omitted.

In addition, in the following description, terms meaning specific positions and directions such as “upper”, “lower”, “side”, “front”, and “back” may be used, but these terms are used for convenience to facilitate understanding of the content of preferred embodiments and are not related to directions when actually implemented.

Hereinafter, prior to a description of preferred embodiments, a reverse conducting IGBT (RC-IGBT) in which an IGBT and a free wheeling diode (FWD) are provided on a common semiconductor substrate will be described.

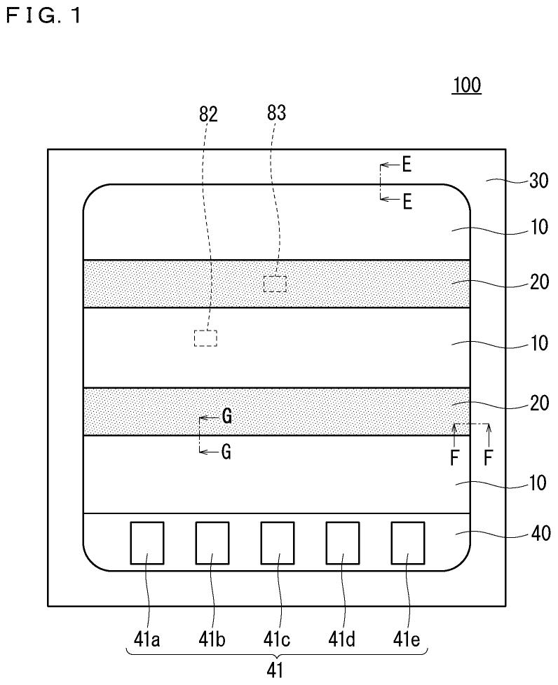

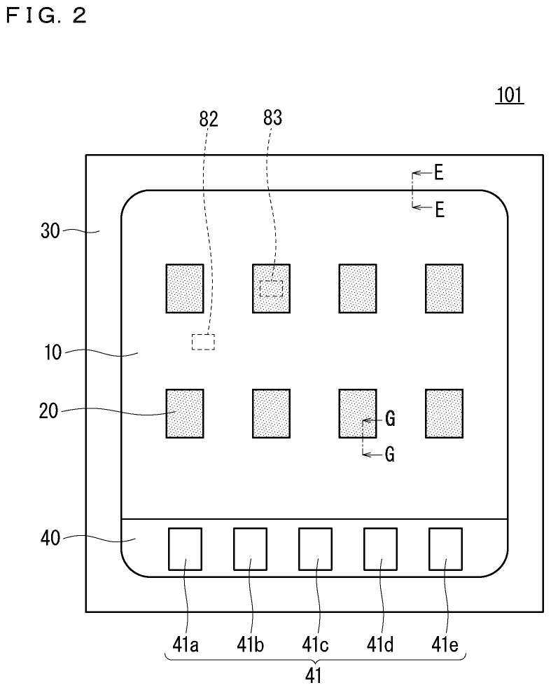

FIG. 1 is a plan view illustrating a semiconductor device that is an RC-IGBT. In addition, FIG. 2 is a plan view illustrating a semiconductor device that is an RC-IGBT having another configuration. A semiconductor device 100 illustrated in FIG. 1 includes IGBT regions 10 and diode regions 20 that are provided side by side in a stripe shape, and may be simply referred to as a “stripe type”. A semiconductor device 101 illustrated in FIG. 2 includes a plurality of diode regions 20 that are provided in a longitudinal direction and a lateral direction and an IGBT region 10 that is provided around the diode regions 20, and may be simply referred to as an “island type”.

### (1) Overall Planar Structure of Stripe Type

In FIG. 1, the semiconductor device 100 includes the IGBT regions 10 and the diode regions 20 in one semiconductor device. The IGBT region 10 and the diode region 20 extend from one end side to the other end side of the semiconductor device 100, and are alternately provided in a stripe shape in a direction orthogonal to the extending direction of the IGBT region 10 and the diode region 20. FIG. 1 illustrates a configuration in which three IGBT regions 10 and two diode regions are provided and all the diode regions 20 are sandwiched between the IGBT regions 10. However, the number of the IGBT regions 10 and the diode regions 20 is not limited thereto. The number of the IGBT regions 10 may be three or more, and three or less, and the number of the diode regions 20 may be two or more and two or less. In addition, the IGBT region 10 and the diode region 20 in FIG. 1 may be interchanged in location, or all the IGBT regions 10 may be sandwiched between the diode regions 20. In addition, the IGBT region 10 and the diode region 20 may be provided adjacent to each other one by one.

As illustrated in FIG. 1, a pad region 40 is provided to be adjacent to the IGBT region 10 on a lower side of the drawing. The pad region 40 is a region where a control pad 41 for controlling the semiconductor device 100 is provided. The IGBT region 10 and the diode region 20 are collectively referred to as a cell region. A termination region 30 is provided around a combined region of the cell region and the pad region 40 in order to hold a withstand voltage of the semiconductor device 100. A known withstand voltage holding structure can be appropriately selected and provided for the termination region 30. The withstand voltage holding structure may be configured, for example, by providing a field limiting ring (FLR), which is obtained by surrounding cell regions with p-type termination well layers of a p-type semiconductor, and a variation of lateral doping (VLD), which is obtained by surrounding cell regions with p-type well layers having a concentration gradient, on a first main surface side which is a front surface side of the semiconductor device 100. In this case, the number of ring-shaped p-type termination well layers used for the FLR and the concentration distribution used for the VLD may be appropriately selected according to the withstand voltage design of the semiconductor device 100. In addition, the p-type termination well layer may be provided over substantially the entire pad region 40, and an IGBT cell and a diode cell may be provided in the pad region 40.

The control pad 41 may include, for example, a current sense pad 41a, a Kelvin emitter pad 41b, a gate pad 41c, and temperature sense diode pads 41d and 41e. The current sense pad 41a is a control pad for detecting a current flowing through the cell regions of the semiconductor device 100, and is a control pad electrically connected to IGBT cells or diode cells in a part of the cell regions such that, when a current flows through the cell regions of the semiconductor device 100, a current corresponding to 1/several to 1/several tens of thousands of the current flowing through the entire cell regions flows.

The Kelvin emitter pad 41b and the gate pad 41c are control pads to which a gate drive voltage for controlling on/off of the semiconductor device 100 is applied. The Kelvin emitter pad 41b is electrically connected to a p-type base layer of the IGBT cell, and the gate pad 41c is electrically connected to a gate trench electrode of the IGBT cell. The Kelvin emitter pad 41b and the p-type base layer may be electrically connected to each other via a p⁺-type contact layer. The temperature sense diode pads 41d and 41e are control pads electrically connected to an anode and a cathode of a temperature sense diode provided in the semiconductor device 100. A temperature of the semiconductor device 100 is measured by measuring a voltage between an anode and a cathode of a temperature sense diode (not illustrated) provided in the cell region.

### (2) Overall Planar Structure of Island Type

In FIG. 2, the semiconductor device 101 includes an IGBT region 10 and diode regions 20 in one semiconductor device. A plurality of diode regions 20 are arranged side by side in a longitudinal direction and a lateral direction in the semiconductor device, and the diode regions 20 are surrounded by the IGBT region 10. That is, the plurality of diode regions 20 are provided in an island shape in the IGBT region 10. FIG. 2 illustrates a configuration in which the diode regions 20 are provided in a matrix shape of 4 columns in a horizontal direction on the drawing and 2 rows in a vertical direction on the drawing. However, the number and the arrangement of the diode regions 20 are not limited thereto. One or a plurality of diode regions 20 may be provided in the IGBT region 10 in an interspersed manner, and each of the diode regions 20 may be surrounded by the IGBT region 10.

As illustrated in FIG. 2, a pad region 40 is provided to be adjacent to a lower side of the IGBT region 10 in the drawing. The pad region 40 is a region where a control pad 41 for controlling the semiconductor device 101 is provided. The IGBT region 10 and the diode region 20 are collectively referred to as a cell region. A termination region 30 is provided around a combined region of the cell region and the pad region 40 in order to hold a withstand voltage of the semiconductor device 101. A known withstand voltage holding structure can be appropriately selected and provided for the termination region 30. The withstand voltage holding structure may be configured, for example, by providing a field limiting ring (FLR), which is obtained by surrounding a combined region of the cell region and the pad region 40 with p-type termination well layers of a p-type semiconductor, and a variation of lateral doping (VLD), which is obtained by surrounding cell regions with p-type well layers having a concentration gradient, on a first main surface side which is a front surface side of the semiconductor device 101. In this case, the number of ring-shaped p-type termination well layers used for the FLR and the concentration distribution used for the VLD may be appropriately selected according to the withstand voltage design of the semiconductor device 101. In addition, the p-type termination well layer may be provided over substantially the entire pad region 40, and an IGBT cell and a diode cell may be provided in the pad region 40.

The control pad 41 may include, for example, a current sense pad 41a, a Kelvin emitter pad 41b, a gate pad 41c, and temperature sense diode pads 41d and 41e. The current sense pad 41a is a control pad for detecting a current flowing through the cell regions of the semiconductor device 101, and is a control pad electrically connected to IGBT cells or diode cells in a part of the cell regions such that, when a current flows through the cell regions of the semiconductor device 101, a current corresponding to 1/several to 1/several tens of thousands of the current flowing through the entire cell regions flows.

The Kelvin emitter pad 41b and the gate pad 41c are control pads to which a gate drive voltage for controlling on/off of the semiconductor device 101 is applied. The Kelvin emitter pad 41b is electrically connected to a p-type base layer and an n⁺-type source layer of the IGBT cell, and the gate pad 41c is electrically connected to a gate trench electrode of the IGBT cell. The Kelvin emitter pad 41b and the p-type base layer may be electrically connected to each other via a p⁺-type contact layer. The temperature sense diode pads 41d and 41e are control pads electrically connected to an anode and a cathode of a temperature sense diode provided in the semiconductor device 101. A temperature of the semiconductor device 101 is measured by measuring a voltage between an anode and a cathode of a temperature sense diode (not illustrated) provided in the cell region.

### (3) General Structure of IGBT Region 10

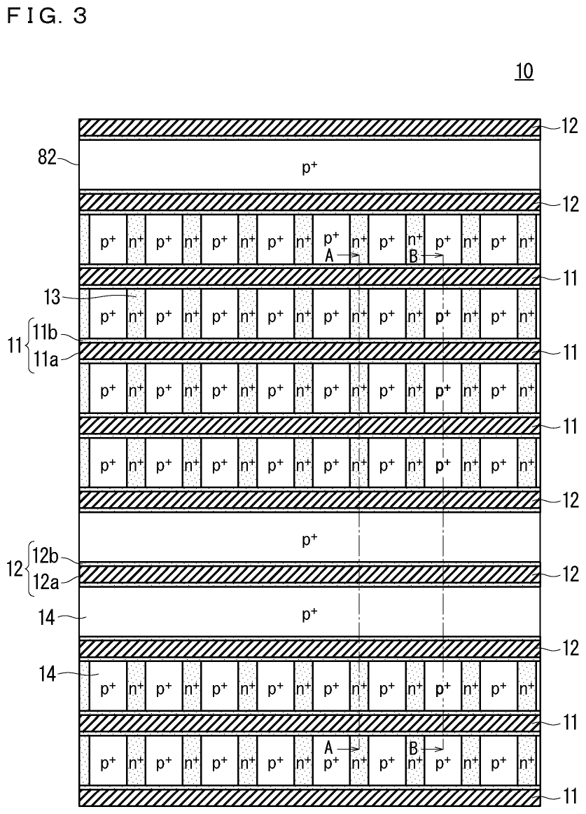

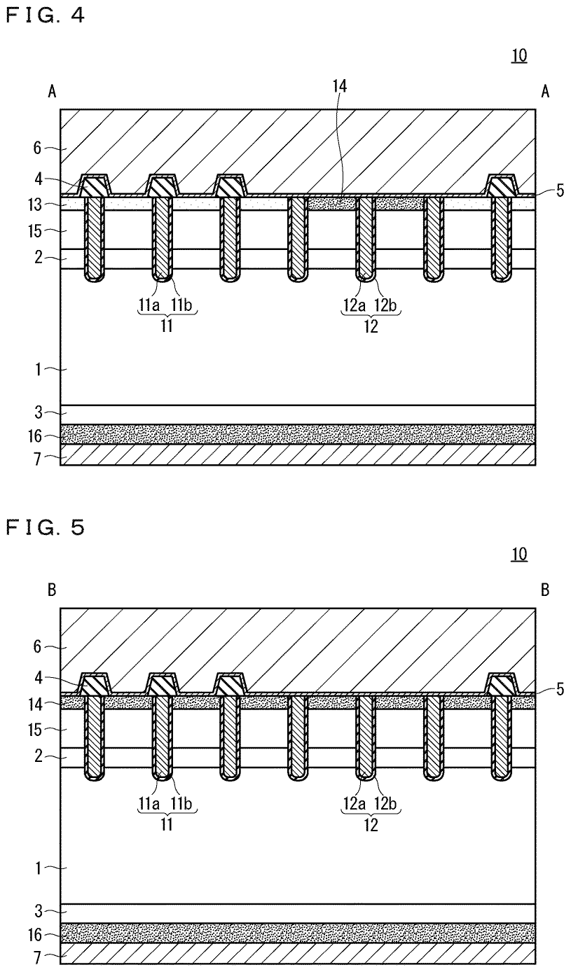

FIG. 3 is a partially-enlarged plan view illustrating a configuration of the IGBT region of the semiconductor device that is an RC-IGBT. In addition, FIG. 4 and FIG. 5 are cross-sectional views illustrating a configuration of the IGBT region of the semiconductor device that is an RC-IGBT. FIG. 3 is an enlarged view of a region surrounded by a broken line 82 in the semiconductor device 100 illustrated in FIG. 1 or the semiconductor device 101 illustrated in FIG. 2. FIG. 4 is a cross-sectional view of the semiconductor device 100 or the semiconductor device 101 taken along a broken line A-A illustrated in FIG. 3 in the arrow direction, and FIG. 5 is a cross-sectional view of the semiconductor device 100 or the semiconductor device 101 taken along a broken line B-B illustrated in FIG. 3 in the arrow direction.

As illustrated in FIG. 3, in the IGBT region 10, an active trench gate 11 and a dummy trench gate 12 are provided in a stripe shape. In the semiconductor device 100, the active trench gate 11 and the dummy trench gate 12 extend in a longitudinal direction of the IGBT region 10, and the longitudinal direction of the IGBT region 10 is a longitudinal direction of the active trench gate 11 and the dummy trench gate 12. On the other hand, in the semiconductor device 101, there is no particular distinction between the longitudinal direction and the lateral direction in the IGBT region 10, but a horizontal direction in the drawing may be the longitudinal direction of the active trench gate 11 and the dummy trench gate 12, and a vertical direction in the drawing may be the longitudinal direction of the active trench gate 11 and the dummy trench gate 12.

The active trench gate 11 is configured by providing a gate trench electrode 11a in a trench formed on the semiconductor substrate via a gate trench insulating film 11b. The dummy trench gate 12 is configured by providing a dummy trench electrode 12a in a trench formed on the semiconductor substrate via a dummy trench insulating film 12b. The gate trench electrode 11a of the active trench gate 11 is electrically connected to the gate pad 41c. The dummy trench electrode 12a of the dummy trench gate 12 is electrically connected to an emitter electrode provided on the first main surface of the semiconductor device 100 or the semiconductor device 101.

An n⁺-type source layer 13 is provided on both sides of the active trench gate 11 in a width direction so as to be in contact with the gate trench insulating film 11b. The n⁺-type source layer 13 is a semiconductor layer containing, for example, arsenic or phosphorus as n-type impurities, and a concentration of the n-type impurities is 1.0×10¹⁷/cm³ to 1.0×10²⁰/cm³. The n⁺-type source layer 13 is provided alternately with a p⁺-type contact layer 14 along the extending direction of the active trench gate 11. The p⁺-type contact layer 14 is also provided between two adjacent dummy trench gates 12. The p⁺-type contact layer 14 is a semiconductor layer containing, for example, boron or aluminum as p-type impurities, and a concentration of the p-type impurities is 1.0×10¹⁵/cm³ to 1.0×10²⁰/cm³.

As illustrated in FIG. 3, in the IGBT region 10 of the semiconductor device 100 or the semiconductor device 101, three dummy trench gates 12 are arranged side by side next to three active trench gates 11, and three active trench gates 11 are arranged side by side next to three dummy trench gates 12. The IGBT region 10 has a configuration in which a set of the active trench gates 11 and a set of the dummy trench gates 12 are alternately arranged as described above. In FIG. 3, the number of active trench gates 11 included in one set of the active trench gates 11 is 3, but the number may be one or more. In addition, the number of dummy trench gates 12 included in one set of the dummy trench gates 12 may be one or more, and the number of dummy trench gates 12 may be 0. That is, all the trenches provided in the IGBT region 10 may be used as the active trench gates 11.

FIG. 4 is a cross-sectional view of the semiconductor device 100 or the semiconductor device 101 taken along a broken line A-A in FIG. 3 in the arrow direction, and is a cross-sectional view of the IGBT region 10. The semiconductor device 100 or the semiconductor device 101 includes an n⁻-type drift layer 1 that is a second semiconductor layer made of a semiconductor substrate. The n⁻-type drift layer 1 is a semiconductor layer containing, for example, arsenic or phosphorus as n-type impurities, and a concentration of the n-type impurities is 1.0×10¹²/cm³ to 1.0×10¹⁵/cm³. In FIG. 4, the semiconductor substrate is in a range from the n⁺-type source layer 13 and the p⁺-type contact layer 14 to a p-type collector layer 16. In FIG. 4, an upper end of the n⁺-type source layer 13 and the p⁺-type contact layer 14 in the drawing is referred to as a first main surface of the semiconductor substrate, and a lower end of the p-type collector layer 16 in the drawing is referred to as a second main surface of the semiconductor substrate. The first main surface of the semiconductor substrate is a main surface on the front surface side of the semiconductor device 100, and the second main surface of the semiconductor substrate is a main surface on the back surface side of the semiconductor device 100. The semiconductor device 100 includes the n⁻-type drift layer 1 between the first main surface and the second main surface which faces the first main surface in the IGBT region 10 that is a cell region.

As illustrated in FIG. 4, in the IGBT region 10, an n-type carrier accumulation layer 2 that has a higher concentration of n-type impurities than the n⁻-type drift layer 1 is provided on the first main surface side of the n⁻-type drift layer 1. The n-type carrier accumulation layer 2 is a semiconductor layer containing, for example, arsenic or phosphorus as n-type impurities, and a concentration of the n-type impurities is 1.0×10¹³/cm³ to 1.0×10¹⁷/cm³. Note that the semiconductor device 100 or the semiconductor device 101 may have a configuration in which the n⁻-type drift layer 1 is also provided in a region of the n-type carrier accumulation layer 2 illustrated in FIG. 4 without providing the n-type carrier accumulation layer 2. By providing the n-type carrier accumulation layer 2, an energization loss when a current flows through the IGBT region 10 can be reduced. The n-type carrier accumulation layer 2 and the n⁻-type drift layer 1 may be collectively referred to as a drift layer.

The n-type carrier accumulation layer 2 is formed by ion-injecting n-type impurities into the semiconductor substrate including the n⁻-type drift layer 1 and then diffusing the injected n-type impurities into the n⁻-type drift layer 1 of the semiconductor substrate by annealing.

A p-type base layer 15 is provided on the first main surface side of the n-type carrier accumulation layer 2. The p-type base layer 15 is a semiconductor layer containing, for example, boron or aluminum as p-type impurities, and a concentration of the p-type impurities is 1.0×10¹²/cm³ to 1.0×10¹⁹/cm³. The p-type base layer 15 is in contact with the gate trench insulating film 11b of the active trench gate 11. On the first main surface side of the p-type base layer 15, an n⁺-type source layer 13 is provided in contact with the gate trench insulating film 11b of the active trench gate 11, and a p⁺-type contact layer 14 is provided in the remaining region. The n⁺-type source layer 13 and the p⁺-type contact layer 14 form the first main surface of the semiconductor substrate. Note that the p⁺-type contact layer 14 is a region having a higher p-type impurity concentration than the p-type base layer 15. In a case where it is necessary to distinguish the p⁺-type contact layer 14 and the p-type base layer 15 from each other, the p⁺-type contact layer 14 and the p-type base layer 15 may be referred to as individual layers, and the p⁺-type contact layer 14 and the p-type base layer 15 may be collectively referred to as a p-type base layer.

Further, in the semiconductor device 100 or the semiconductor device 101, an n-type buffer layer 3 that has a higher concentration of n-type impurities than the n⁻-type drift layer 1 is provided on the second main surface side of the n⁻-type drift layer 1. The n-type buffer layer 3 is provided to suppress punch-through of a depletion layer extending from the p-type base layer 15 to the second main surface side when the semiconductor device 100 is in an off state. The n-type buffer layer 3 may be formed by, for example, injecting phosphorus (P) or protons (H⁺), or may be formed by injecting both phosphorus (P) and protons (H⁺). A concentration of the n-type impurities in the n-type buffer layer 3 is 1.0×10¹²/cm³ to 1.0×10¹⁸/cm³.

Note that the semiconductor device 100 or the semiconductor device 101 may have a configuration in which the n⁻-type drift layer 1 is also provided in a region of the n-type buffer layer 3 illustrated in FIG. 4 without providing the n-type buffer layer 3. The n-type buffer layer 3 and the n⁻-type drift layer 1 may be collectively referred to as a drift layer.

In the semiconductor device 100 or the semiconductor device 101, a p-type collector layer 16 is provided on the second main surface side of the n-type buffer layer 3. That is, the p-type collector layer 16 is provided between the n⁻-type drift layer 1 and the second main surface. The p-type collector layer 16 is a semiconductor layer containing, for example, boron or aluminum as p-type impurities, and a concentration of the p-type impurities is 1.0×10¹⁶/cm³ to 1.0×10²⁰/cm³. The p-type collector layer 16 forms the second main surface of the semiconductor substrate. The p-type collector layer 16 is provided not only in the IGBT region 10 but also in the termination region 30, and a portion of the p-type collector layer 16 provided in the termination region 30 forms a p-type termination collector layer 16a. In addition, the p-type collector layer 16 may be provided so as to partially protrude from the IGBT region 10 to the diode region 20.

As illustrated in FIG. 4, in the semiconductor device 100 or the semiconductor device 101, a trench that penetrates the p-type base layer 15 from the first main surface of the semiconductor substrate and reaches into the n⁻-type drift layer 1 is formed. By providing the gate trench electrode 11a in the trench via the gate trench insulating film 11b, the active trench gate 11 is formed. The gate trench electrode 11a faces the n⁻-type drift layer 1 via the gate trench insulating film 11b. In addition, by providing the dummy trench electrode 12a in the trench via the dummy trench insulating film 12b, the dummy trench gate 12 is formed. The dummy trench electrode 12a faces the n⁻-type drift layer 1 via the dummy trench insulating film 12b. The gate trench insulating film 11b of the active trench gate 11 is in contact with the p-type base layer 15 and the n⁺-type source layer 13. When a gate drive voltage is applied to the gate trench electrode 11a, a channel is formed in the p-type base layer 15 in contact with the gate trench insulating film 11b of the active trench gate 11.

As illustrated in FIG. 4, an interlayer insulating film 4 is provided on the gate trench electrode 11a of the active trench gate 11. A barrier metal 5 is formed on a region in which the interlayer insulating film 4 is not provided on the first main surface of the semiconductor substrate and on the interlayer insulating film 4. The barrier metal 5 may be, for example, a conductor containing titanium (Ti), and may be, for example, titanium nitride or TiSi obtained by alloying titanium and silicon (Si). As illustrated in FIG. 4, the barrier metal 5 is in ohmic contact with the n⁺-type source layer 13, the p⁺-type contact layer 14, and the dummy trench electrode 12a, and is electrically connected to the n⁺-type source layer 13, the p⁺-type contact layer 14, and the dummy trench electrode 12a. An emitter electrode 6 is provided on the barrier metal 5. The emitter electrode 6 may be formed of, for example, an aluminum alloy such as an aluminum silicon alloy (Al—Si-based alloy), or may be an electrode including a plurality of layers of metal films obtained by forming a plating film on an electrode formed of an aluminum alloy by electroless plating or electrolytic plating. The plating film formed by electroless plating or electrolytic plating may be, for example, a nickel (Ni) plating film. In addition, in a case where there is a region where favorable embedding cannot be obtained in the emitter electrode 6, such as a fine region between adjacent interlayer insulating films 4 or the like, tungsten having better embeddability than the emitter electrode 6 may be arranged in the fine region, and the emitter electrode 6 may be provided on the tungsten. Note that the emitter electrode 6 may be provided on the n⁺-type source layer 13, the p⁺-type contact layer 14, and the dummy trench electrode 12a without providing the barrier metal 5. In addition, the barrier metal 5 may be provided only on the n-type semiconductor layer such as the n⁺-type source layer 13. The barrier metal 5 and the emitter electrode 6 may be collectively referred to as an emitter electrode. Note that, although FIG. 4 illustrates a view in which the interlayer insulating film 4 is not provided on the dummy trench electrode 12a of the dummy trench gate 12, the interlayer insulating film 4 may be formed on the dummy trench electrode 12a of the dummy trench gate 12. In a case where the interlayer insulating film 4 is formed on the dummy trench electrode 12a of the dummy trench gate 12, the emitter electrode 6 and the dummy trench electrode 12a may be electrically connected to each other in another cross section.

A collector electrode 7 is provided on the second main surface side of the p-type collector layer 16. Similarly to the emitter electrode 6, the collector electrode 7 may be made of an aluminum alloy, or an aluminum alloy and a plating film. In addition, the collector electrode 7 may have a configuration different from the configuration of the emitter electrode 6. The collector electrode 7 is in ohmic contact with the p-type collector layer 16, and is electrically connected to the p-type collector layer 16.

FIG. 5 is a cross-sectional view of the semiconductor device 100 or the semiconductor device 101 taken along a broken line B-B in FIG. 3 in the arrow direction, and is a cross-sectional view of the IGBT region 10. The cross-sectional view taken along the broken line B-B in FIG. 5 in the arrow direction is different from the cross-sectional view taken along the broken line A-A in FIG. 4 in the arrow direction in that the n⁺-type source layer 13 which is provided on the first main surface side of the semiconductor substrate in contact with the active trench gate 11 is not seen. That is, as illustrated in FIG. 3, the n⁺-type source layer 13 is selectively provided on the first main surface side of the p-type base layer. Note that the p-type base layer referred to herein is a p-type base layer when the p-type base layer 15 and the p⁺-type contact layer 14 are collectively referred to.

### (4) General Structure of Diode Region 20

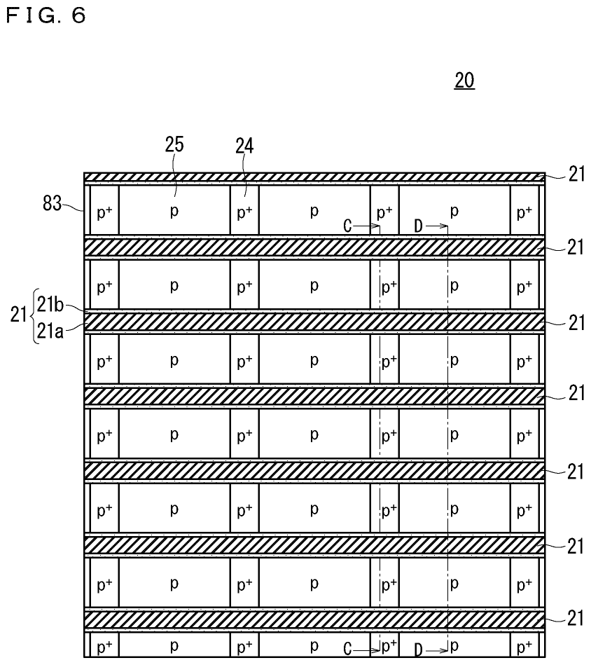

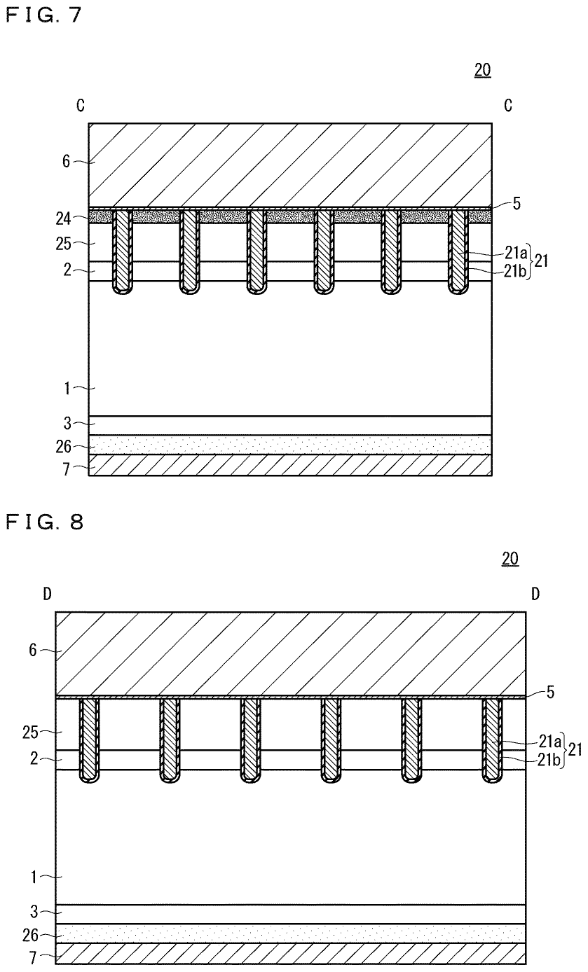

FIG. 6 is a partially-enlarged plan view illustrating a configuration of a diode region of a semiconductor device that is an RC-IGBT. In addition, FIG. 7 and FIG. 8 are cross-sectional views illustrating a configuration of the diode region of the semiconductor device that is an RC-IGBT. FIG. 6 is an enlarged view of a region 83 illustrated in FIG. 1 that is surrounded by a broken line in the semiconductor device 100 or the semiconductor device 101. FIG. 7 is a cross-sectional view of the semiconductor device 100 illustrated in FIG. 6 taken along a broken line C-C in the arrow direction. FIG. 8 is a cross-sectional view of the semiconductor device 100 illustrated in FIG. 6 taken along a broken line D-D in the arrow direction.

A diode trench gate 21 extends along the first main surface of the semiconductor device 100 or the semiconductor device 101 from one end side of the diode region 20 toward the opposite other end side of the diode region 20 which is a cell region. The diode trench gate 21 is formed by providing a diode trench electrode 21a in the trench formed on the semiconductor substrate in the diode region 20 via a diode trench insulating film 21b. The diode trench electrode 21a faces the n⁻-type drift layer 1 via the diode trench insulating film 21b. A p⁺-type contact layer 24 and a p-type anode layer 25 which is a third semiconductor layer are provided between two adjacent diode trench gates 21. The p⁺-type contact layer 24 is a semiconductor layer containing, for example, boron or aluminum as p-type impurities, and a concentration of the p-type impurities is 1.0×10¹⁵/cm³ to 1.0×10²⁰/cm³. The p-type anode layer 25 is a semiconductor layer containing, for example, boron or aluminum as p-type impurities, and a concentration of the p-type impurities is 1.0×10¹²/cm³ to 1.0×10¹⁹/cm³. The p⁺-type contact layer 24 and the p-type anode layer 25 are alternately provided in the longitudinal direction of the diode trench gate 21.

FIG. 7 is a cross-sectional view of the semiconductor device 100 or the semiconductor device 101 taken along a broken line C-C in FIG. 6 in the arrow direction, and is a cross-sectional view of the diode region 20. The semiconductor device 100 or the semiconductor device 101 also includes an n⁻-type drift layer 1 made of a semiconductor substrate in the diode region 20 similarly to the IGBT region 10. The n⁻-type drift layer 1 of the diode region 20 and the n⁻-type drift layer 1 of the IGBT region 10 are continuously and integrally formed, and are formed of the same semiconductor substrate. In FIG. 7, the semiconductor substrate is in a range from a p⁺-type contact layer 24 to an n⁺-type cathode layer 26 which is a first semiconductor layer. In FIG. 7, an upper end of the p⁺-type contact layer 24 in the drawing is referred to as a first main surface of the semiconductor substrate, and a lower end of the n⁺-type cathode layer 26 in the drawing is referred to as a second main surface of the semiconductor substrate. The first main surface of the diode region 20 and the first main surface of the IGBT region 10 are the same surface, and the second main surface of the diode region 20 and the second main surface of the IGBT region 10 are the same surface.

As illustrated in FIG. 7, also in the diode region 20, similarly to the IGBT region 10, an n-type carrier accumulation layer 2 is provided on the first main surface side of the n⁻-type drift layer 1, and an n-type buffer layer 3 is provided on the second main surface side of the n⁻-type drift layer 1. The n-type carrier accumulation layer 2 and the n-type buffer layer 3 provided in the diode region 20 have the same configuration as the n-type carrier accumulation layer 2 and the n-type buffer layer 3 provided in the IGBT region 10. Note that the n-type carrier accumulation layer 2 is not necessarily provided in the IGBT region 10 and the diode region 20, and even in a case where the n-type carrier accumulation layer 2 is provided in the IGBT region 10, the n-type carrier accumulation layer 2 may not be provided in the diode region 20. In addition, similarly to the IGBT region 10, the n⁻-type drift layer 1, the n-type carrier accumulation layer 2, and the n-type buffer layer 3 may be collectively referred to as a drift layer.

A p-type anode layer 25 is provided on the first main surface side of the n-type carrier accumulation layer 2. The p-type anode layer 25 is provided between the n⁻-type drift layer 1 and the first main surface. By making a concentration of the p-type impurities of the p-type anode layer 25 equal to the concentration of the p-type impurities of the p-type base layer 15 of the IGBT region 10, the p-type anode layer 25 and the p-type base layer 15 may be simultaneously formed. In addition, by making the concentration of the p-type impurities of the p-type anode layer 25 lower than the concentration of the p-type impurities of the p-type base layer 15 of the IGBT region 10, the amount of holes to be injected into the diode region 20 during an operation of the diode can be reduced. By reducing the amount of holes to be injected during an operation of the diode, a recovery loss during the operation of the diode can be reduced.

A p⁺-type contact layer 24 is provided on the first main surface side of the p-type anode layer 25. A concentration of the p-type impurities of the p⁺-type contact layer 24 may be equal to or different from the concentration of the p-type impurities of the p⁺-type contact layer 14 of the IGBT region 10. The p⁺-type contact layer 24 forms the first main surface of the semiconductor substrate. Note that the p⁺-type contact layer 24 is a region having a higher p-type impurity concentration than the p-type anode layer 25. In a case where it is necessary to distinguish the p⁺-type contact layer 24 and the p-type anode layer 25 from each other, the p⁺-type contact layer 24 and the p-type anode layer 25 may be referred to as individual layers, and the p⁺-type contact layer 24 and the p-type anode layer 25 may be collectively referred to as a p-type anode layer.

In the diode region 20, an n⁺-type cathode layer 26 is provided on the second main surface side of the n-type buffer layer 3. The n⁺-type cathode layer 26 is provided between the n⁻-type drift layer 1 and the second main surface. The n⁺-type cathode layer 26 is a semiconductor layer containing, for example, arsenic or phosphorus as n-type impurities, and a concentration of the n-type impurities is 1.0×10¹⁶/cm³ to 1.0×10²¹/cm³. As illustrated in FIG. 7, the n⁺-type cathode layer 26 is provided in a part or all of the diode region 20. The n⁺-type cathode layer 26 forms the second main surface of the semiconductor substrate. Note that, although not illustrated, a p⁺-type cathode layer may be provided by selectively further injecting p-type impurities into a region where the n⁺-type cathode layer 26 is formed as described above, and using a part of the region where the n⁺-type cathode layer 26 is formed as a p-type semiconductor. The diode in which the n⁺-type cathode layer and the p⁺-type cathode layer are alternately arranged along the second main surface of the semiconductor substrate is referred to as a relaxed field of cathode (RFC) diode.

As illustrated in FIG. 7, a trench that penetrates the p-type anode layer 25 from the first main surface of the semiconductor substrate and reaches into the n⁻-type drift layer 1 is formed in the diode region 20 of the semiconductor device 100 or the semiconductor device 101. By providing the diode trench electrode 21a in the trench of the diode region 20 via the diode trench insulating film 21b, the diode trench gate 21 is formed. The diode trench electrode 21a faces the n⁻-type drift layer 1 via the diode trench insulating film 21b.

As illustrated in FIG. 7, a barrier metal 5 is provided on the diode trench electrode 21a and the p⁺-type contact layer 24. The barrier metal 5 is in ohmic contact with the diode trench electrode 21a and the p⁺-type contact layer 24, and is electrically connected to the diode trench electrode and the p⁺-type contact layer 24. The barrier metal 5 may have the same configuration as the barrier metal 5 in the IGBT region 10. An emitter electrode 6 is provided on the barrier metal 5. The emitter electrode 6 provided in the diode region 20 is formed to be continuous with the emitter electrode 6 provided in the IGBT region 10. Note that, as in the case of the IGBT region 10, the diode trench electrode 21a and the p⁺-type contact layer 24 may be brought into ohmic contact with the emitter electrode 6 without providing the barrier metal 5. Note that, although FIG. 7 illustrates the configuration in which an interlayer insulating film 4 is not provided on the diode trench electrode 21a of the diode trench gate 21, an interlayer insulating film 4 may be formed on the diode trench electrode 21a of the diode trench gate 21. In a case where an interlayer insulating film 4 is formed on the diode trench electrode 21a of the diode trench gate 21, the emitter electrode 6 and the diode trench electrode 21a may be electrically connected to each other in another cross section.

A collector electrode 7 is provided on the second main surface side of the n⁺-type cathode layer 26. Similarly to the emitter electrode 6, the collector electrode 7 of the diode region 20 is formed to be continuous with the collector electrode 7 provided in the IGBT region 10. The collector electrode 7 is in ohmic contact with the n⁺-type cathode layer 26, is electrically connected to the n⁺-type cathode layer 26, and also functions as a cathode electrode.

FIG. 8 is a cross-sectional view of the semiconductor device 100 or the semiconductor device 101 taken along a broken line D-D in FIG. 6 in the arrow direction, and is a cross-sectional view of the diode region 20 in the arrow direction. The cross-sectional view illustrated in FIG. 8 is different from the cross-sectional view illustrated in FIG. 7 in the arrow direction taken along the broken line C-C in that the p⁺-type contact layer 24 is not provided between the p-type anode layer 25 and the barrier metal 5, and that the p-type anode layer 25 forms the first main surface of the semiconductor substrate. That is, the p⁺-type contact layer 24 illustrated in FIG. 7 is selectively provided on the first main surface side of the p-type anode layer 25.

### (5) Boundary Region Between IGBT Region 10 and Diode Region 20

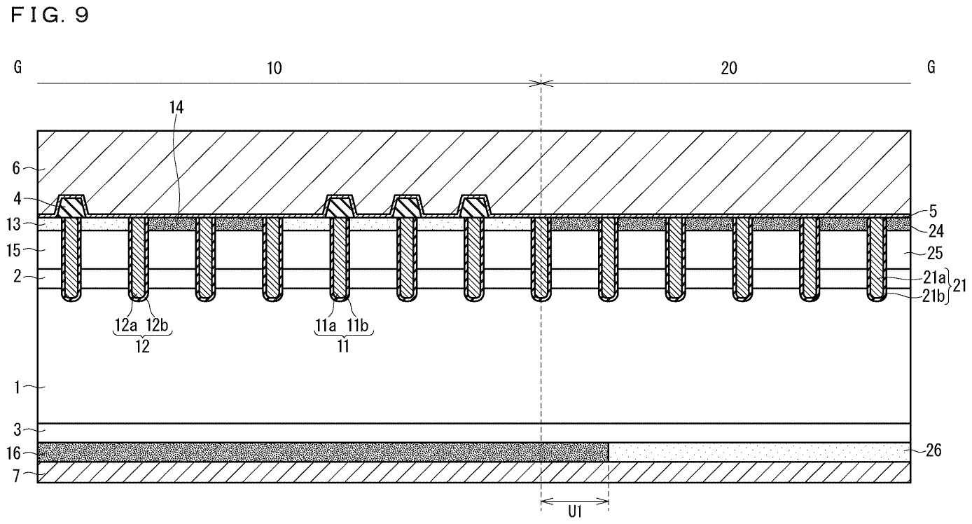

FIG. 9 is a cross-sectional view illustrating a configuration of a boundary between the IGBT region and the diode region of the semiconductor device that is an RC-IGBT. FIG. 9 is a cross-sectional view of the semiconductor device 100 or the semiconductor device 101 taken along a broken line G-G illustrated in FIG. 1 in the arrow direction.

As illustrated in FIG. 9, the p-type collector layer 16 provided on the second main surface side of the IGBT region 10 is provided so as to protrude toward the diode region 20 from a boundary between the IGBT region 10 and the diode region 20 by a distance U1. As described above, by providing the p-type collector layer 16 so as to protrude toward the diode region 20, a distance between the n⁺-type cathode layer 26 of the diode region 20 and the active trench gate 11 can be increased, and even in a case where a gate drive voltage is applied to the gate trench electrode 11a during an operation of the free wheeling diode, it is possible to prevent a current from flowing from a channel formed adjacent to the active trench gate 11 of the IGBT region 10 to the n⁺-type cathode layer 26. The distance U1 may be, for example, 100 μm. Note that the distance U1 may be 0 or a distance shorter than 100 μm depending on the application of the semiconductor device 100 or the semiconductor device 101 that is an RC-IGBT.

### (6) General Structure of Termination Region 30

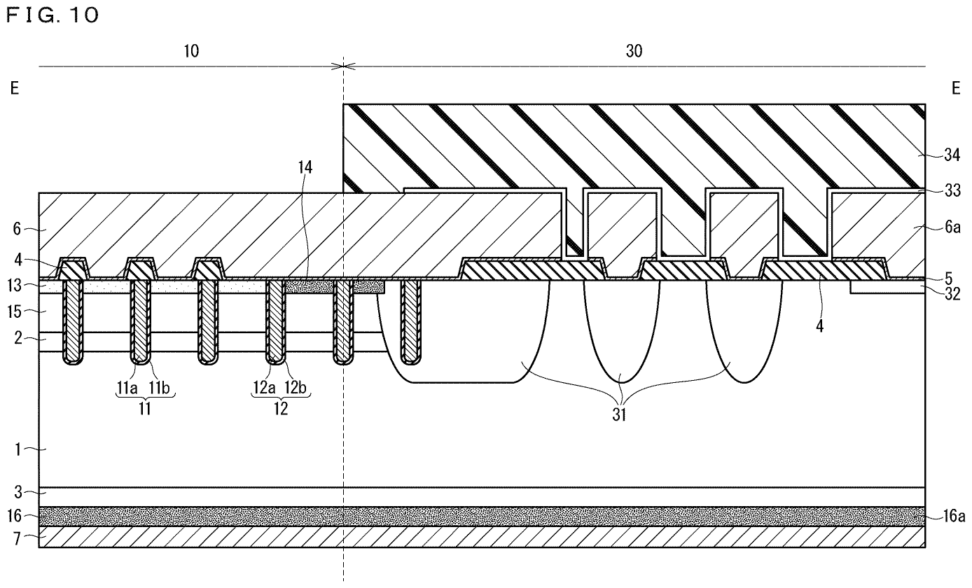

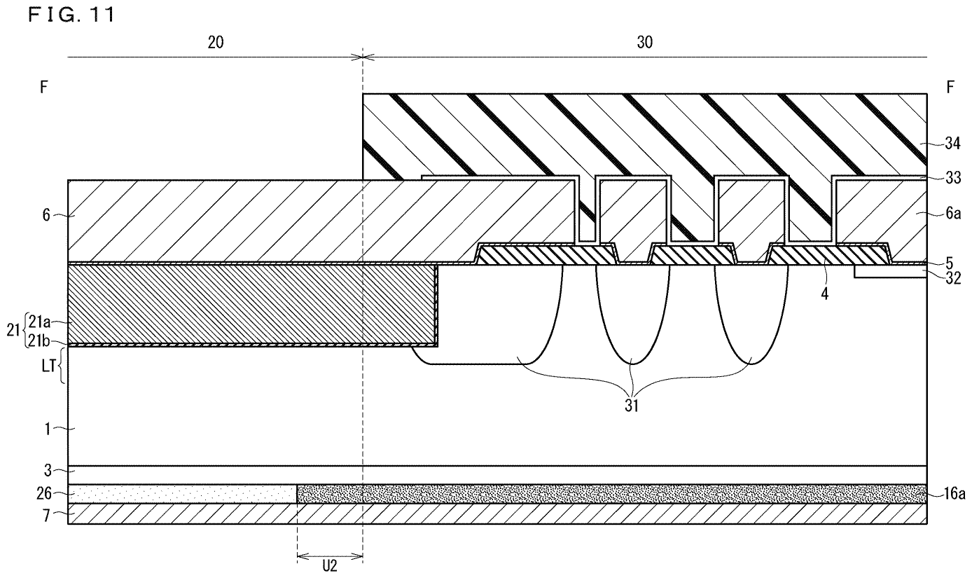

FIG. 10 and FIG. 11 are cross-sectional views illustrating a configuration of the termination region of the semiconductor device that is an RC-IGBT. FIG. 10 is a cross-sectional view taken along a broken line E-E in FIG. 1 or FIG. 2 in the arrow direction, and is a cross-sectional view from the IGBT region 10 to the termination region 30. In addition, FIG. 11 is a cross-sectional view taken along a broken line F-F in FIG. 1 in the arrow direction, and is a cross-sectional view from the diode region 20 to the termination region 30.

As illustrated in FIG. 10 and FIG. 11, the termination region 30 of the semiconductor device 100 includes the n⁻-type drift layer 1 between the first main surface and the second main surface of the semiconductor substrate. The first main surface and the second main surface of the termination region 30 are respectively the same as the first main surface and the second main surface of the IGBT region 10 and the diode region 20. In addition, the n⁻-type drift layer 1 in the termination region 30 has the same configuration as the n⁻-type drift layer 1 in the IGBT region 10 and the diode region 20, and is continuously and integrally formed.

A p-type termination well layer 31 is provided on the first main surface side of the n⁻-type drift layer 1, that is, between the first main surface of the semiconductor substrate and the n⁻-type drift layer 1. The p-type termination well layer 31 is a semiconductor layer containing, for example, boron or aluminum as p-type impurities, and a concentration of the p-type impurities is 1.0×10¹⁴/cm³ to 1.0×10¹⁹/cm³. The p-type termination well layers 31 are provided to surround the cell region including the IGBT region 10 and the diode region 20. The p-type termination well layers 31 are provided in a plurality of ring shapes, and the number of the p-type termination well layers 31 to be provided is appropriately selected according to the withstand voltage design of the semiconductor device 100 or the semiconductor device 101. Further, an n⁺-type channel stopper layer 32 is provided on a further outer edge side of the p-type termination well layer 31, and the n⁺-type channel stopper layer 32 surrounds the p-type termination well layer 31.

A p-type termination collector layer 16a is provided between the n⁻-type drift layer 1 and the second main surface of the semiconductor substrate. The p-type termination collector layer 16a is formed integrally and continuously with the p-type collector layer 16 provided in the cell region. Therefore, the p-type collector layer 16 including the p-type termination collector layer 16a may be referred to as a p-type collector layer 16. Further, in the configuration in which the diode region 20 is provided to be adjacent to the termination region 30 as in the semiconductor device 100 illustrated in FIG. 1, as illustrated in FIG. 11, the p-type termination collector layer 16a is provided such that an end portion on the diode region 20 side protrudes into the diode region 20 by a distance U2. As described above, by providing the p-type termination collector layer 16a so as to protrude into the diode region 20, a distance between the n⁺-type cathode layer 26 of the diode region 20 and the p-type termination well layer 31 can be increased, and it is possible to prevent the p-type termination well layer 31 from operating as an anode of a diode. The distance U2 may be, for example, 100 μm.

A collector electrode 7 is provided on the second main surface of the semiconductor substrate. The collector electrode 7 is continuously and integrally formed from the cell region including the IGBT region 10 and the diode region 20 to the termination region 30. On the other hand, an emitter electrode 6 that is continuous from the cell region and a termination electrode 6a that is separated from the emitter electrode 6 are provided on the first main surface of the semiconductor substrate in the termination region 30.

The emitter electrode 6 and the termination electrode 6a are electrically connected to each other via a semi-insulating film 33. The semi-insulating film 33 may be, for example, a semi-insulating silicon nitride (sinSiN) film. The termination electrode 6a, the p-type termination well layer 31, and the n⁺-type channel stopper layer 32 are electrically connected to each other via a contact hole formed on the interlayer insulating film 4 provided on the first main surface of the termination region 30. In addition, in the termination region 30, a termination protection film 34 is provided to cover the emitter electrode 6, the termination electrode 6a, and the semi-insulating film 33. The termination protection film 34 may be formed of, for example, polyimide.

### Application Target of Preferred Embodiments

Hereinafter, preferred embodiments according to the present disclosure will be described. First, an example of an application target of the present disclosure will be described. Although examples of an application target of the present disclosure include a metal oxide semiconductor (MOS) transistor and an insulated gate bipolar transistor (IGBT), the following description will be given assuming that an application target of the present disclosure is an RC-IGBT.

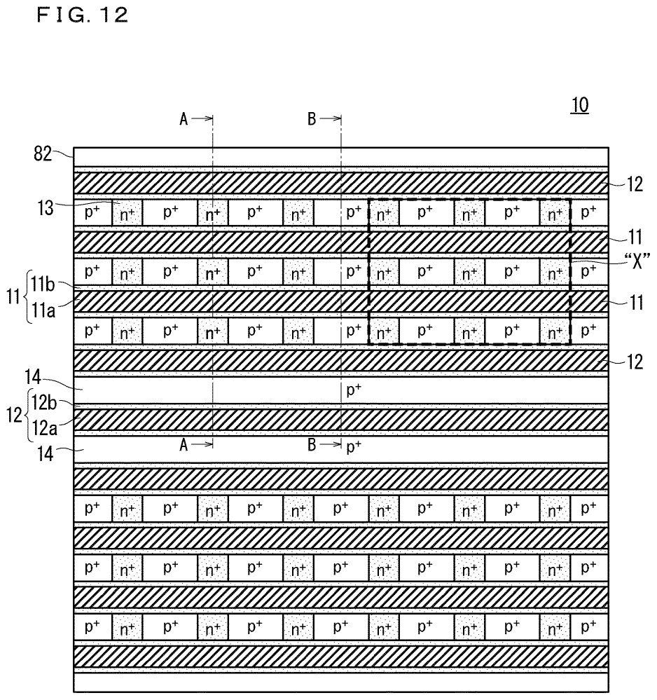

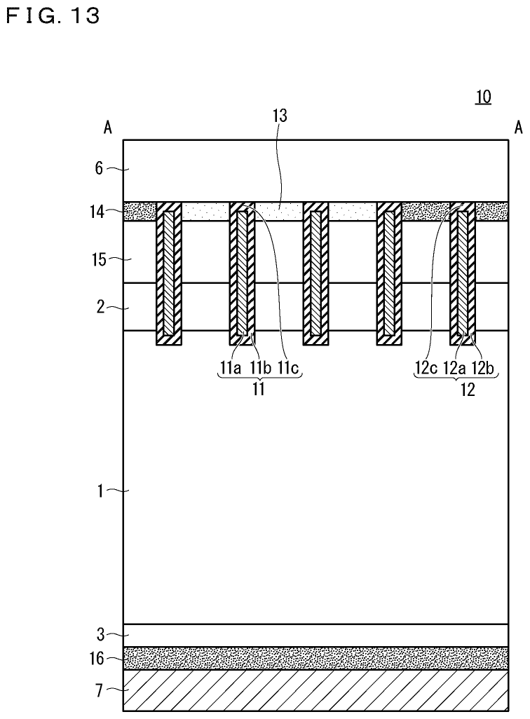

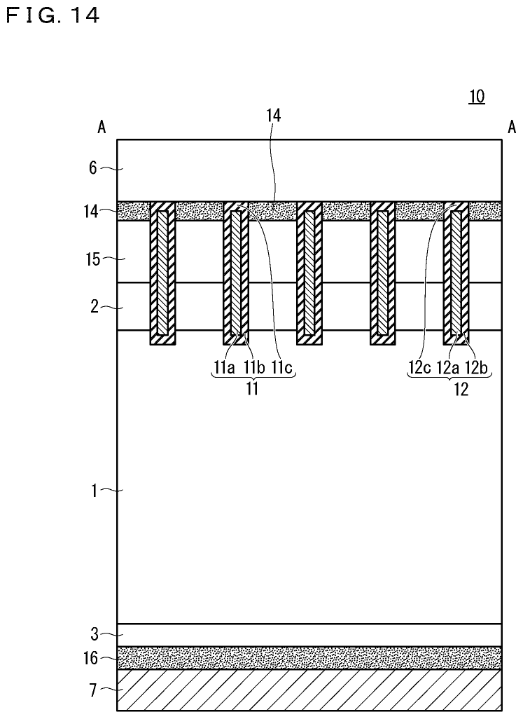

FIG. 12 is a partially-enlarged plan view illustrating a configuration of an IGBT region of a semiconductor device that is an RC-IGBT. In addition, FIG. 13 and FIG. 14 are cross-sectional views illustrating a configuration of the IGBT region of the semiconductor device that is an RC-IGBT. FIG. 12 is an enlarged view of a region surrounded by a broken line 82 in the semiconductor device 100 illustrated in FIG. 1 or the semiconductor device 101 illustrated in FIG. 2. FIG. 13 is a cross-sectional view of the semiconductor device 100 or the semiconductor device 101 taken along a broken line A-A illustrated in FIG. 12 in the arrow direction, and FIG. 14 is a cross-sectional view of the semiconductor device 100 or the semiconductor device 101 taken along a broken line B-B illustrated in FIG. 12 in the arrow direction.

As illustrated in FIG. 12, in the IGBT region 10, an active trench gate 11 and a dummy trench gate 12 are provided in a stripe shape. In the semiconductor device 100, the active trench gate 11 and the dummy trench gate 12 extend in a longitudinal direction of the IGBT region 10, and the longitudinal direction of the IGBT region 10 is a longitudinal direction of the active trench gate 11 and the dummy trench gate 12. On the other hand, in the semiconductor device 101, there is no particular distinction between the longitudinal direction and the lateral direction in the IGBT region 10, but a horizontal direction in the drawing may be the longitudinal direction of the active trench gate 11 and the dummy trench gate 12, and a vertical direction in the drawing may be the longitudinal direction of the active trench gate 11 and the dummy trench gate 12.

The active trench gate 11 is configured by providing a gate trench electrode 11a in a trench formed in the semiconductor substrate such as a silicon substrate via a gate trench insulating film 11b. The dummy trench gate 12 is configured by providing a dummy trench electrode 12a in a trench formed in the semiconductor substrate via a dummy trench insulating film 12b. The gate trench electrode 11a of the active trench gate 11 is electrically connected to the gate pad 41c. The dummy trench electrode 12a of the dummy trench gate 12 is electrically connected to an emitter electrode provided on the first main surface of the semiconductor device 100 or the semiconductor device 101. Note that the semiconductor substrate is not limited to a silicon substrate, and a wide band gap semiconductor substrate mainly made of a wide band gap semiconductor such as silicon carbide (SiC) that has a wider band gap than Si can be used.

An n⁺-type source layer 13 is provided on both sides of the active trench gate 11 in a width direction so as to be in contact with the gate trench insulating film 11b. The n⁺-type source layer 13 is a semiconductor layer containing, for example, arsenic or phosphorus as n-type impurities, and a concentration of the n-type impurities is 1.0×10¹⁷/cm³ or higher. The n⁺-type source layer 13 is provided alternately with a p⁺-type contact layer 14 along the extending direction of the active trench gate 11. The p⁺-type contact layer 14 is also provided between two adjacent dummy trench gates 12. The p⁺-type contact layer 14 is a semiconductor layer containing, for example, boron or aluminum as p-type impurities, and a concentration of the p-type impurities is 1.0×10¹⁵/cm³ or higher.

As illustrated in FIG. 12, in the IGBT region 10 of the semiconductor device 100 or the semiconductor device 101, three dummy trench gates 12 are arranged side by side next to two active trench gates 11, and two active trench gates 11 are arranged side by side next to three dummy trench gates 12. The IGBT region 10 has a configuration in which a set of the active trench gates 11 and a set of the dummy trench gates 12 are alternately arranged as described above. In FIG. 12, the number of active trench gates 11 included in one set of the active trench gates 11 is 2, but the number may be one or more. In addition, the number of dummy trench gates 12 included in one set of the dummy trench gates 12 may be one or more, and the number of dummy trench gates 12 may be 0. That is, all the trenches provided in the IGBT region 10 may be used as the active trench gates 11.

FIG. 13 is a cross-sectional view of the semiconductor device 100 or the semiconductor device 101 taken along a broken line A-A in FIG. 12 in the arrow direction, and is a cross-sectional view of the IGBT region 10. The semiconductor device 100 or the semiconductor device 101 includes an n⁻-type drift layer 1 that is a second semiconductor layer made of a semiconductor substrate. The n⁻-type drift layer 1 is a semiconductor layer containing, for example, arsenic or phosphorus as n-type impurities, and a concentration of the n-type impurities is 1.0×10¹²/cm³ to 1.0×10¹⁵/cm³. In FIG. 13, the semiconductor substrate is in a range from the n⁺-type source layer 13 and the p⁺-type contact layer 14 to a p-type collector layer 16. In FIG. 13, an upper end of the n⁺-type source layer 13 and the p⁺-type contact layer 14 in the drawing is referred to as a first main surface of the semiconductor substrate, and a lower end of the p-type collector layer 16 in the drawing is referred to as a second main surface of the semiconductor substrate. The first main surface of the semiconductor substrate is a main surface on the front surface side of the semiconductor device 100, and the second main surface of the semiconductor substrate is a main surface on the back surface side of the semiconductor device 100. The semiconductor device 100 includes the n⁻-type drift layer 1 between the first main surface and the second main surface which faces the first main surface in the IGBT region 10 that is a cell region.

As illustrated in FIG. 13, in the IGBT region 10, an n-type carrier accumulation layer 2 that has a higher concentration of n-type impurities than the n⁻-type drift layer 1 is provided on the first main surface side of the n⁻-type drift layer 1. The n-type carrier accumulation layer 2 is a semiconductor layer containing, for example, arsenic or phosphorus as n-type impurities, and a concentration of the n-type impurities is 1.0×10¹³/cm³ to 1.0×10¹⁷/cm³. Note that the semiconductor device 100 or the semiconductor device 101 may have a configuration in which the n⁻-type drift layer 1 is also provided in a region of the n-type carrier accumulation layer 2 illustrated in FIG. 13 without providing the n-type carrier accumulation layer 2. By providing the n-type carrier accumulation layer 2, an energization loss when a current flows through the IGBT region 10 can be reduced. The n-type carrier accumulation layer 2 and the n⁻-type drift layer 1 may be collectively referred to as a drift layer.

The n-type carrier accumulation layer 2 is formed by ion-injecting n-type impurities into the semiconductor substrate including the n⁻-type drift layer 1 and then diffusing the injected n-type impurities into the n⁻-type drift layer 1 of the semiconductor substrate by annealing.

A p-type base layer 15 is provided on the first main surface side of the n-type carrier accumulation layer 2. The p-type base layer 15 is a semiconductor layer containing, for example, boron or aluminum as p-type impurities, and a concentration of the p-type impurities is 1.0×10¹²/cm³ to 1.0×10¹⁹/cm³. The p-type base layer 15 is in contact with the gate trench insulating film 11b of the active trench gate 11. On the first main surface side of the p-type base layer 15, an n⁺-type source layer 13 is provided in contact with the gate trench insulating film 11b of the active trench gate 11, and a p⁺-type contact layer 14 is provided in the remaining region. The n⁺-type source layer 13 and the p⁺-type contact layer 14 form the first main surface of the semiconductor substrate. Note that the p⁺-type contact layer 14 is a region having a higher p-type impurity concentration than the p-type base layer 15. In a case where it is necessary to distinguish the p⁺-type contact layer 14 and the p-type base layer 15 from each other, the p⁺-type contact layer 14 and the p-type base layer 15 may be referred to as individual layers, and the p⁺-type contact layer 14 and the p-type base layer 15 may be collectively referred to as a p-type base layer.

Further, in the semiconductor device 100 or the semiconductor device 101, an n-type buffer layer 3 that has a higher concentration of n-type impurities than the n⁻-type drift layer 1 is provided on the second main surface side of the n⁻-type drift layer 1. The n-type buffer layer 3 is provided to suppress punch-through of a depletion layer extending from the p-type base layer 15 to the second main surface side when the semiconductor device 100 is in an off state. The n-type buffer layer 3 may be formed by, for example, injecting phosphorus (P) or protons (H⁺), or may be formed by injecting both phosphorus (P) and protons (H⁺). A concentration of the n-type impurities in the n-type buffer layer 3 is 1.0×10¹²/cm³ to 1.0×10¹⁸/cm³.

Note that the semiconductor device 100 or the semiconductor device 101 may have a configuration in which the n⁻-type drift layer 1 is also provided in a region of the n-type buffer layer 3 illustrated in FIG. 4 without providing the n-type buffer layer 3. The n-type buffer layer 3 and the n⁻-type drift layer 1 may be collectively referred to as a drift layer.

In the semiconductor device 100 or the semiconductor device 101, a p-type collector layer 16 is provided on the second main surface side of the n-type buffer layer 3. That is, the p-type collector layer 16 is provided between the n⁻-type drift layer 1 and the second main surface. The p-type collector layer 16 is a semiconductor layer containing, for example, boron or aluminum as p-type impurities, and a concentration of the p-type impurities is 1.0×10¹⁶/cm³ to 1.0×10²⁰/cm³. The p-type collector layer 16 forms the second main surface of the semiconductor substrate. The p-type collector layer 16 is provided not only in the IGBT region 10 but also in the termination region 30, and a portion of the p-type collector layer 16 provided in the termination region 30 forms a p-type termination collector layer 16a. In addition, the p-type collector layer 16 may be provided so as to partially protrude from the IGBT region 10 to the diode region 20.

As illustrated in FIG. 13, in the semiconductor device 100 or the semiconductor device 101, a trench that penetrates the p-type base layer 15 from the first main surface of the semiconductor substrate and reaches the n⁻-type drift layer 1 is formed. By providing the gate trench electrode 11a in the trench via the gate trench insulating film 11b, the active trench gate 11 is formed. The gate trench electrode 11a faces the n⁻-type drift layer 1 via the gate trench insulating film 11b. In addition, by providing the dummy trench electrode 12a in the trench via the dummy trench insulating film 12b, the dummy trench gate 12 is formed. The dummy trench electrode 12a faces the n⁻-type drift layer 1 via the dummy trench insulating film 12b. The gate trench insulating film 11b of the active trench gate 11 is in contact with the p-type base layer 15 and the n⁺-type source layer 13. When a gate drive voltage is applied to the gate trench electrode 11a, a channel is formed in the p-type base layer 15 in contact with the gate trench insulating film 11b of the active trench gate 11.

As illustrated in FIG. 13, an upper insulating film 11c is provided on the gate trench electrode 11a of the active trench gate 11, and an upper insulating film 12c is provided on the dummy trench electrode 12a of the dummy trench gate 12. A barrier metal 5 is formed on the first main surface of the semiconductor substrate including an upper surface of the upper insulating film 11c and an upper surface of the upper insulating film 12c. The barrier metal 5 may be, for example, a conductor containing titanium (Ti), and may be, for example, titanium nitride or TiSi obtained by alloying titanium and silicon (Si). As illustrated in FIG. 9, the barrier metal 5 is in ohmic contact with the n⁺-type source layer 13 and the p⁺-type contact layer 14, and is electrically connected to the n⁺-type source layer 13 and the p⁺-type contact layer 14.

An emitter electrode 6 is provided on the barrier metal 5. The emitter electrode 6 may be formed of, for example, an aluminum alloy such as an aluminum silicon alloy (Al—Si-based alloy), or may be an electrode including a plurality of layers of metal films obtained by forming a plating film on an electrode formed of an aluminum alloy by electroless plating or electrolytic plating. The plating film formed by electroless plating or electrolytic plating may be, for example, a nickel (Ni) plating film.

In addition, the barrier metal 5 may be provided only on the upper surface of the n-type semiconductor layer such as the n⁺-type source layer 13. The barrier metal 5 and the emitter electrode 6 may be collectively referred to as an emitter electrode. Note that, in FIG. 13, the upper insulating film 12c is provided on the dummy trench electrode 12a, and the emitter electrode 6 seems not to be electrically connected to the dummy trench electrode 12a, but the emitter electrode 6 and the dummy trench electrode 12a may be electrically connected to each other in another cross section.

A collector electrode 7 is provided on the second main surface side of the p-type collector layer 16. Similarly to the emitter electrode 6, the collector electrode 7 may be made of an aluminum alloy, or an aluminum alloy and a plating film. In addition, the collector electrode 7 may have a configuration different from the configuration of the emitter electrode 6. The collector electrode 7 is in ohmic contact with the p-type collector layer 16, and is electrically connected to the p-type collector layer 16.

FIG. 14 is a cross-sectional view of the semiconductor device 100 or the semiconductor device 101 taken along a broken line B-B in FIG. 12 in the arrow direction, and is a cross-sectional view of the IGBT region 10. The cross-sectional view taken along the broken line B-B in FIG. 14 in the arrow direction is different from the cross-sectional view taken along the broken line A-A in FIG. 13 in the arrow direction in that the n⁺-type source layer 13 which is provided on the first main surface side of the semiconductor substrate in contact with the active trench gate 11 is not seen. That is, as illustrated in FIG. 12, the n⁺-type source layer 13 is selectively provided on the first main surface side of the p-type base layer. Note that the p-type base layer referred to herein is a p-type base layer when the p-type base layer 15 and the p⁺-type contact layer 14 are collectively referred to.

### First Preferred Embodiment

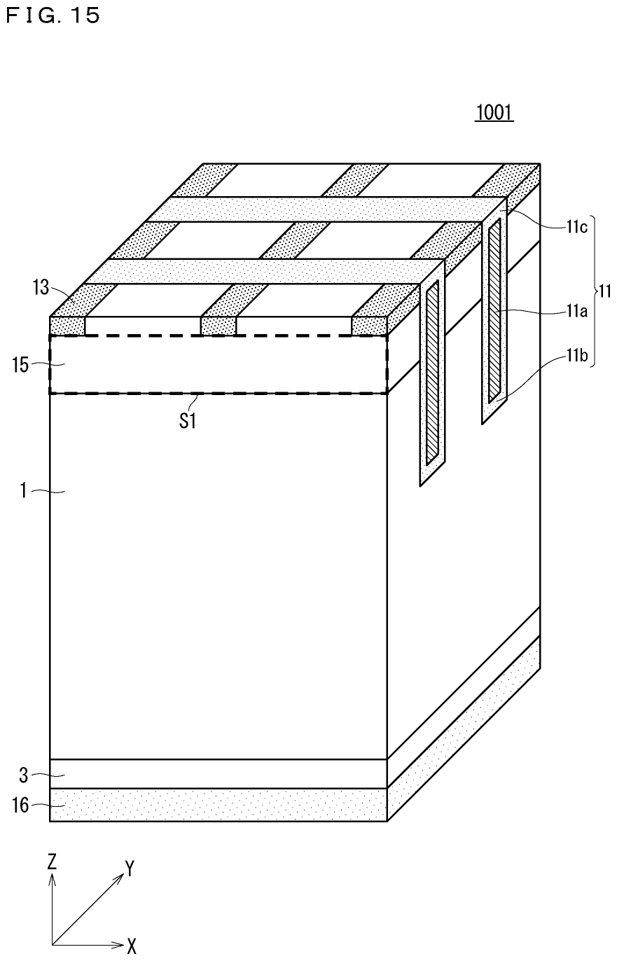

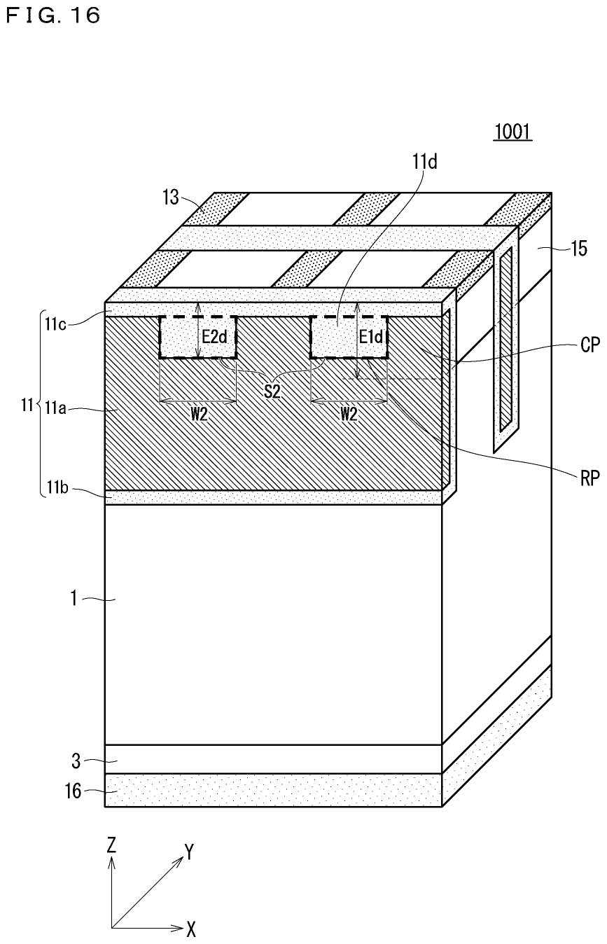

A configuration of an RC-IGBT 1001 according to a first preferred embodiment will be described with reference to FIG. 15 and FIG. 16. An overall configuration of the RC-IGBT 1001 is the same as the configuration of the semiconductor device 100 illustrated in FIG. 1 or the semiconductor device 101 illustrated in FIG. 2. The same applies to other preferred embodiments to be described below. Note that, in FIG. 15 and FIG. 16, the same components as the components in the cross-sectional view illustrated in FIG. 13 are denoted by the same reference numerals, and redundant description is omitted. The same applies to other preferred embodiments.

FIG. 15 is a cross-sectional perspective view of a region surrounded by a broken line X in FIG. 12, and FIG. 16 is a cross-sectional perspective view along the extending direction of the active trench gate 11. Note that, as illustrated in FIG. 15 and FIG. 16, the RC-IGBT 1001 does not include the p⁺-type contact layer 14 and the n-type carrier accumulation layer 2 illustrated in FIG. 13, and the first main surface of the semiconductor substrate is the outermost surface of the p-type base layer 15. In addition, the barrier metal 5 and the emitter electrode 6 illustrated in FIG. 13 are omitted for the sake of convenience.

As illustrated in FIG. 16, the gate trench electrode 11a in the active trench gate 11 is formed in a comb shape. That is, in the gate trench electrode 11a, a recess portion RP that is recessed to a side opposite to the n⁺-type source layer 13 and a protrusion portion CP that protrudes to a side of the n⁺-type source layer 13 are alternately provided along the extending direction of the active trench gate 11. The recess portion RP is filled with an insulating film 11d extending from the upper insulating film 11c.

An upper end of the protrusion portion CP of the gate trench electrode 11a is provided at a position higher than a lower end of the n⁺-type source layer 13 in a Z-axis direction, and a lower end of the recess portion RP is provided at a position lower than the lower end of the n⁺-type source layer 13 in the Z-axis direction. Here, a lower end position of the p-type base layer 15 is defined as a position E1, and a lower end position of the recess portion RP is defined as a position E2.

In a case where distances from the first main surface of the semiconductor substrate to the position E1 and the position E2 are respectively defined as a distance E1d and a distance E2d, in a case where the distance E1d is longer than the distance E2d, and in a case where an area of the p-type base layer 15 in a range from the lower end of the n⁺-type source layer 13 to the position E1 in the cross-sectional view is defined as an area S1 and an area of the recess portion RP of the gate trench electrode 11a formed in the region of the area S1 is defined as an area S2, as illustrated in FIG. 15, a gate capacitance ratio Cgc/Cge can be linearly controlled by changing the area S2.

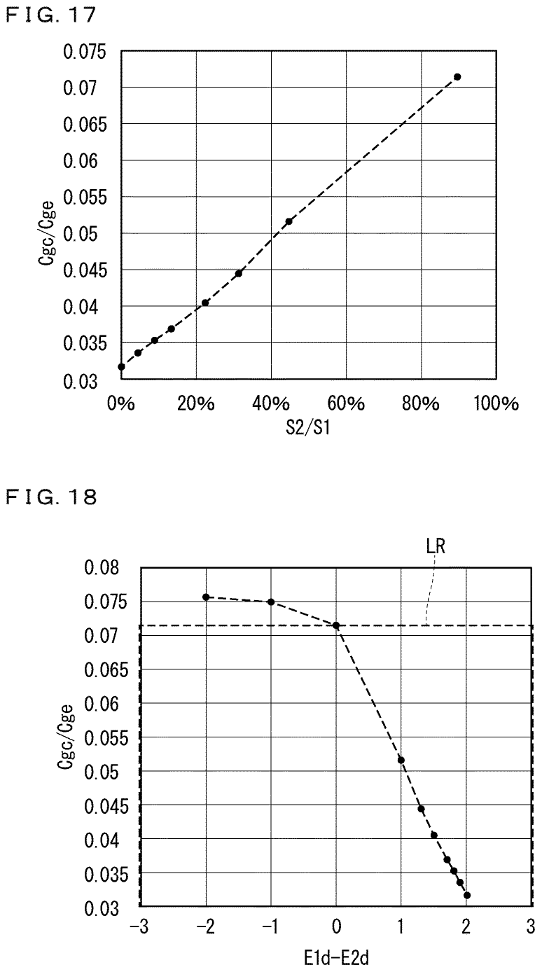

FIG. 17 is a diagram illustrating a relationship between an area ratio (S2/S1) of the area S1 and the area S2 and the gate capacitance ratio Cgc/Cge, and in FIG. 17, a horizontal axis is S2/S1 and a vertical axis is Cgc/Cge. As illustrated in FIG. 17, the area S2 is compared with the area S1, and it is found that the gate capacitance ratio Cgc/Cge is 0.032 in a case where the recess portion RP is not provided and the area ratio is 0%, the gate capacitance ratio Cgc/Cge is 0.04 in a case where the area ratio is 20%, and the gate capacitance ratio Cgc/Cge can be linearly controlled to approximately 0.05 in a case where the area ratio is 40%.

FIG. 18 is a diagram illustrating a relationship between a distance E1d-E2d and the gate capacitance ratio Cgc/Cge, the distance E1d-E2d being a distance between the distance (depth) E1d from the upper end of the n⁺-type source layer 13 to the lower end position E1 of the p-type base layer 15 and the distance (depth) E2d from the upper end of the n⁺-type source layer 13 to the lower end position E2 of the recess portion RP in a case where a width W2 which is a length of the recess portion RP of the gate trench electrode 11a illustrated in FIG. 16 in an X-axis direction is constant. In FIG. 18, a horizontal axis is E1d-E2d, and a vertical axis is Cgc/Cge. In a region LR surrounded by a broken line in FIG. 18, it is shown that, in a case where the width W2 of the recess portion RP is constant, the gate capacitance ratio Cgc/Cge can be linearly controlled in a case where the distance E1d is longer than the distance E2d.

From FIG. 18, the gate capacitance ratio Cgc/Cge can be adjusted by making the width W2 of the recess portion RP constant and changing the distance E2d of the recess portion RP in a case where the distance E1d is longer than the distance E2d. In addition, from FIG. 17, by changing a ratio of the area S1 of the p-type base layer 15 and the area S2 of the recess portion RP in the cross-sectional view, the gate capacitance ratio has a linear dependency on the area ratio S2/S1. Thus, it is possible to obtain a semiconductor device capable of optimizing the capacitance characteristics by changing the gate capacitance ratio Cgc/Cge with good controllability. This is because the recess portion RP suppresses the gate-emitter capacitance Cge, the protrusion portion CP plays a role of injecting carriers, and the gate capacitance ratio Cgc/Cge can be adjusted with good controllability by changing the shape of the recess portion RP. Therefore, it is possible to avoid erroneous firing due to dV/dt during reverse recovery of the free wheeling diode (FWD) that is caused by excessively lowering Cge.

In addition, as illustrated in FIG. 16, in the RC-IGBT 1001, the n⁺-type source layer 13 is provided corresponding to the position of the protrusion portion CP of the gate trench electrode 11a, and a hole extraction effect at the time of turn-off when the RC-IGBT 1001 operates as an IGBT can be maximized.

### Second Preferred Embodiment

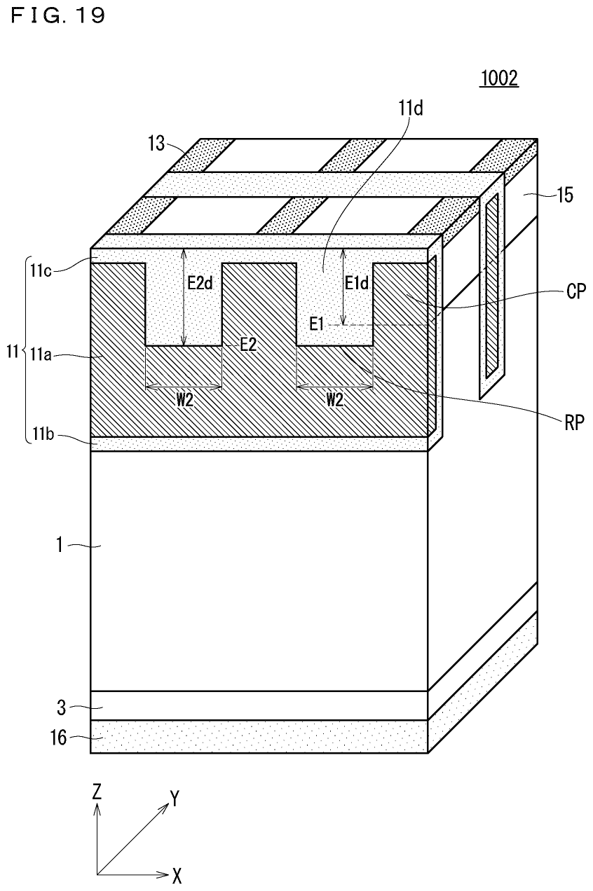

A configuration of an RC-IGBT 1002 according to a second preferred embodiment will be described with reference to FIG. 19. FIG. 19 is a cross-sectional perspective view of a region surrounded by a broken line X in FIG. 12. Note that, in FIG. 19, the same components as the components of the RC-IGBT 1001 described with reference to FIG. 16 are denoted by the same reference numerals, and redundant description is omitted.

In the RC-IGBT 1001 illustrated in FIG. 16, in a case where the lower end position of the p-type base layer 15 is a position E1, the lower end position of the recess portion RP is a position E2, and distances from the first main surface of the semiconductor substrate to the position E1 and the position E2 are respectively a distance E1d and a distance E2d, the distance E1d is set to be longer than the distance E2d. On the other hand, in the RC-IGBT 1002 illustrated in FIG. 19, the distance E1d is set to be shorter than the distance E2d. That is, a depth of the recess portion RP is set to be deeper than a bottom surface of the p-type base layer 15.

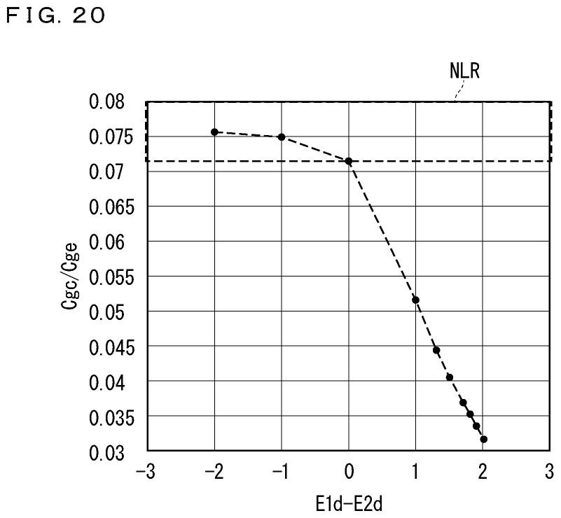

FIG. 20 is a diagram illustrating a relationship between a distance E1d-E2d and the gate capacitance ratio Cgc/Cge, the distance E1d-E2d being a distance between the distance E1d of the lower end position E1 of the p-type base layer 15 and the distance E2d of the lower end position E2 of the recess portion RP in a case where the width W2 of the recess portion RP of the gate trench electrode 11a illustrated in FIG. 19 is constant. In FIG. 20, a horizontal axis is E1d-E2d, and a vertical axis is Cgc/Cge. A region NLR surrounded by a broken line in FIG. 20 indicates a case where the distance E1d is shorter than the distance E2d. In this case, since the lower end position E2 is deeper than the lower end position E1, it is shown that the gate-emitter capacitance Cge can be further reduced and the gate capacitance ratio Cgc/Cge can be further increased.

This means that, in a case where it is desired to prioritize the noise reduction effect, the controllability of Cgc/Cge in the depth direction decreases, but the gate-emitter capacitance Cge can be further reduced. Therefore, it is possible to avoid erroneous firing due to dV/dt during reverse recovery of the FWD and to reduce noise.

### Third Preferred Embodiment

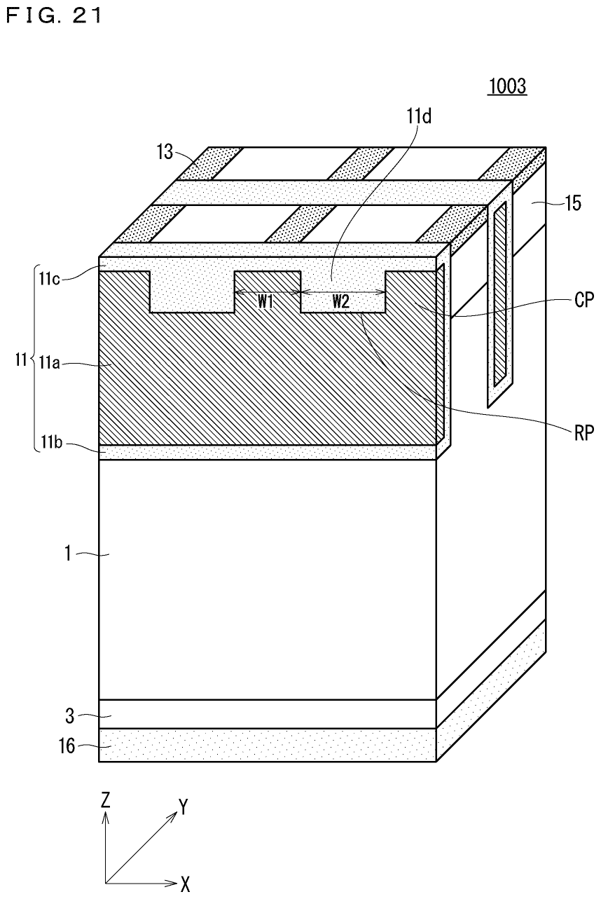

A configuration of an RC-IGBT 1003 according to a third preferred embodiment will be described with reference to FIG. 21. FIG. 21 is a cross-sectional perspective view of a region surrounded by a broken line X in FIG. 12. Note that, in FIG. 21, the same components as the components of the RC-IGBT 1001 described with reference to FIG. 16 are denoted by the same reference numerals, and redundant description is omitted.

In the RC-IGBT 1001 and the RC-IGBT 1002 illustrated in FIG. 16 and FIG. 19, the width W2 of the recess portion RP of the gate trench electrode 11a is constant, but in the RC-IGBT 1003 illustrated in FIG. 21, the width W2 is set to be wider than a width W1, the width W1 being a length of the protrusion portion CP of the gate trench electrode 11a in the X-axis direction, and the width W2 being a length of the recess portion RP of the gate trench electrode 11a in the X-axis direction. Thereby, the gate-emitter capacitance Cge can be further reduced, and the gate capacitance ratio Cgc/Cge can be further increased.

### Fourth Preferred Embodiment

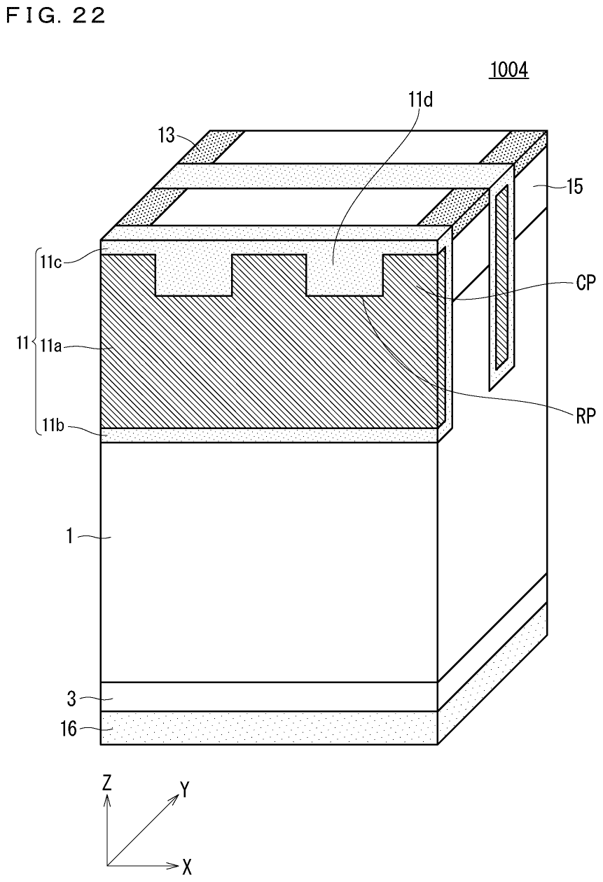

A configuration of an RC-IGBT 1004 according to a fourth preferred embodiment will be described with reference to FIG. 22. FIG. 22 is a cross-sectional perspective view corresponding to a region surrounded by a broken line X in FIG. 12. Note that, in FIG. 22, the same components as the components of the RC-IGBT 1001 described with reference to FIG. 16 are denoted by the same reference numerals, and redundant description is omitted.

In the RC-IGBT 1001 illustrated in FIG. 16, the n⁺-type source layer 13 is provided corresponding to the position of the protrusion portion CP of the gate trench electrode 11a, but the n⁺-type source layer 13 may not necessarily be provided corresponding to the protrusion portion CP as in the RC-IGBT 1004 illustrated in FIG. 22. That is, the p-type base layer 15 may include a region in which the n⁺-type source layer 13 is not provided in a region corresponding to the position at which the protrusion portion CP is provided.

By reducing the number of the n⁺-type source layers 13 to be provided, a saturation current can be adjusted without changing the gate capacitance ratio Cgc/Cge.

### Fifth Preferred Embodiment

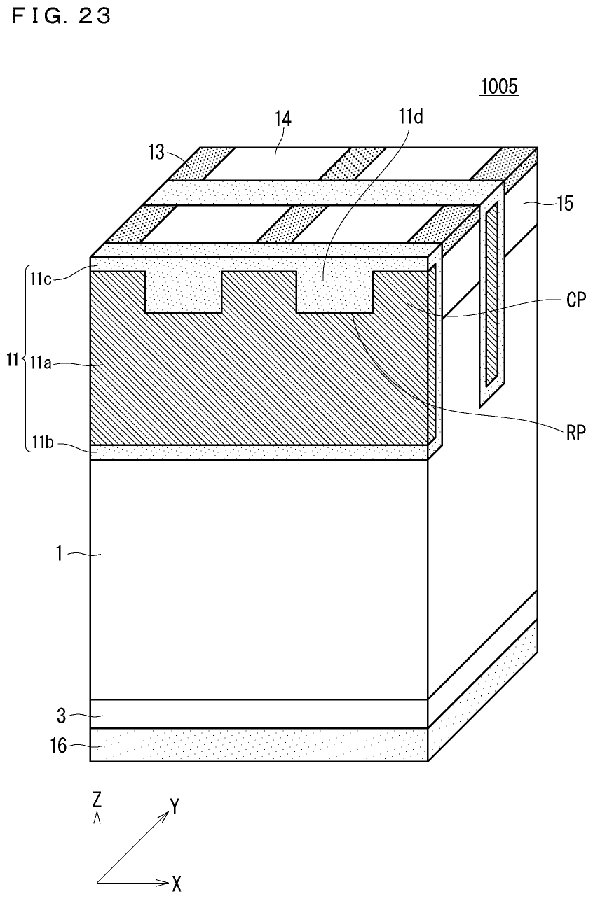

A configuration of an RC-IGBT 1005 according to a fifth preferred embodiment will be described with reference to FIG. 23. FIG. 23 is a cross-sectional perspective view of a region surrounded by a broken line X in FIG. 12. Note that, in FIG. 23, the same components as the components of the RC-IGBT 1001 described with reference to FIG. 16 are denoted by the same reference numerals, and redundant description is omitted.

In the RC-IGBT 1005 illustrated in FIG. 23, a p⁺-type contact layer 14 is provided between the n⁺-type source layers 13 provided to be parallel to each other. Thereby, it is possible to increase hole extraction efficiency at the time of turn-off when the RC-IGBT 1005 operates as an IGBT.

### Sixth Preferred Embodiment

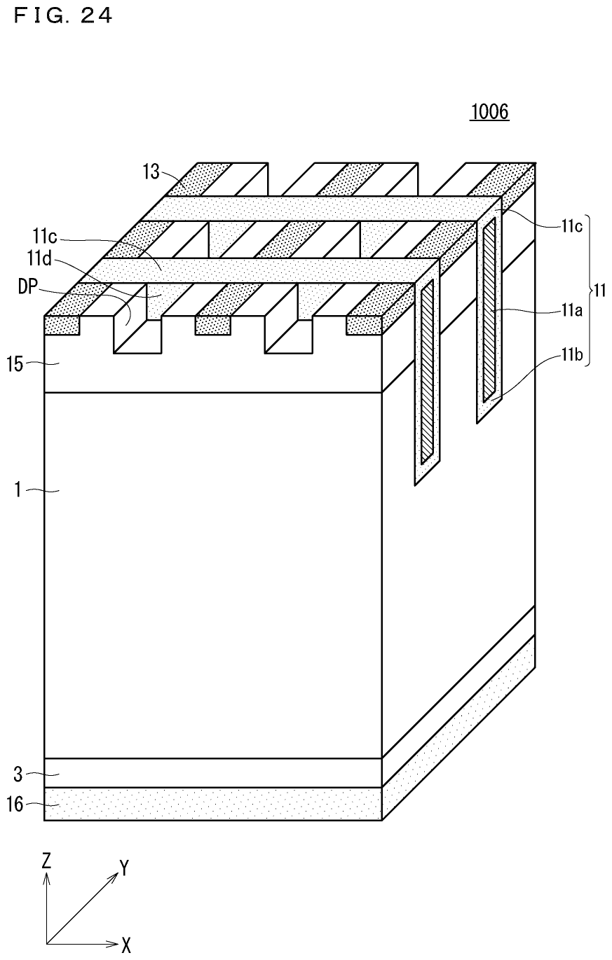

A configuration of an RC-IGBT 1006 according to a sixth preferred embodiment will be described with reference to FIG. 24. FIG. 24 is a cross-sectional perspective view corresponding to a region surrounded by a broken line X in FIG. 12. Note that, in FIG. 24, the same components as the components of the RC-IGBT 1001 described with reference to FIG. 15 are denoted by the same reference numerals, and redundant description is omitted.

In the RC-IGBT 1006 illustrated in FIG. 24, the p-type base layer 15 between the n⁺-type source layers 13 provided to be parallel to each other is removed to a predetermined depth to form a depression portion DP. In the depression portion DP, the p-type base layer 15 is removed such that the upper insulating film 11c and the insulating film 11d of the active trench gate 11 are exposed. Thereby, an area in which the barrier metal 5 and the emitter electrode 6 (not illustrated) are in contact with the p-type base layer 15 increases, and it is possible to increase the hole extraction efficiency at the time of turn-off when the RC-IGBT 1006 operates as an IGBT.

### Seventh Preferred Embodiment

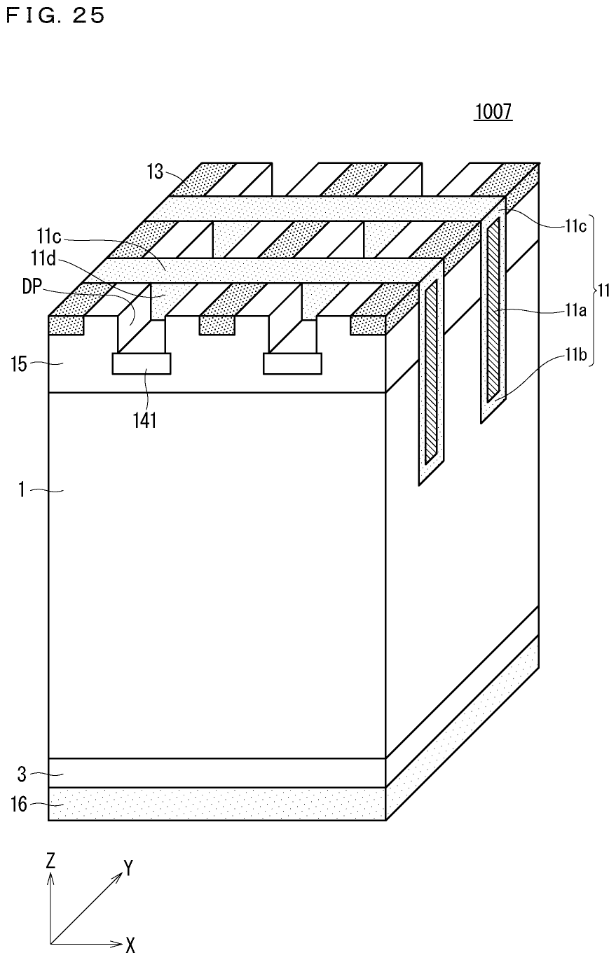

A configuration of an RC-IGBT 1007 according to a seventh preferred embodiment will be described with reference to FIG. 25. FIG. 25 is a cross-sectional perspective view corresponding to a region surrounded by a broken line X in FIG. 12. Note that, in FIG. 25, the same components as the components of the RC-IGBT 1006 described with reference to FIG. 24 are denoted by the same reference numerals, and redundant description is omitted.

In the RC-IGBT 1007 illustrated in FIG. 25, a p⁺-type contact layer 141 is provided at least on a bottom portion of the depression portion DP provided in the p-type base layer 15 between the n⁺-type source layers 13 provided to be parallel to each other. Thereby, it is possible to increase the hole extraction efficiency at the time of turn-off when the RC-IGBT 1007 operates as an IGBT.

### Eighth Preferred Embodiment

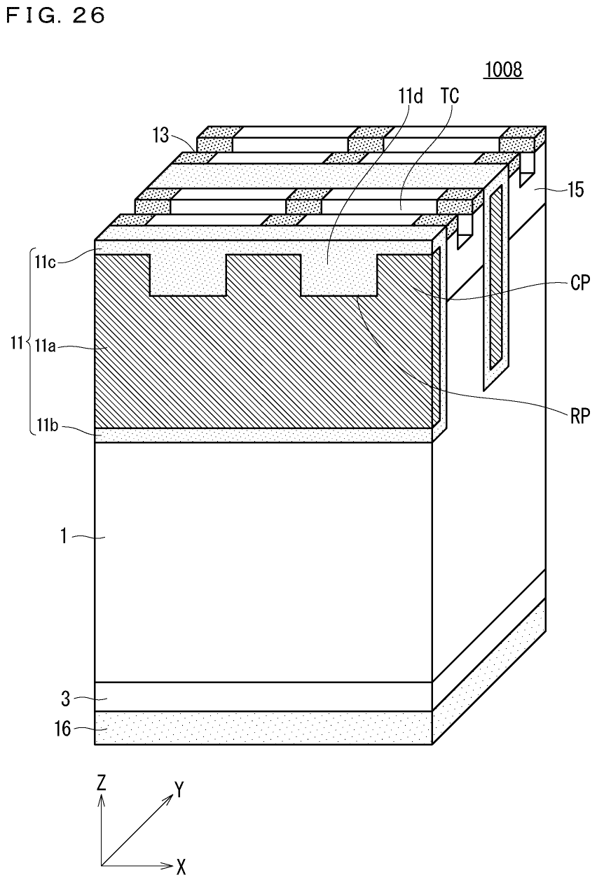

A configuration of an RC-IGBT 1008 according to an eighth preferred embodiment will be described with reference to FIG. 26. FIG. 26 is a cross-sectional perspective view corresponding to a region surrounded by a broken line X in FIG. 12. Note that, in FIG. 26, the same components as the components of the RC-IGBT 1001 described with reference to FIG. 16 are denoted by the same reference numerals, and redundant description is omitted.

In the RC-IGBT 1008 illustrated in FIG. 26, the p-type base layer 15 and the n⁺-type source layer 13 between the active trench gates 11 provided to be parallel to each other are removed along the active trench gate 11, and a trench contact TC that is parallel to the active trench gate 11 is provided. In the trench contact TC, the p-type base layer 15 is removed to a predetermined depth. Thereby, it is possible to increase the hole extraction efficiency at the time of turn-off when the RC-IGBT 1008 operates as an IGBT. Note that the trench contact TC is provided with a barrier metal 5 and an emitter electrode 6 (not illustrated).

### Ninth Preferred Embodiment

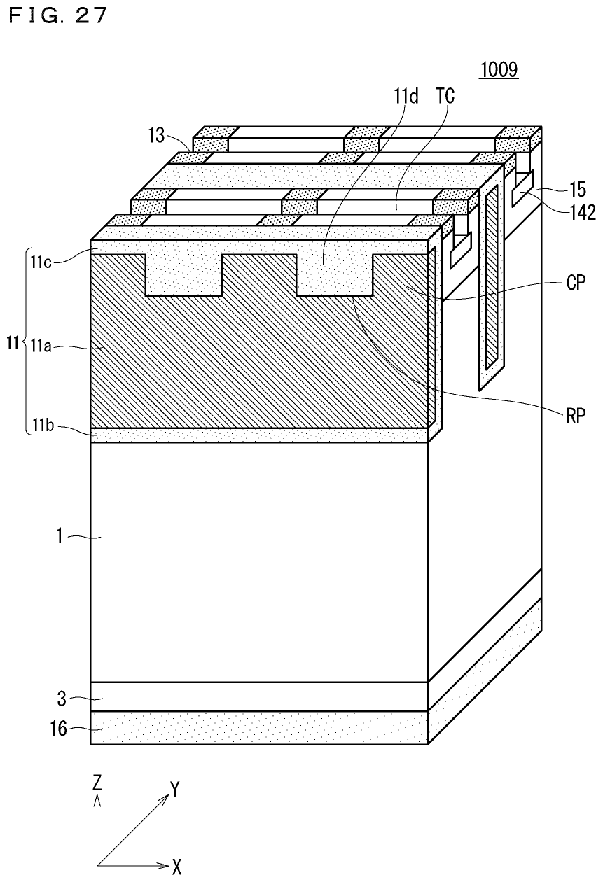

A configuration of an RC-IGBT 1009 according to a ninth preferred embodiment will be described with reference to FIG. 27. FIG. 27 is a cross-sectional perspective view corresponding to a region surrounded by a broken line X in FIG. 12. Note that, in FIG. 27, the same components as the components of the RC-IGBT 1008 described with reference to FIG. 26 are denoted by the same reference numerals, and redundant description is omitted.

In the RC-IGBT 1009 illustrated in FIG. 27, a p⁺-type contact layer 142 is provided at least on a bottom portion of the trench contact TC provided between the active trench gates 11 provided to be parallel to each other. Thereby, it is possible to increase the hole extraction efficiency at the time of turn-off when the RC-IGBT 1009 operates as an IGBT.

### Tenth Preferred Embodiment

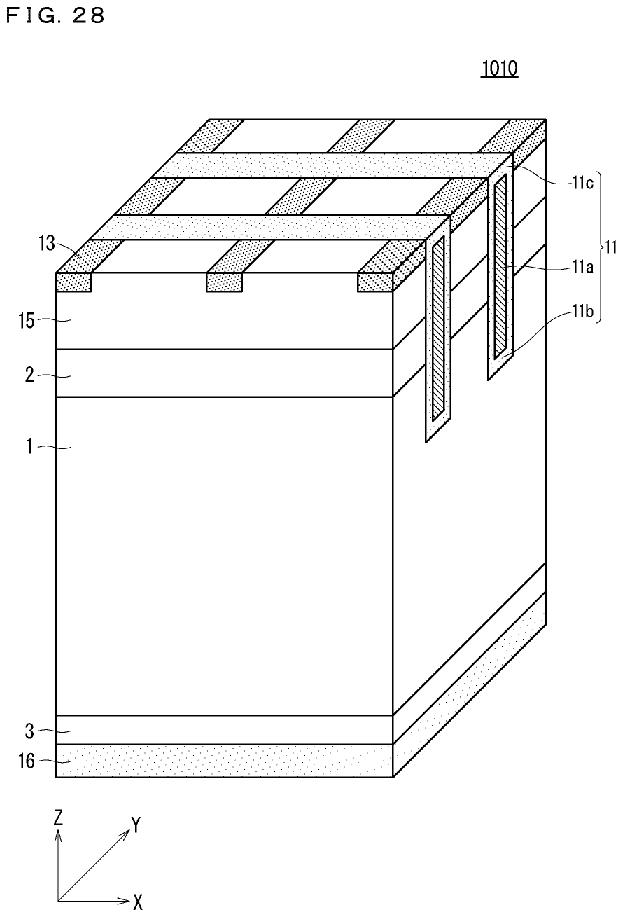

A configuration of an RC-IGBT 1010 according to a tenth preferred embodiment will be described with reference to FIG. 28. FIG. 28 is a cross-sectional perspective view of a region surrounded by a broken line X in FIG. 12. Note that, in FIG. 28, the same components as the components of the RC-IGBT 1001 described with reference to FIG. 15 are denoted by the same reference numerals, and redundant description is omitted.

In the RC-IGBT 1010 illustrated in FIG. 28, an n-type carrier accumulation layer 2 is provided under the p-type base layer 15. By providing the n-type carrier accumulation layer 2 having a higher impurity concentration on the n⁻-type drift layer 1, the carrier density on the emitter side increases due to a carrier accumulation effect of preventing holes from being extracted to the emitter side and accumulating holes. Thus, conductivity modulation is promoted, and an on-state voltage when the RC-IGBT 1010 operates as an IGBT can be lowered.

### Eleventh Preferred Embodiment

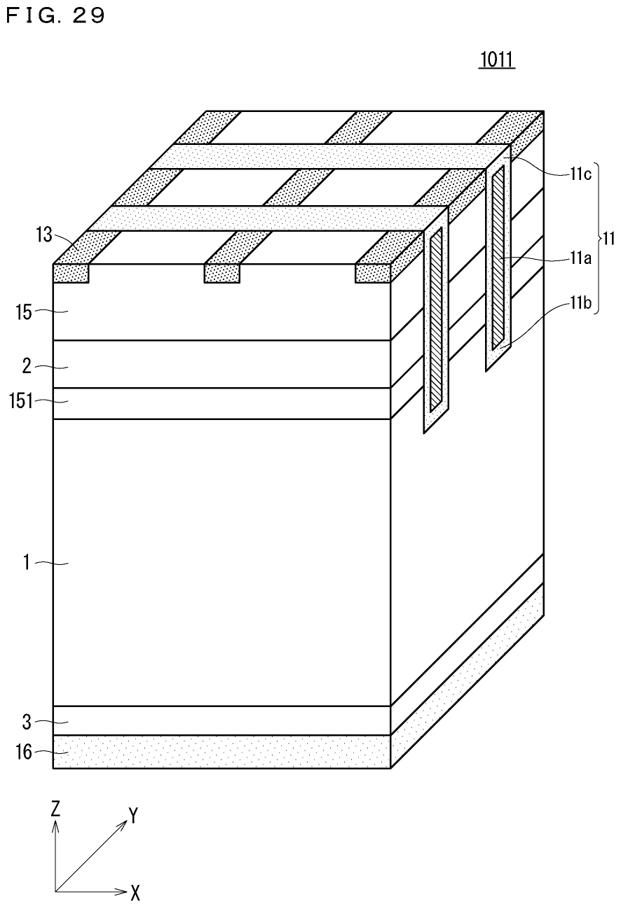

A configuration of an RC-IGBT 1011 according to an eleventh preferred embodiment will be described with reference to FIG. 29. FIG. 29 is a cross-sectional perspective view of a region surrounded by a broken line X in FIG. 12. Note that, in FIG. 29, the same components as the components of the RC-IGBT 1010 described with reference to FIG. 28 are denoted by the same reference numerals, and redundant description is omitted.

In the RC-IGBT 1011 illustrated in FIG. 29, a p-type bottom base layer 151 is provided under the n-type carrier accumulation layer 2. An impurity concentration of the p-type bottom base layer 151 is set to be equal to or lower than the impurity concentration of the p-type base layer 15. By providing the p-type bottom base layer 151, a withstand voltage of the RC-IGBT 1011 can be improved, and thus, it is possible to reduce a leakage current.

That is, in a case where the p-type bottom base layer 151 is not provided, the active trench gate 11 protrudes from a bottom surface of the n-type carrier accumulation layer 2, and electric fields concentrate only on the active trench gate 11. On the other hand, by providing the p-type bottom base layer 151, electric fields are also generated at a junction portion (junction) between the p-type bottom base layer 151 and the n⁻-type drift layer 1. Thus, the electric fields are made uniform, and the withstand voltage is improved. In a case where the electric fields are increased, carriers are generated from a high electric field region by avalanche, and a leakage current is generated. On the other hand, by providing the p-type bottom base layer 151, the electric fields are made uniform, and thus, avalanche is less likely to occur. Thereby, a leakage current can be reduced.

### Twelfth Preferred Embodiment

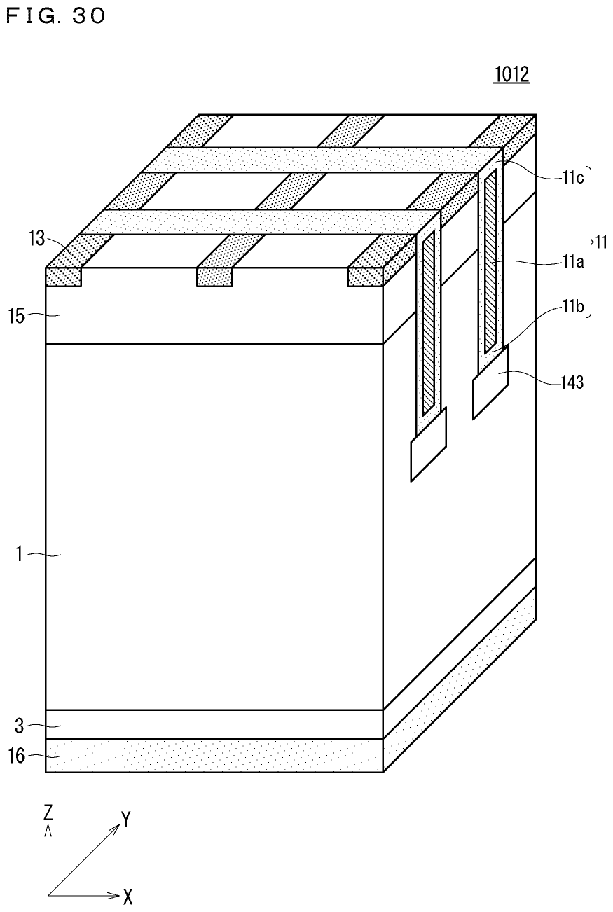

A configuration of an RC-IGBT 1012 according to a twelfth preferred embodiment will be described with reference to FIG. 30. FIG. 30 is a cross-sectional perspective view of a region surrounded by a broken line X in FIG. 12. Note that, in FIG. 30, the same components as the components of the RC-IGBT 1001 described with reference to FIG. 15 are denoted by the same reference numerals, and redundant description is omitted.

In the RC-IGBT 1012 illustrated in FIG. 30, a p⁺-type trench bottom layer 143 is provided under a bottom surface of the active trench gate 11. The p⁺-type trench bottom layer 143 is in contact with the bottom surface of the active trench gate 11, and is formed in a size such that the p⁺-type trench bottom layer 143 completely covers at least the bottom surface of the active trench gate 11. By providing the p⁺-type trench bottom layer 143, electric fields at the bottom portion of the active trench gate 11 can be relaxed, and a withstand voltage of the RC-IGBT 1012 can be improved. Thus, the withstand voltage can be improved.

That is, the p⁺-type trench bottom layer 143 is formed to be larger than the bottom surface of the active trench gate 11 such that the p⁺-type trench bottom layer 143 completely covers the bottom surface of the active trench gate 11. Therefore, the cross-sectional shape is more rounded than the bottom portion of the active trench gate 11. Therefore, in the vicinity of the p⁺-type trench bottom layer 143, the electric fields are relaxed, and the electric fields are made uniform. Thus, the withstand voltage can be improved. Thereby, it is possible to improve the withstand voltage.

### Thirteenth Preferred Embodiment

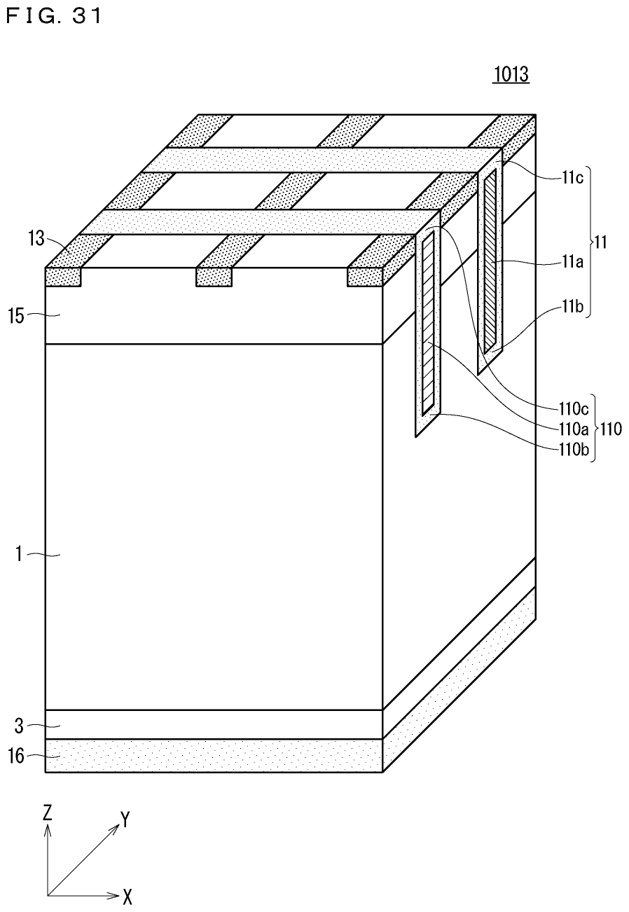

A configuration of an RC-IGBT 1013 according to a thirteenth preferred embodiment will be described with reference to FIG. 31. FIG. 31 is a cross-sectional perspective view in which at least one active trench gate 11 is changed to a dummy trench gate 110 in a region surrounded by a broken line X in FIG. 12. Note that, in FIG. 31, the same components as the components of the RC-IGBT 1001 described with reference to FIG. 15 are denoted by the same reference numerals, and redundant description is omitted.

In the RC-IGBT 1013 illustrated in FIG. 31, a dummy trench electrode 110a is provided via a dummy trench insulating film 110b in a trench that penetrates the p-type base layer 15 from the first main surface of the semiconductor substrate and reaches into the n⁻-type drift layer 1, and a dummy upper insulating film 110c is provided on the dummy trench electrode 110a. Thus, a dummy trench gate 110 is formed. The dummy trench electrode 110a is electrically connected to, for example, the emitter electrode 6. By providing the dummy trench gate 110, feedback capacitance Cgc can be reduced, and it is possible to optimize the semiconductor device that requires consideration of radiation noise.

That is, since the dummy trench electrode 110a is electrically connected to the emitter electrode 6, the dummy trench gate 110 does not function as an active trench gate, and does not form a capacitance component between the p-type base layer 15 and the n—type drift layer 1. Thus, the feedback capacitance Cgc can be reduced, and the radiation noise can be reduced by reducing di/dt, which is a temporal variation of a drain current i at the time of turn-on when the RC-IGBT 1013 operates as an IGBT.

Note that the dummy trench electrode 110a may be set to a floating potential without applying a potential thereto. Even in this case, the dummy trench gate 110 does not function as an active trench gate, and the feedback capacitance Cgc can be reduced. Thus, the radiation noise can be reduced by reducing di/dt, which is a temporal variation of a drain current i at the time of turn-on when the RC-IGBT 1013 operates as an IGBT.

In addition, by electrically connecting the dummy trench electrode 110a to a control gate, a carrier injection timing can be adjusted by the control gate, and thus, it is possible to contribute to improvement of a power loss.

The control gate is a gate that supplies a control gate potential different from the gate potential supplied from gate wiring, and the carrier injection timing can be adjusted by connecting the gate trench electrode 11a and the dummy trench electrode 110a to different gate drivers.

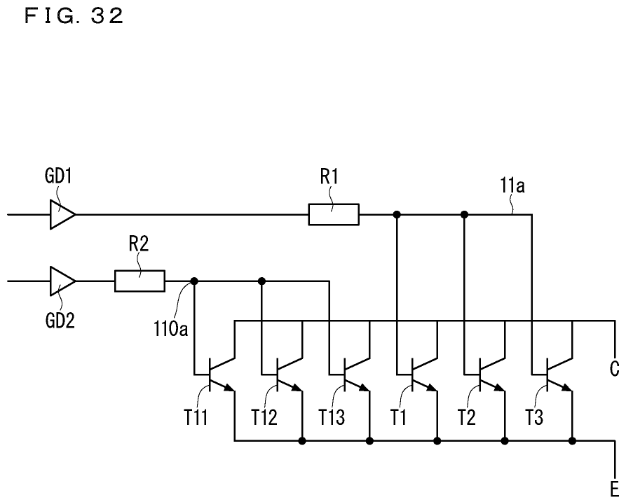

FIG. 32 is a circuit diagram for supplying a gate potential and a control gate potential in the RC-IGBT 1013 of FIG. 31. In FIG. 32, a plurality of transistors included in the RC-IGBT 1013 are represented as transistors T1 to T3 and transistors T11 to T13, gates of the transistors T1 to T3 are gate trench electrodes 11a, and gates of the transistors T11 to T13 are dummy trench electrodes 110a.

A gate potential is supplied from a gate driver GD1 to the gates of the transistors T1 to T3 via a resistor R1, and a control gate potential is supplied from a gate driver GD2 to the gates of the transistors T11 to T13 via a resistor R2. The resistor R1 and the resistor R2 have different resistance values from each other, and become different gate resistors for each electrode. By adjusting the carrier injection timing to shift the on-timing of some electrodes, this contributes to improvement of a loss.

### Fourteenth Preferred Embodiment

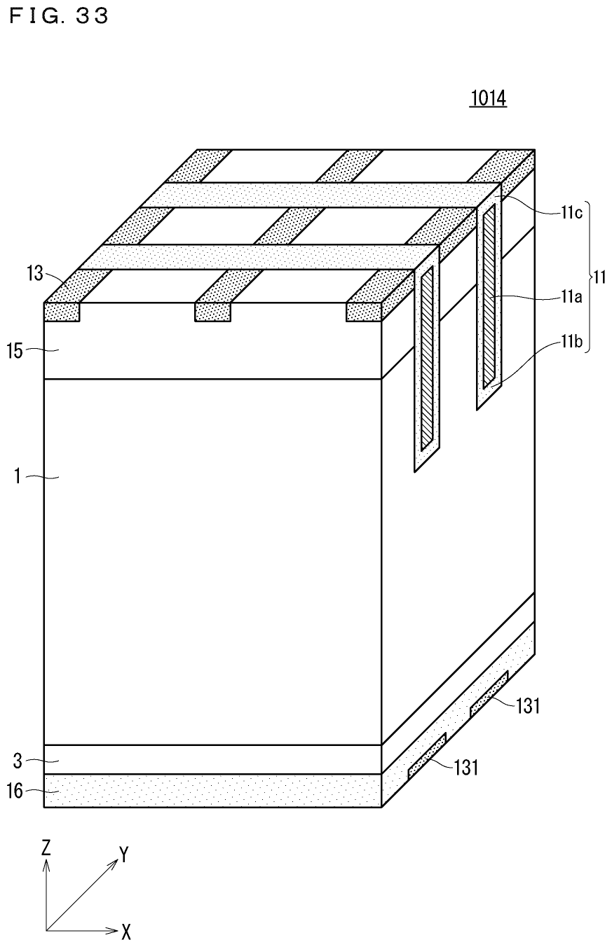

A configuration of an RC-IGBT 1014 according to a fourteenth preferred embodiment will be described with reference to FIG. 33. FIG. 33 is a cross-sectional perspective view of a region surrounded by a broken line X in FIG. 12. Note that, in FIG. 33, the same components as the components of the RC-IGBT 1001 described with reference to FIG. 15 are denoted by the same reference numerals, and redundant description is omitted.

In the RC-IGBT 1014 illustrated in FIG. 33, an n⁺-type back surface source layer 131 is provided on the second main surface of the semiconductor substrate that is a lower surface of the p-type collector layer 16. By providing the n⁺-type back surface source layer 131 and injecting carriers from the back surface, a power loss can be improved. That is, a back surface active trench gate (not illustrated) similar to the active trench gate 11 is provided from the p-type collector layer 16 side, and a control gate potential is supplied from a gate driver to a gate trench electrode of the back surface active trench gate. A circuit for supplying a control gate potential is similar to the circuit illustrated in FIG. 32.

By changing a timing of supplying the control gate potential and a timing of supplying the gate potential to the gate trench electrode 11a, the carrier injection timing is adjusted, and the on-timing of some electrodes is shifted. Thus, this contributes to improvement of a loss.

Note that the n⁺-type back surface source layer 131 and the back surface active trench gate are electrically insulated from the collector electrode 7 by an insulating film.

### Fifteenth Preferred Embodiment

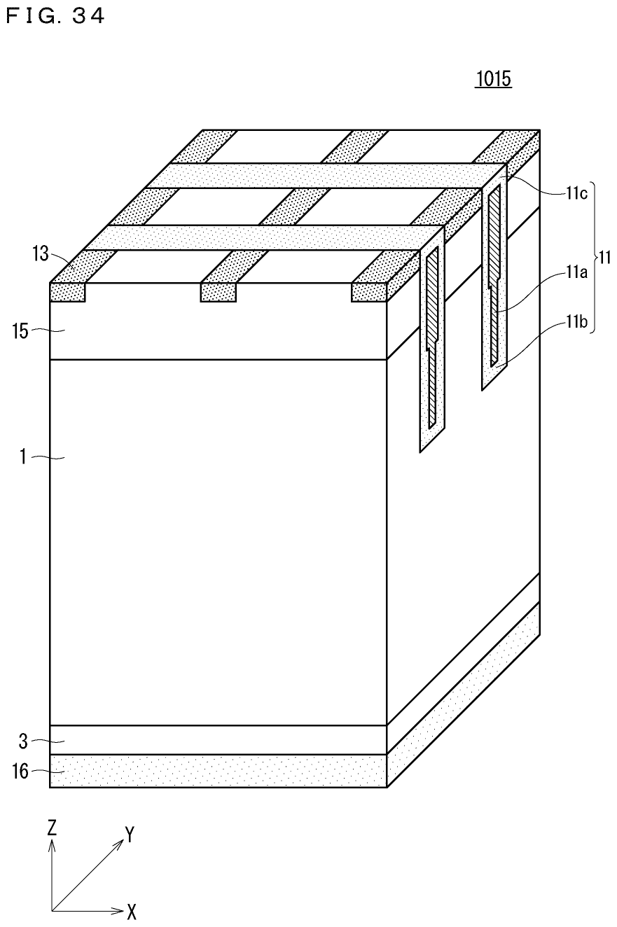

A configuration of an RC-IGBT 1015 according to a fifteenth preferred embodiment will be described with reference to FIG. 34. FIG. 34 is a cross-sectional perspective view of a region surrounded by a broken line X in FIG. 12. Note that, in FIG. 34, the same components as the components of the RC-IGBT 1001 described with reference to FIG. 15 are denoted by the same reference numerals, and redundant description is omitted.

In the RC-IGBT 1015 illustrated in FIG. 34, in the active trench gate 11, a gate width, which is a length of the gate trench electrode 11a in a Y-axis direction, is different between the upper side and the lower side in the Z-axis direction. That is, the gate width on the lower side than approximately a half of the entire length of the gate trench electrode 11a is narrower than the gate width on the upper side. In the portion having a narrower gate width, a thickness of the gate trench insulating film 11b is thicker by the narrower gate width.

Since the electric fields concentrate on the bottom portion of the active trench gate 11 and strong electric fields are applied, the gate trench insulating film 11b is likely to be damaged by the carriers accelerated at the time of occurrence of avalanche. However, in a portion on the lower side than approximately a half of the entire length of the gate trench electrode 11a, the thickness of the gate trench insulating film 11b is thick. Thus, the electric fields are relaxed, and the reliability for the gate trench insulating film 11b can be improved.

Since the gate width on the upper side than approximately a half of the entire length of the gate trench electrode 11a is not different from the gate width of the gate trench electrode 11a according to other preferred embodiments, the thickness of the gate trench insulating film 11b between the p-type base layer 15 and the gate trench electrode 11a does not change, and it is not necessary to change the basic design as the semiconductor device. The configurations of the first to fifteenth preferred embodiments described above can be freely combined and used.

### Sixteenth Preferred Embodiment

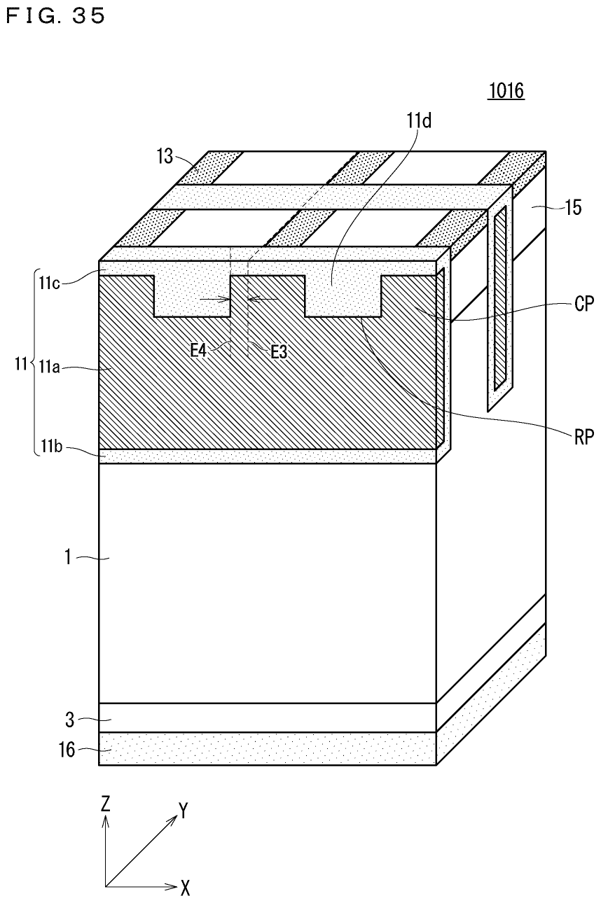

A configuration of an RC-IGBT 1016 according to a sixteenth preferred embodiment will be described with reference to FIG. 35. FIG. 35 is a cross-sectional perspective view of a region surrounded by a broken line X in FIG. 12. Note that, in FIG. 35, the same components as the components of the RC-IGBT 1001 described with reference to FIG. 16 are denoted by the same reference numerals, and redundant description is omitted.

In the RC-IGBT 1016 illustrated in FIG. 35, in a case where a position of one end portion of the n⁺-type source layer 13 in the horizontal direction (X-axis direction) is defined as a position E3 and a position of one end portion of the protrusion portion CP of the gate trench electrode 11a in the horizontal direction that is close to the position of the one end portion is defined as a position E4, a distance from the n⁺-type source layer 13 to the position E4 is set to be 0.5 μm or shorter with reference to the position E3. In a case where the distance between the end portion of the n⁺-type source layer 13 and the end portion of the protrusion portion CP in the horizontal direction is brought close to a certain distance or shorter, a saturation current decreases depending on the width of the protrusion portion CP.

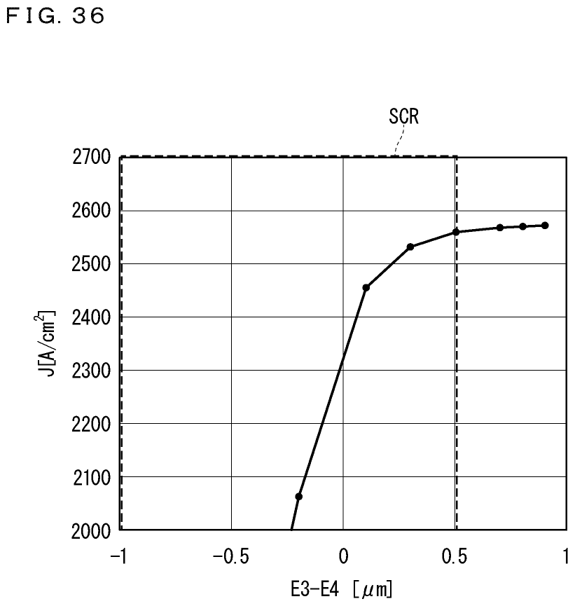

FIG. 36 is a diagram illustrating a relationship between a distance (E3-E4) and a current density of the saturation current, the distance (E3-E4) being a distance between the position E3 of one end portion of the n⁺-type source layer 13 in the horizontal direction and the position E4 of one end portion of the protrusion portion CP in the horizontal direction. In FIG. 36, a horizontal axis is the distance E3-E4 (μm), and a vertical axis is the current density J (A/cm²). In a region SCR surrounded by a broken line in FIG. 36, when E3-E4 is 0.5 μm or shorter, a decrease in the current density J of the saturation current approaches a linear shape, and it is shown that the saturation current can be controlled. That is, the saturation current can be reduced as the width, which is the length of the protrusion portion CP in the X-axis direction, is narrowed.

Thereby, it is possible to provide a semiconductor device capable of adjusting the saturation current only by changing the electrode shape of the gate trench electrode 11a without changing the arrangement of the n⁺-type source layer 13. This semiconductor device has good controllability of the gate capacitance ratio Cgc/Cge, and can further reduce the number of mask design processes required for design changes.

### Seventeenth Preferred Embodiment

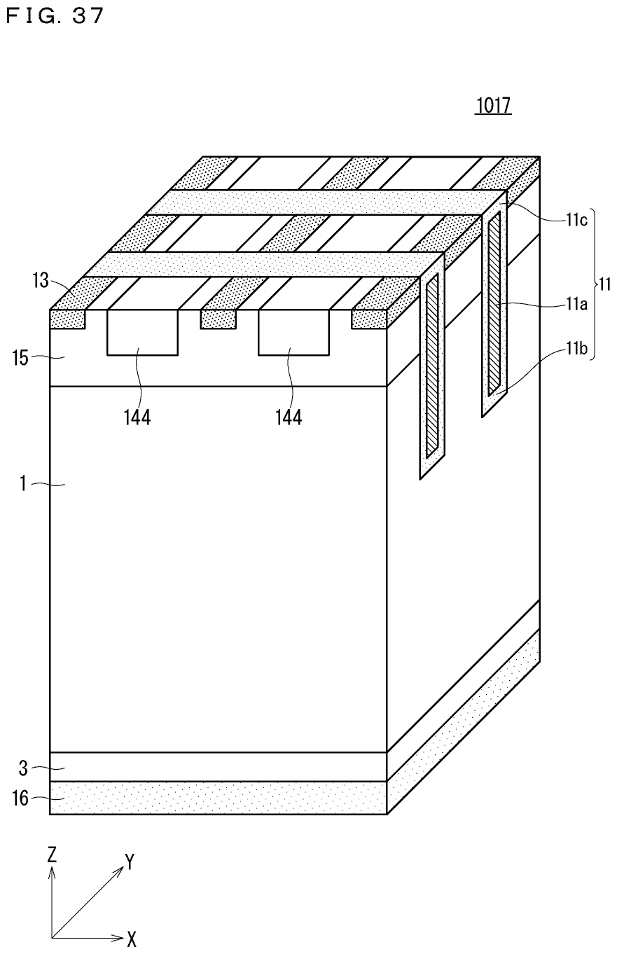

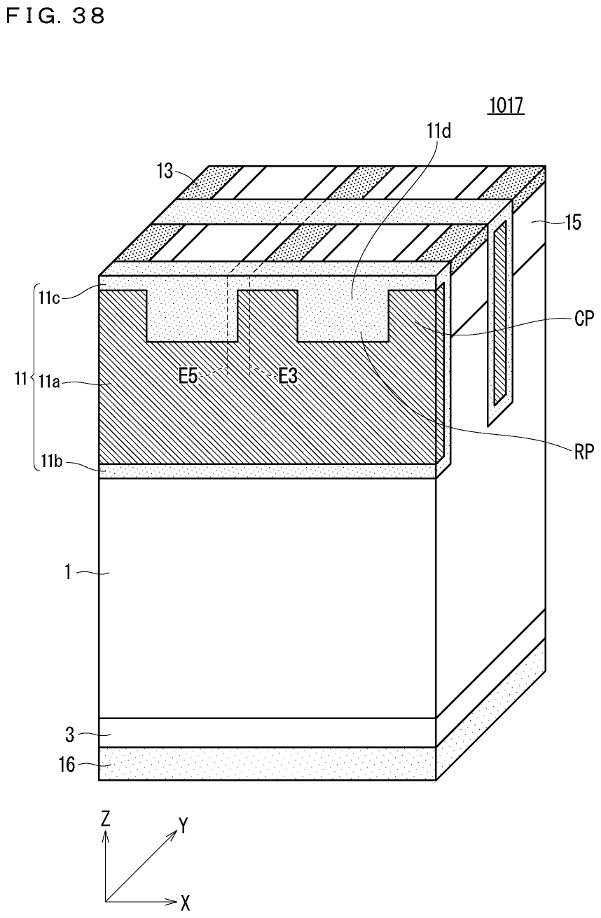

A configuration of an RC-IGBT 1017 according to a seventeenth preferred embodiment will be described with reference to FIG. 37 and FIG. 38. FIG. 37 is a cross-sectional perspective view corresponding to a region surrounded by a broken line X in FIG. 12, and FIG. 38 is a cross-sectional perspective view along the extending direction of the active trench gate 11. Note that, in FIG. 38, the same components as the components of the RC-IGBT 1001 described with reference to FIG. 16 are denoted by the same reference numerals, and redundant description is omitted.

In the RC-IGBT 1017 illustrated in FIG. 37 and FIG. 38, a p⁺-type contact layer 144 thicker than the n⁺-type source layer 13 is provided between the n⁺-type source layers 13 provided to be parallel to each other.

In the RC-IGBT 1016 illustrated in FIG. 38, in a case where a position of one end portion of the n⁺-type source layer 13 in the horizontal direction (X-axis direction) is defined as a position E3 and a position of one end portion of the p⁺-type contact layer 144 in the horizontal direction that is close to the position of the one end portion is defined as a position E5, a distance from the n⁺-type source layer 13 to the position E5 is set to be 0.5 μm or shorter with reference to the position E3. In a case where the distance between the end portion of the n⁺-type source layer 13 in the horizontal direction and the end portion of the p⁺-type contact layer 144 approaches a certain distance or shorter, the saturation current decreases depending on the width of the p⁺-type contact layer 144. That is, the saturation current can be regulated by bringing the p⁺-type contact layer 144 close to the n⁺-type source layer 13.

Thereby, it is possible to provide a semiconductor device capable of adjusting the saturation current only by changing the width, which is the length of the p⁺-type contact layer 144 in the X-axis direction, without changing the arrangement of the n⁺-type source layer 13. This semiconductor device has good controllability of the gate capacitance ratio Cgc/Cge, and can further reduce the number of mask design processes required for design changes.

The configurations of the sixteenth and seventeenth preferred embodiments described above can be freely combined and used.

### Eighteenth Preferred Embodiment

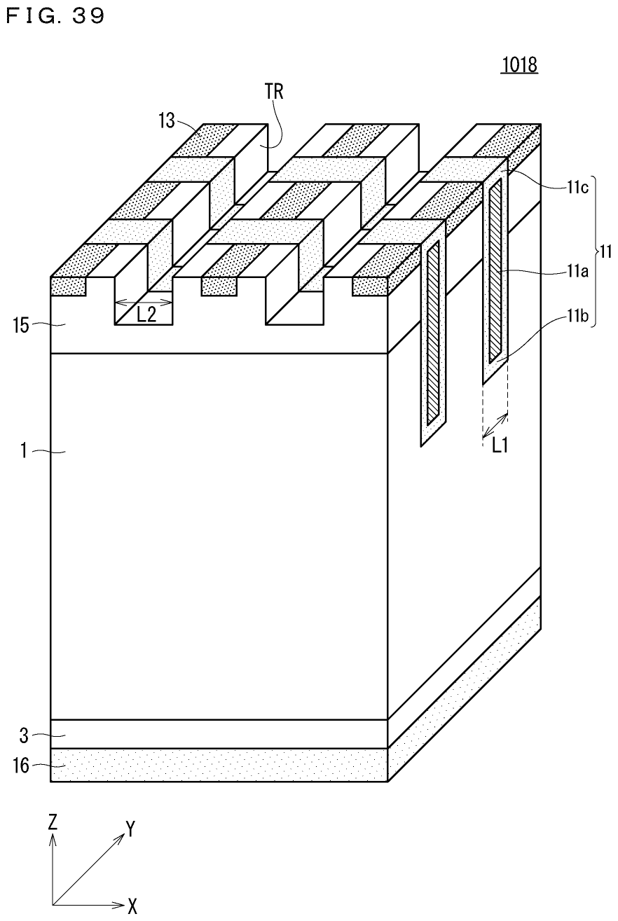

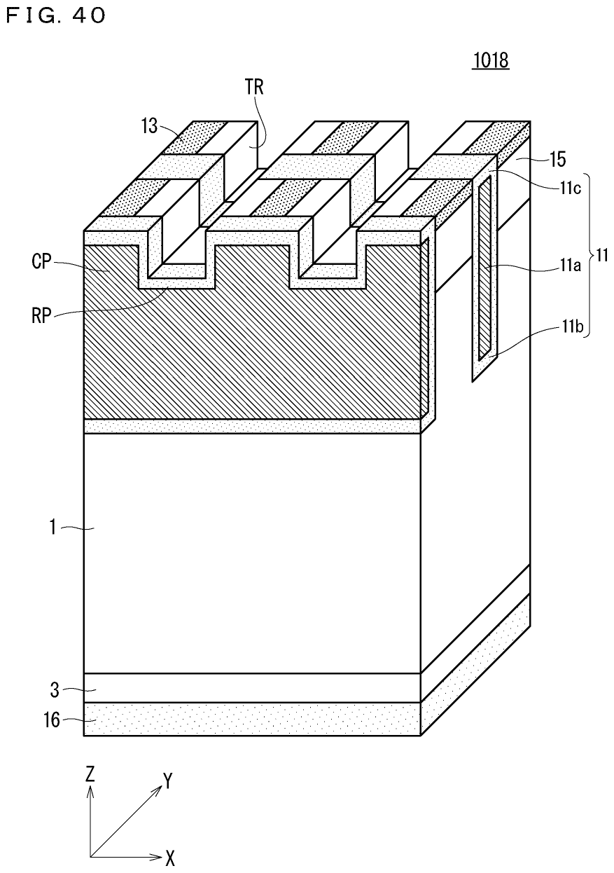

A configuration of an RC-IGBT 1018 according to an eighteenth preferred embodiment will be described with reference to FIG. 39 and FIG. 40. FIG. 39 is a cross-sectional perspective view corresponding to a region surrounded by a broken line X in FIG. 12. FIG. 40 is a cross-sectional perspective view along the extending direction of the active trench gate 11. Note that, in FIG. 40, the same components as the components of the RC-IGBT 1001 described with reference to FIG. 16 are denoted by the same reference numerals, and redundant description is omitted.

In the RC-IGBT 1018 illustrated in FIG. 39, the p-type base layer 15 between the n⁺-type source layers 13 provided to be parallel to each other is removed to a predetermined depth, and the active trench gate 11 is provided so as to have a partial step such that an upper surface of the upper insulating film 11c has the same depth as an upper surface of the removed p-type base layer 15. Thus, a trench TR parallel to the n⁺-type source layer 13 is formed.

As illustrated in FIG. 40, the RC-IGBT 1018 is the same as the RC-IGBT 1001 according to the first preferred embodiment in that the gate trench electrode 11a in the active trench gate 11 is formed in a comb shape. The recess portion RP and the protrusion portion CP are alternately provided, but the upper insulating film 11c is provided along the surfaces of the recess portion RP and the protrusion portion CP. The upper surface of the upper insulating film 11c is the same surface as the upper surface of the p-type base layer 15.

The RC-IGBT 1018 is the same as the RC-IGBT 1001 according to the first preferred embodiment in that the shape of the gate trench electrode 11a is the same, and is also the same as the RC-IGBT 1001 in that the gate capacitance ratio Cgc/Cge can be linearly controlled by changing the area of the recess portion RP. However, in the RC-IGBT 1018, the trench TR is provided, and the lower end of the trench TR is provided at a position higher than the lower end of the p-type base layer 15 in the Z-axis direction.

Therefore, the barrier metal 5 and the emitter electrode 6 (not illustrated) can be disposed at positions deeper than the n⁺-type source layer 13, and it is possible to increase the hole extraction efficiency at the time of turn-off when the RC-IGBT 1018 operates as an IGBT.

Further, in the RC-IGBT 1018 illustrated in FIG. 39, the width L2 which is the length of the trench TR in the X-axis direction is set to be wider than the width L1 which is the length of the active trench gate 11 in the Y-axis direction. Therefore, it is possible to further increase the hole extraction efficiency at the time of turn-off when the RC-IGBT 1018 operates as an IGBT.

### Nineteenth Preferred Embodiment

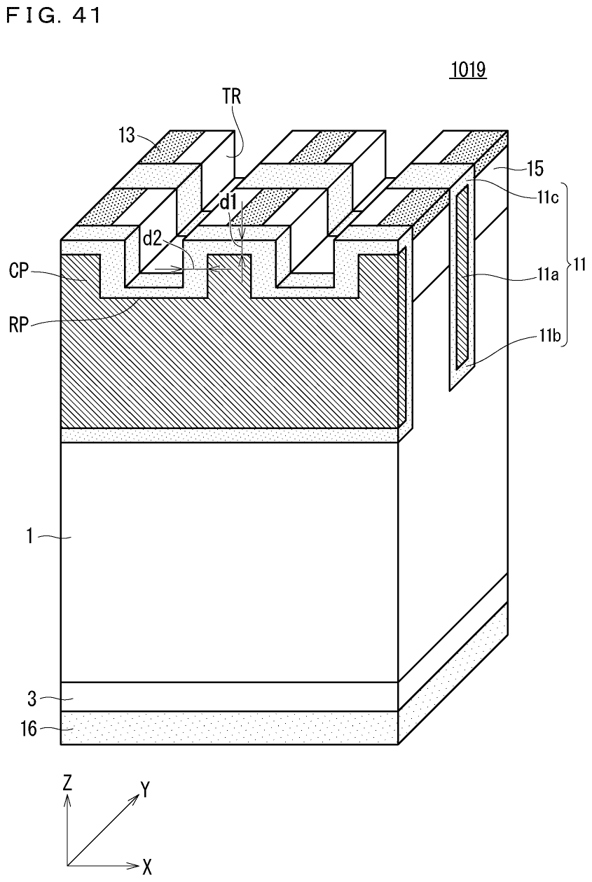

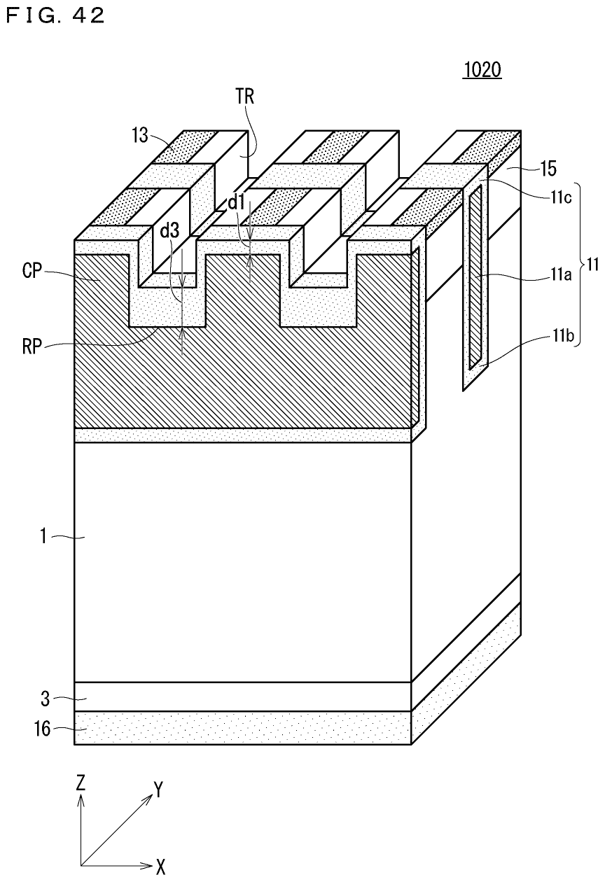

A configuration of an RC-IGBT 1019 according to a nineteenth preferred embodiment will be described with reference to FIG. 41. FIG. 41 is a cross-sectional perspective view corresponding to FIG. 40 of the eighteenth preferred embodiment. In FIG. 41, the same components as the components of the RC-IGBT 1018 described with reference to FIG. 40 are denoted by the same reference numerals, and redundant description is omitted.

In the RC-IGBT 1019 illustrated in FIG. 41, a thickness d2 of the upper insulating film 11c that covers side surfaces of the protrusion portion CP of the gate trench electrode 11a is formed to be thicker than a thickness d1 of the upper insulating film 11c that covers an upper surface of the protrusion portion CP, and a corner portion of the trench TR is covered with the upper insulating film 11c thicker than the other portions.

Depending on an operation of the IGBT, the electric fields may concentrate at the corner portion of the trench TR. A large current flows due to concentration of the electric fields, and self-heating may lead to destruction. For this reason, it is desirable that the corner portion of the trench TR and the corner portion of the gate trench electrode 11a are separated from each other. In the RC-IGBT 1019, the electric field concentration at the corner portion of the trench TR can be alleviated by adjusting the thickness of the upper insulating film 11c.

### Twentieth Preferred Embodiment

A configuration of an RC-IGBT 1020 according to a twentieth preferred embodiment will be described with reference to FIG. 42. FIG. 42 is a cross-sectional perspective view corresponding to FIG. 40 of the eighteenth preferred embodiment. In FIG. 42, the same components as the components of the RC-IGBT 1018 described with reference to FIG. 40 are denoted by the same reference numerals, and redundant description is omitted.

In the RC-IGBT 1020 illustrated in FIG. 42, a thickness d3 of the upper insulating film 11c that covers the recess portion RP of the gate trench electrode 11a is formed to be thicker than a thickness d1 of the upper insulating film 11c that covers the upper surface of the protrusion portion CP, and the corner portion of the trench TR is covered with the upper insulating film 11c thicker than the other portions.

Depending on an operation of the IGBT, the electric fields may concentrate at the corner portion of the trench TR. A large current flows due to concentration of the electric fields, and self-heating may lead to breakdown. For this reason, it is desirable that the corner portion of the trench TR and the corner portion of the gate trench electrode 11a are separated from each other. In the RC-IGBT 1020, the electric field concentration at the corner portion of the trench TR can be alleviated by adjusting the thickness of the upper insulating film 11c.

### Twenty-First Preferred Embodiment

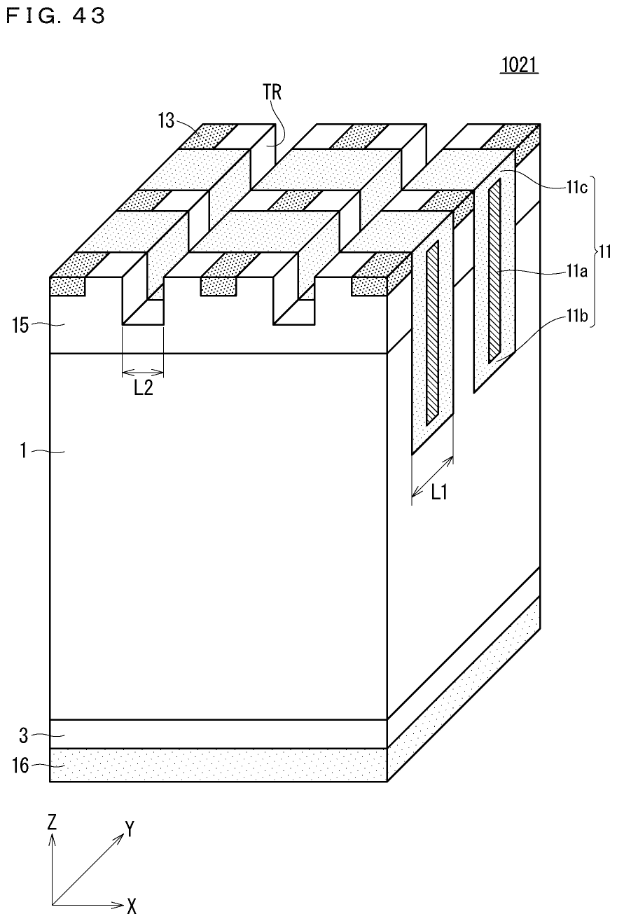

A configuration of an RC-IGBT 1021 according to a twenty-first preferred embodiment will be described with reference to FIG. 43. FIG. 43 is a cross-sectional perspective view corresponding to FIG. 39 of the eighteenth preferred embodiment. In FIG. 43, the same components as the components of the RC-IGBT 1018 described with reference to FIG. 39 are denoted by the same reference numerals, and redundant description is omitted.

In the RC-IGBT 1021 illustrated in FIG. 43, a width L1 that is a length of the active trench gate 11 in the Y-axis direction is set to be wider than a width L2 that is a length of the trench TR in the X-axis direction. Therefore, the width of the gate trench electrode 11a can be increased. Further, an electrode material that is difficult to form a thick film, for example, tungsten can be used as the gate trench electrode 11a, and warpage of a wafer can be controlled.

As in the RC-IGBT 1018 illustrated in FIG. 39, by forming the width L2 of the trench TR to be wider than the width L1 of the active trench gate 11, it is possible to further increase the hole extraction efficiency at the time of turn-off when operating as an IGBT, as compared with the RC-IGBT 1021.

### Twenty-Second Preferred Embodiment

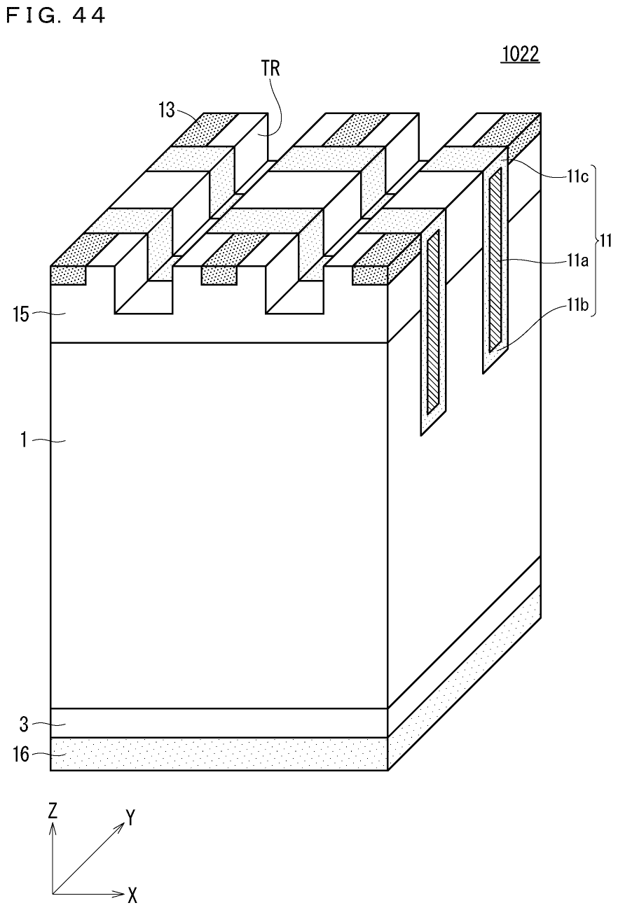

A configuration of an RC-IGBT 1022 according to a twenty-second preferred embodiment will be described with reference to FIG. 44. FIG. 44 is a cross-sectional perspective view corresponding to FIG. 39 of the eighteenth preferred embodiment. In FIG. 44, the same components as the components of the RC-IGBT 1018 described with reference to FIG. 39 are denoted by the same reference numerals, and redundant description is omitted.

In the RC-IGBT 1018 illustrated in FIG. 39, the n⁺-type source layer 13 is always provided on an upper layer of the mesa of the p-type base layer 15 sandwiched between the trenches TR, but the n⁺-type source layer 13 is not necessarily provided on the entire upper layer of the mesa as in the RC-IGBT 1022 illustrated in FIG. 44. That is, the p-type base layer 15 may include a region in which the n⁺-type source layer 13 is not provided in a region corresponding to the position at which the protrusion portion CP is provided. By reducing the number of n⁺-type source layers 13 to be disposed, the saturation current can be adjusted without changing the gate capacitance ratio Cgc/Cge.

### Twenty-Third Preferred Embodiment

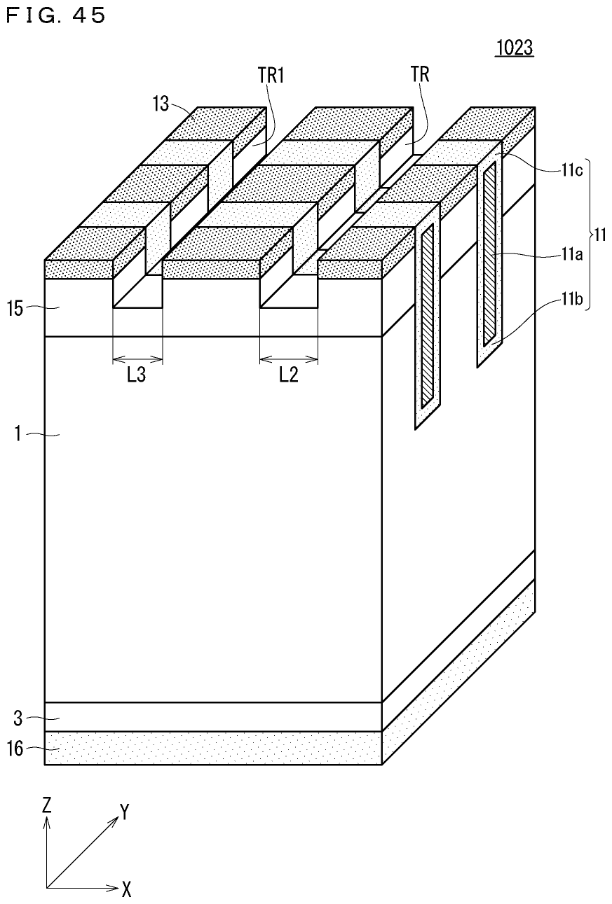

A configuration of an RC-IGBT 1023 according to a twenty-third preferred embodiment will be described with reference to FIG. 45. FIG. 45 is a cross-sectional perspective view corresponding to FIG. 39 of the eighteenth preferred embodiment. In FIG. 45, the same components as the components of the RC-IGBT 1018 described with reference to FIG. 39 are denoted by the same reference numerals, and redundant description is omitted.

In the RC-IGBT 1018 described with reference to FIG. 39, the trenches TR between the n⁺-type source layers 13 provided to be parallel to each other have the same trench width, which is the length of the trench TR in the X-axis direction, but in the RC-IGBT 1023 illustrated in FIG. 45, the trench TR and the trench TR1 have different trench widths. That is, in the example of FIG. 45, the trench width L3 of the trench TR1 is set to be narrower than the trench width L2 of the adjacent trench TR.

By providing the trench TR1 having a narrow width, the number of the trenches TR1 and the trenches TR can be increased. Since the carrier injection amount is determined by a region where the n⁺-type source layer 13 and the protrusion portion CP of the gate trench electrode 11a face each other, in a case where the number of trenches increases, more carriers can be injected by the increased number of trenches. Thus, the carrier injection amount can be adjusted.

In addition, in the RC-IGBT 1023 illustrated in FIG. 45, the n⁺-type source layer 13 is provided on the entire upper layer of the mesa of the p-type base layer 15. Thereby, patterning of the n⁺-type source layer 13 becomes unnecessary, and a manufacturing cost can be reduced.

### Twenty-Fourth Preferred Embodiment

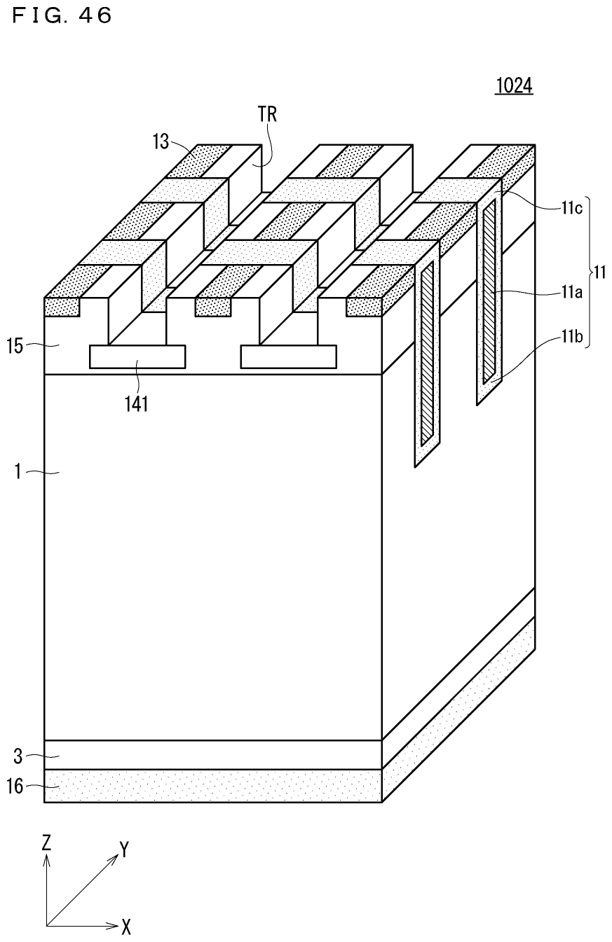

A configuration of an RC-IGBT 1024 according to a twenty-fourth preferred embodiment will be described with reference to FIG. 46. FIG. 46 is a cross-sectional perspective view corresponding to FIG. 39 of the eighteenth preferred embodiment. In FIG. 46, the same components as the components of the RC-IGBT 1018 described with reference to FIG. 39 are denoted by the same reference numerals, and redundant description is omitted.

In the RC-IGBT 1024 illustrated in FIG. 46, a p⁺-type contact layer 141 is provided at least at a bottom portion of the trench TR. Thereby, it is possible to increase the hole extraction efficiency at the time of turn-off when the RC-IGBT 1024 operates as an IGBT.

### Twenty-Fifth Preferred Embodiment

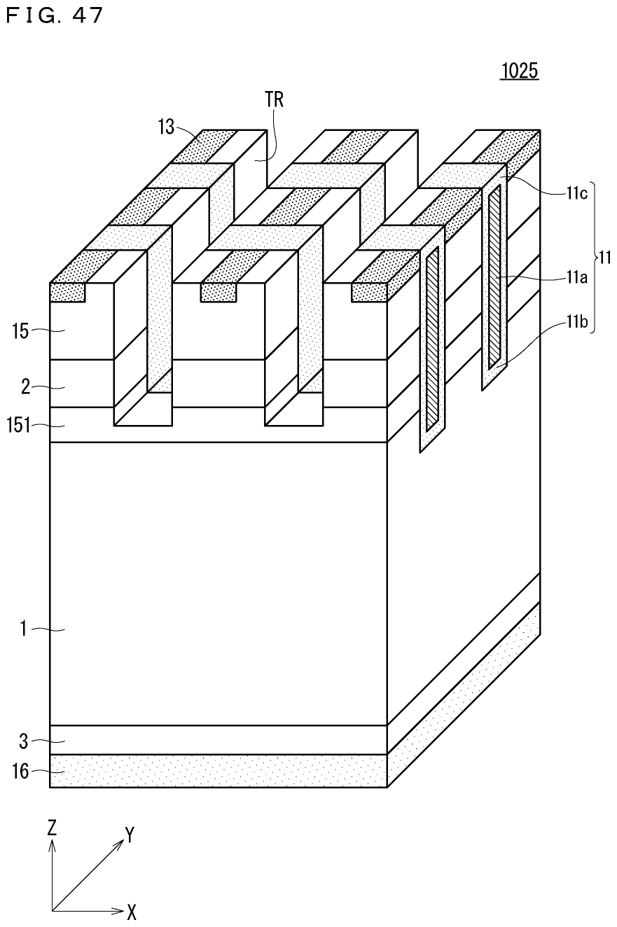

A configuration of an RC-IGBT 1025 according to a twenty-fifth preferred embodiment will be described with reference to FIG. 47. FIG. 47 is a cross-sectional perspective view corresponding to FIG. 39 of the eighteenth preferred embodiment. In FIG. 47, the same components as the components of the RC-IGBT 1018 described with reference to FIG. 39 are denoted by the same reference numerals, and redundant description is omitted.

In the RC-IGBT 1025 illustrated in FIG. 47, an n-type carrier accumulation layer 2 is provided under the p-type base layer 15, and a p-type bottom base layer 151 is provided under the n-type carrier accumulation layer 2. By providing the n-type carrier accumulation layer 2 having a higher impurity concentration on the n⁻-type drift layer 1, the carrier density on the emitter side increases due to the carrier accumulation effect of preventing holes from being extracted to the emitter side and accumulating holes. Thereby, conductivity modulation is promoted, and thus, the on-state voltage when the RC-IGBT 1025 operates as an IGBT can be lowered.

The impurity concentration of the p-type bottom base layer 151 is set to be equal to or lower than the impurity concentration of the p-type base layer 15. By providing the p-type bottom base layer 151, the withstand voltage of the RC-IGBT 1025 can be improved, and thus, the leakage current can be reduced.

Further, in the RC-IGBT 1025, a lower end of the trench reaches into the p-type bottom base layer 151. Therefore, the barrier metal 5 and the emitter electrode 6 (not illustrated) can be disposed at positions deeper than the n⁺-type source layer 13, and it is possible to increase the hole extraction efficiency at the time of turn-off when the RC-IGBT 1025 operates as an IGBT.

The configurations of the eighteenth to twenty-fifth preferred embodiments described above can be freely combined and used.

### Twenty-Sixth Preferred Embodiment

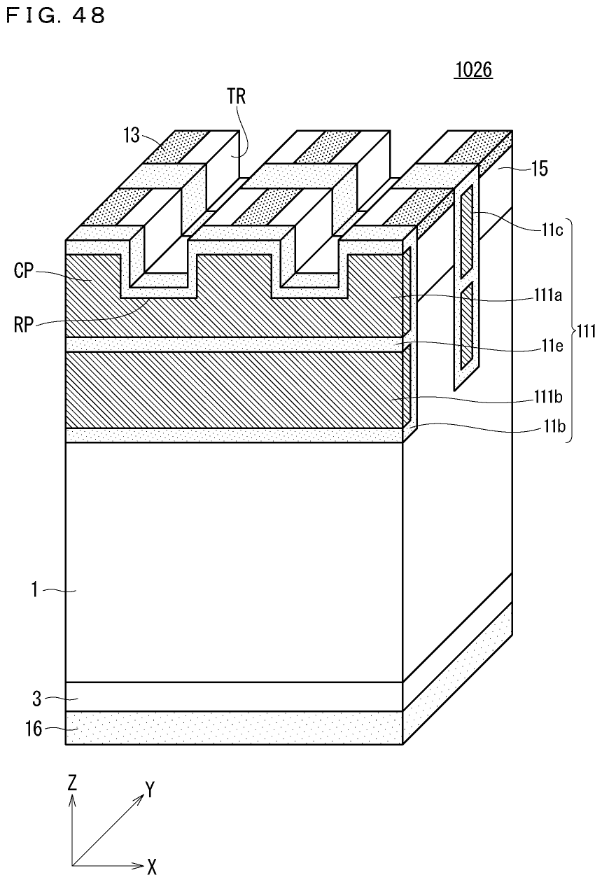

A configuration of an RC-IGBT 1026 according to a twenty-sixth preferred embodiment will be described with reference to FIG. 48. FIG. 48 is a cross-sectional perspective view in which the active trench gate 11 is changed to the active trench gate 111 in a region surrounded by a broken line X in FIG. 12, and is a cross-sectional perspective view along the extending direction of the active trench gate 111. Note that, in FIG. 48, the same components as the components of the RC-IGBT 1001 described with reference to FIG. 16 are denoted by the same reference numerals, and redundant description is omitted.

The active trench gate 111 is a split gate (two-stage gate) including a lower electrode 111b that extends in the Z-axis direction from a position lower than the lower end of the p-type base layer 15 toward the n-type buffer layer 3 and an upper electrode 111a that extends from a position higher than the lower electrode 111b in the Z-axis direction toward the n⁺-type source layer 13 in a trench formed on the semiconductor substrate via the gate trench insulating film 11b. The upper electrode 111a and the lower electrode 111b are insulated from each other by an intermediate insulating film 11e.

The upper electrode 111a is formed in a comb shape similarly to the gate trench electrode 11a illustrated in FIG. 16 and the like. That is, in the upper electrode 111a, a recess portion RP that is recessed toward a side opposite to the n⁺-type source layer 13 and a protrusion portion CP that protrudes toward the n⁺-type source layer 13 side are alternately provided along the extending direction of the active trench gate 111. An upper insulating film 11c is provided on the upper electrode 111a.

In the RC-IGBT 1026 illustrated in FIG. 48, the p-type base layer 15 between the n⁺-type source layers 13 provided to be parallel to each other is removed to a predetermined depth, and the active trench gate 111 is provided so as to have a partial step such that an upper surface of the upper insulating film 11c has the same depth as an upper surface of the removed p-type base layer 15. Thus, a trench TR parallel to the n⁺-type source layer 13 is formed.

In the RC-IGBT 1026, by using a split gate as the active trench gate 111, the upper electrode 111a and the lower electrode 111b can be used as separate electrodes, and the gate capacitance ratio Cgc/Cge can be controlled in a wider range.

For example, in a case where a gate potential is applied to the gate wiring to which the upper electrode 111a is connected and an emitter potential is applied to the emitter electrode to which the lower electrode 111b is connected, the lower electrode 111b does not function as an active trench gate, and the feedback capacitance Cgc can be lowered. Further, the radiation noise can be lowered by lowering di/dt, which is a temporal variation of a drain current i at the time of turn-on when the RC-IGBT 1026 operates as an IGBT.

In addition, for example, in a case where the upper electrode 111a is connected to the gate wiring and the lower electrode 111b is also connected to the gate wiring, when a gate potential is applied, the gate potential is applied to the upper electrode 111a and the lower electrode 111b via the gate wiring. In this case, it is possible to perform adjustment of capacitance characteristics, such as increasing of the feedback capacitance Cgc.

### Twenty-Seventh Preferred Embodiment

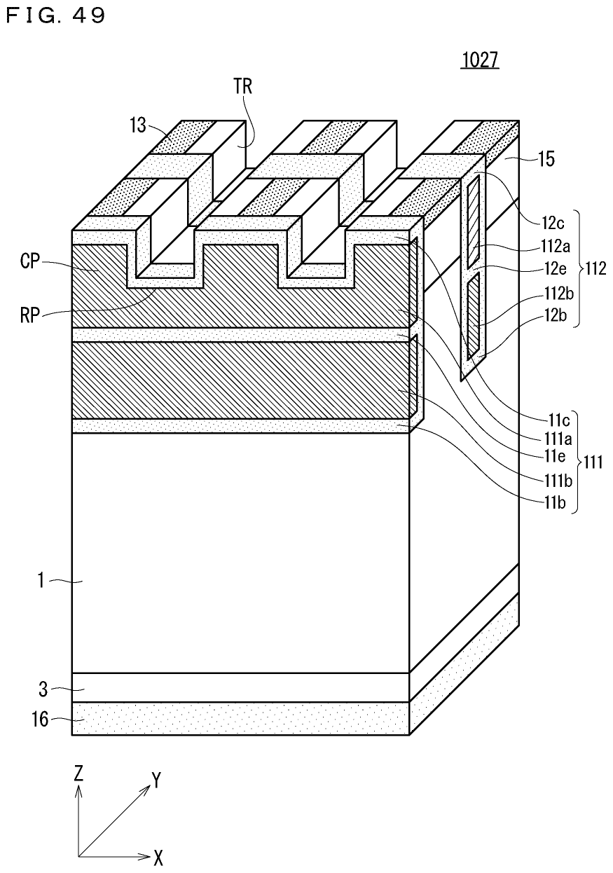

A configuration of an RC-IGBT 1027 according to a twenty-seventh preferred embodiment will be described with reference to FIG. 49. FIG. 49 is a cross-sectional perspective view in which the active trench gate 11 is changed to an active trench gate 111 and a dummy trench gate 112 in a region surrounded by a broken line X in FIG. 12, and is a cross-sectional perspective view along the extending direction of the active trench gate 111. Note that, in FIG. 49, the same components as the components of the RC-IGBT 1026 described with reference to FIG. 48 are denoted by the same reference numerals, and redundant description is omitted.

The dummy trench gate 112 is a split gate (two-stage gate) including a dummy lower electrode 112b that extends from a position lower than the lower end of the p-type base layer 15 in the Z-axis direction toward the n-type buffer layer 3 and a dummy upper electrode 112a that extends from a position higher than the dummy lower electrode 112b in the Z-axis direction toward the n⁺-type source layer 13 in a dummy trench formed on the semiconductor substrate via a dummy trench insulating film 12b. The dummy upper electrode 112a and the dummy lower electrode 112b are insulated from each other by a dummy intermediate insulating film 12e.

As illustrated in FIG. 49, in the RC-IGBT 1027, the p-type base layer 15 between the n⁺-type source layers 13 provided to be parallel to each other is removed to a predetermined depth, and the active trench gate 111 and the dummy trench gate 112 are provided so as to have a partial step such that the upper insulating film 11c and the dummy upper insulating film 12c have the same depth as the upper surface of the p-type base layer 15 from which the upper surface is removed. Thus, a trench TR parallel to the n⁺-type source layer 13 is formed.

In the RC-IGBT 1027, by using the split gate as the active trench gate 111 and the dummy trench gate 112, the upper electrode 111a and the lower electrode 111b can be used as separate electrodes, and the dummy upper electrode 112a and the dummy lower electrode 112b can be used as separate electrodes.

In the active trench gate 111, the potential as described in the twenty-sixth preferred embodiment is applied to the upper electrode 111a and the lower electrode 111b. In the dummy trench gate 112, the dummy upper electrode 112a is connected to the control gate and the control gate potential is applied, and the dummy lower electrode 112b is connected to the emitter electrode or the gate wiring. By connecting the dummy upper electrode 112a of the dummy trench gate 112 to the control gate, carrier injection can be controlled, and thus, a power loss can be reduced.

### Twenty-Eighth Preferred Embodiment

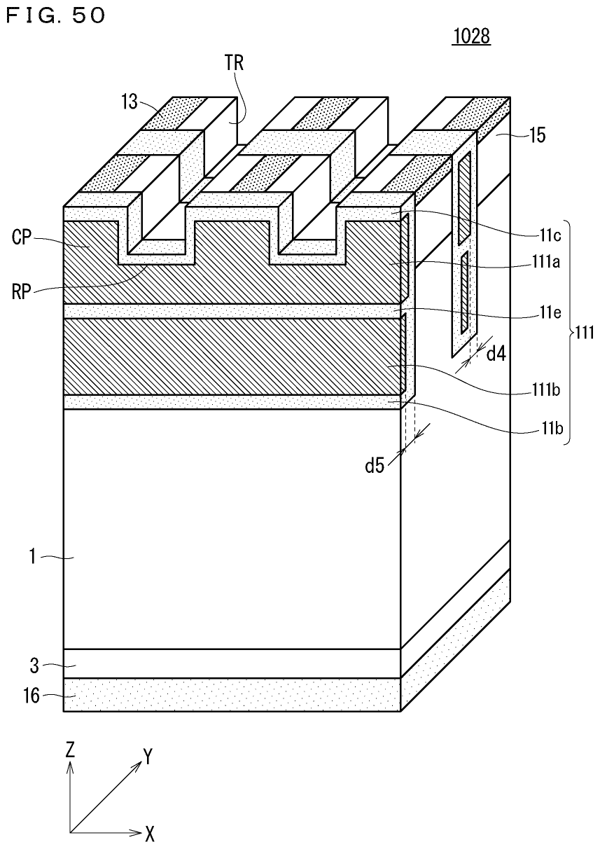

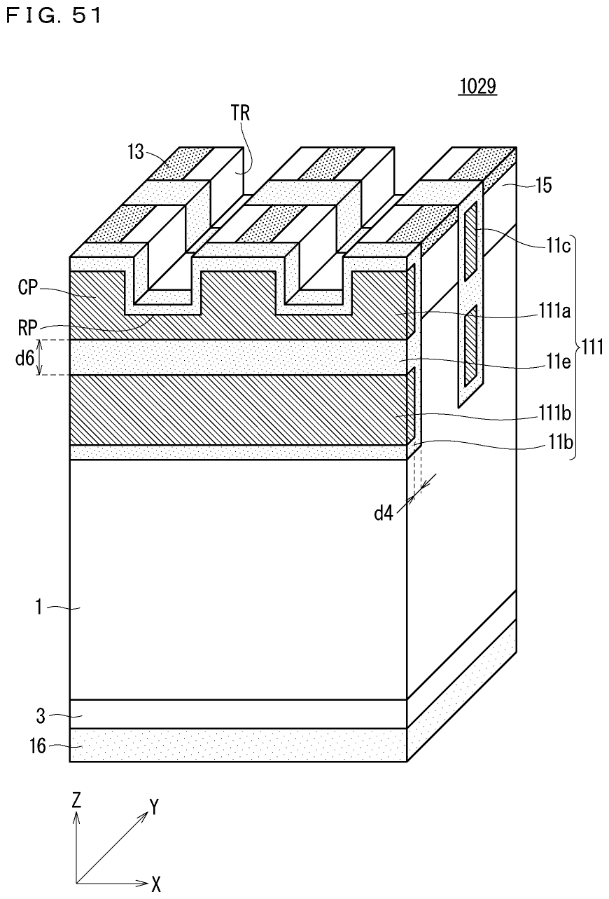

A configuration of an RC-IGBT 1028 according to a twenty-eighth preferred embodiment will be described with reference to FIG. 50. FIG. 50 is a cross-sectional perspective view in which the active trench gate 11 is changed to the active trench gate 111 in a region surrounded by a broken line X in FIG. 12, and is a cross-sectional perspective view along the extending direction of the active trench gate 111. Note that, in FIG. 50, the same components as the components of the RC-IGBT 1026 described with reference to FIG. 48 are denoted by the same reference numerals, and redundant description is omitted.

As illustrated in FIG. 50, in the RC-IGBT 1028, a thickness of the gate trench insulating film 11b varies depending on the location. That is, a thickness d5 of the gate trench insulating film 11b in contact with the lower electrode 111b is set to be thicker than a thickness d4 of the gate trench insulating film 11b in contact with the upper electrode 111a.

Since the electric fields concentrate on the bottom portion of the active trench gate 111 and strong electric fields are applied, the gate trench insulating film 11b is likely to be damaged by the carriers accelerated at the time of occurrence of avalanche. However, by increasing the thickness of the gate trench insulating film 11b in contact with the lower electrode 111b, the electric fields are relaxed, and the reliability of the gate trench insulating film 11b can be improved. Note that the thickness d5 may be, for example, approximately 1.1 times to 1.5 times the thickness d4, but is not limited thereto.

Further, even in the active trench gate 111 of the RC-IGBT 1027 illustrated in FIG. 49, the thickness of the gate trench insulating film 11b in contact with the lower electrode 111b can be set to be thicker than the thickness of the gate trench insulating film 11b in contact with the upper electrode 111a, and even in the dummy trench gate 112, the thickness of the dummy trench insulating film 12b in contact with the dummy lower electrode 112b can be set to be thicker than the thickness of the dummy trench insulating film 12b in contact with the dummy upper electrode 112a.

### Twenty-Ninth Preferred Embodiment

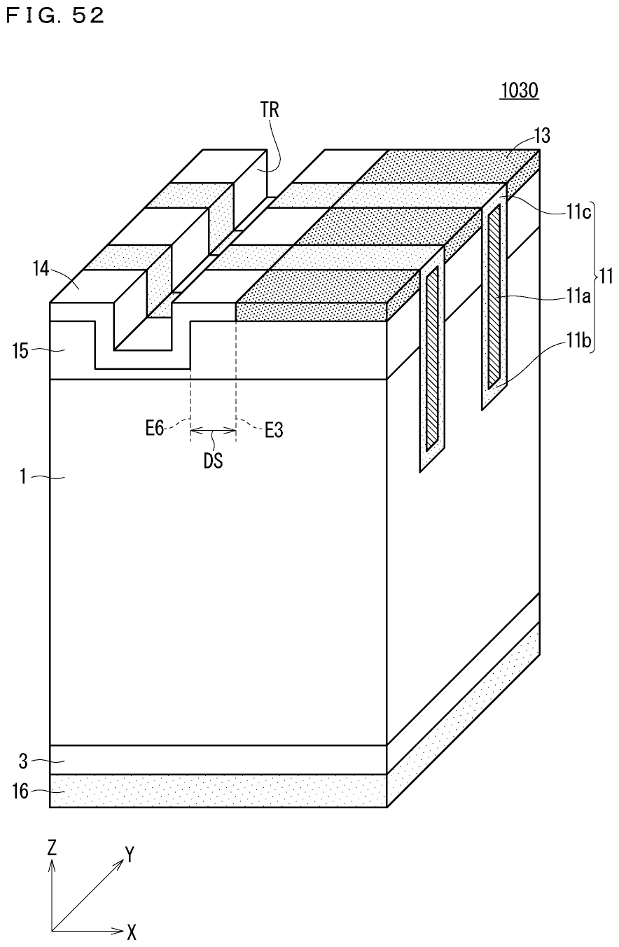

A configuration of an RC-IGBT 1029 according to a twenty-ninth preferred embodiment will be described with reference to FIG. 51. FIG. 51 is a cross-sectional perspective view in which the active trench gate 11 is changed to the active trench gate 111 in a region surrounded by a broken line X in FIG. 12, and is a cross-sectional perspective view along the extending direction of the active trench gate 111. Note that, in FIG. 51, the same components as the components of the RC-IGBT 1026 described with reference to FIG. 48 are denoted by the same reference numerals, and redundant description is omitted.

As illustrated in FIG. 51, in the RC-IGBT 1029, a thickness d6 of the intermediate insulating film 11e is set to be thicker than a thickness d4 of the gate trench insulating film 11b. There is a case where different potentials are applied to the upper electrode 111a and the lower electrode 111b. In this case, a potential difference is generated between both electrodes, and an electric field is generated between the upper electrode 111a and the lower electrode 111b. However, by increasing the thickness d6 of the intermediate insulating film 11e, the electric field is relaxed, and the reliability of the intermediate insulating film 11e can be improved. Note that the thickness d6 may be, for example, approximately 1.1 times to 2 times the thickness d4, but is not limited thereto.

Further, even in the active trench gate 111 and the dummy trench gate 112 of the RC-IGBT 1027 illustrated in FIG. 49, the thicknesses of the intermediate insulating film 11e and the dummy intermediate insulating film 12e can be set to be thicker than the thicknesses of the gate trench insulating film 11b and the dummy trench insulating film 12b.

### Thirtieth Preferred Embodiment

A configuration of an RC-IGBT 1030 according to a thirtieth preferred embodiment will be described with reference to FIG. 52. FIG. 52 is a cross-sectional perspective view corresponding to a region surrounded by a broken line X in FIG. 12. Note that, in FIG. 52, the same components as the components of the RC-IGBT 1001 described with reference to FIG. 16 are denoted by the same reference numerals, and redundant description is omitted.

In the RC-IGBT 1030 illustrated in FIG. 52, a p⁺-type contact layer 14 that is provided to be parallel to the n⁺-type source layer 13 is provided, and a trench TR in which the active trench gate 11 at a portion intersecting with the p⁺-type contact layer 14 is retracted in the Z-axis direction is provided.

In the trench TR, the active trench gate 11 is provided so as to have a partial step such that the upper surface of the upper insulating film 11c has the same depth as the upper surface of the recessed p⁺-type contact layer 14.

The RC-IGBT 1030 is the same as the RC-IGBT 1001 according to the first preferred embodiment in that the shape of the gate trench electrode 11a is the same, and is also the same as the RC-IGBT 1001 in that the gate capacitance ratio Cgc/Cge can be linearly controlled by changing the area of the recess portion RP. However, in the RC-IGBT 1030, the trench TR is provided, and a lower end of the trench TR is provided at a position higher than the lower end of the p-type base layer 15 in the Z-axis direction.

As illustrated in FIG. 52, in the cross section in the extending direction of the active trench gate 11, a distance DS between a position E3 of an end portion of the n⁺-type source layer 13 on the p⁺-type contact layer 14 side and a position E6 of an outer side surface of the p⁺-type contact layer 14 included in the trench TR is set to be 0.5 μm or shorter.

The saturation current can be adjusted by adjusting the distance between the p⁺-type contact layer 14 and the n⁺-type source layer 13. That is, as described in the sixteenth preferred embodiment with reference to FIG. 36, the saturation current can be reduced by reducing the width which is the length of the protrusion portion CP of the gate trench electrode 11a in the X-axis direction. This corresponds to setting the distance DS between the position E3 of the end portion of the n⁺-type source layer 13 and the position E6 of the outer side surface of the p⁺-type contact layer 14 to 0.5 μm or shorter.

Thereby, it is possible to provide a semiconductor device capable of adjusting the saturation current by changing the arrangement of the n⁺-type source layer 13. In addition, the same effect can be obtained by bringing the position of the outer side surface of the p⁺-type contact layer 14 closer to the n⁺-type source layer 13, and thus, the design of the saturation current can be changed without changing the gate capacitance ratio Cgc/Cge. Thereby, the number of design change processes can be reduced.

### Thirty-First Preferred Embodiment

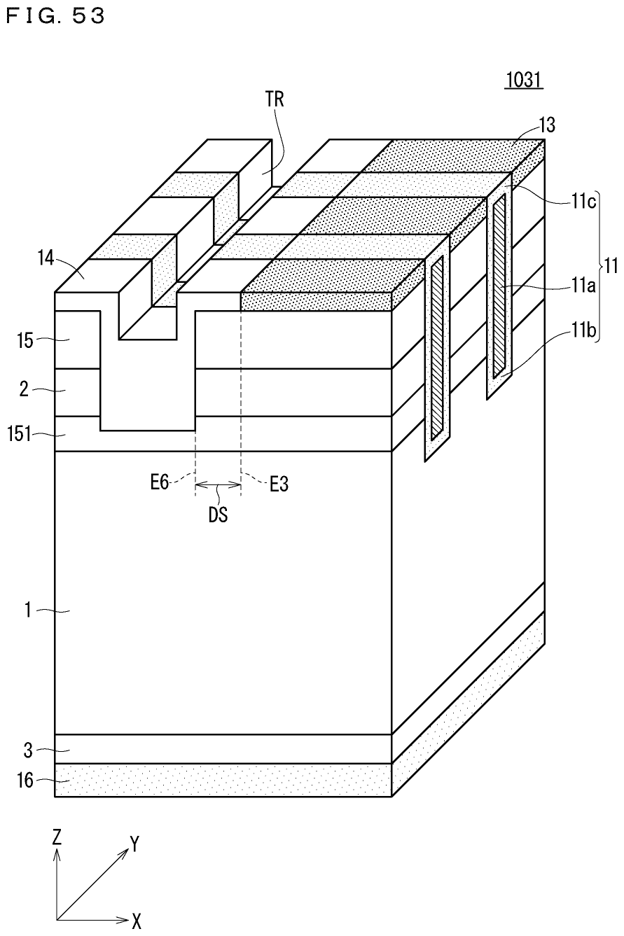

A configuration of an RC-IGBT 1031 according to a thirty-first preferred embodiment will be described with reference to FIG. 53. FIG. 53 is a cross-sectional perspective view corresponding to a region surrounded by a broken line X in FIG. 12. Note that, in FIG. 53, the same components as the components of the RC-IGBT 1030 described with reference to FIG. 52 are denoted by the same reference numerals, and redundant description is omitted.

In the RC-IGBT 1031 illustrated in FIG. 53, the n-type carrier accumulation layer 2 is provided under the p-type base layer 15, and the p-type bottom base layer 151 is provided under the n-type carrier accumulation layer 2. The lower end of the p⁺-type contact layer 14 included in the trench TR is provided at a position higher than the lower end of the p-type bottom base layer 151 in the Z-axis direction. In addition, the lower end of the trench TR is provided at a position higher than the lower end of the p-type base layer 15 in the Z-axis direction.

By providing the n-type carrier accumulation layer 2 having a higher impurity concentration on the n⁻-type drift layer 1, the carrier density on the emitter side increases due to the carrier accumulation effect of preventing holes from being extracted to the emitter side and accumulating holes. Thus, conductivity modulation is promoted, and the on-state voltage when the RC-IGBT 1031 operates as an IGBT can be lowered.

The impurity concentration of the p-type bottom base layer 151 is set to be equal to or lower than the impurity concentration of the p-type base layer 15. By providing the p-type bottom base layer 151, the withstand voltage of the RC-IGBT 1031 can be improved, and thus, the leakage current can be reduced.

Even in the RC-IGBT 1031, in the cross section in the extending direction of the active trench gate 11, the distance DS between the position E3 of the end portion of the n⁺-type source layer 13 on the p⁺-type contact layer 14 side and the position E6 of the end portion of the p⁺-type contact layer 14 included in the trench TR, that is, the position of the outer side surface of the p⁺-type contact layer 14 is set to be 0.5 μm or shorter.

Thereby, it is possible to provide a semiconductor device capable of adjusting the saturation current by changing the arrangement of the n⁺-type source layer 13. In addition, the same effect can be obtained by bringing the position of the end portion of the p⁺-type contact layer 14 included in the trench TR closer to the n⁺-type source layer 13, and thus, the design of the saturation current can be changed without changing the gate capacitance ratio Cgc/Cge. Thereby, the number of design change processes can be reduced. In addition, by adjusting the saturation current, the hole extraction effect at the time of turn-off when the RC-IGBT 1031 operates as an IGBT can be improved.

The configurations of the twenty-sixth to thirty-first preferred embodiments described above can be freely combined and used.

### Thirty-Second Preferred Embodiment

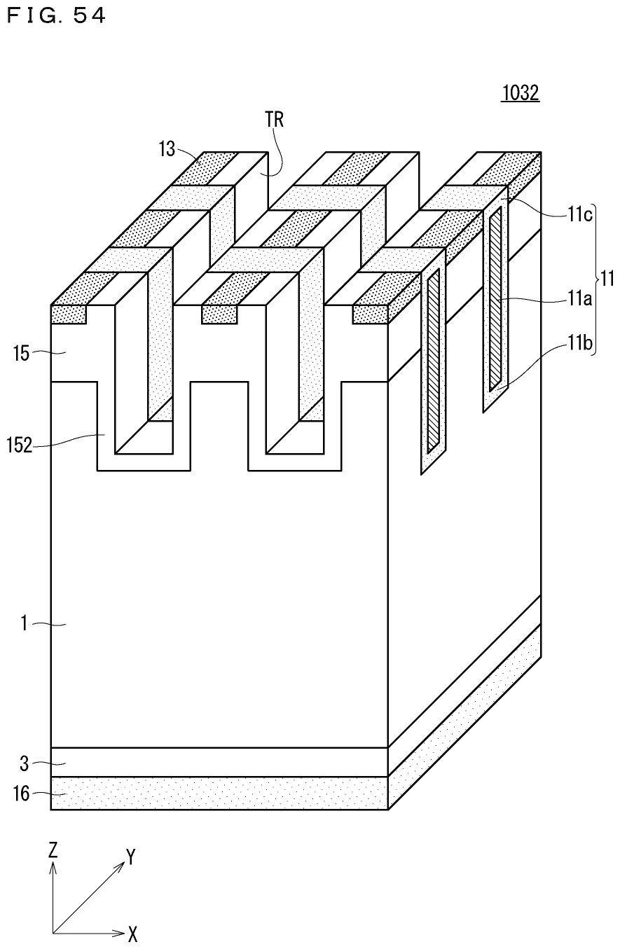

A configuration of an RC-IGBT 1032 according to a thirty-second preferred embodiment will be described with reference to FIG. 54. FIG. 54 is a cross-sectional perspective view corresponding to a region surrounded by a broken line X in FIG. 12. Note that, in FIG. 54, the same components as the components of the RC-IGBT 1001 described with reference to FIG. 15 are denoted by the same reference numerals, and redundant description is omitted.

In the RC-IGBT 1032 illustrated in FIG. 54, a trench TR that penetrates the p-type base layer 15 between the n⁺-type source layers 13 provided to be parallel to each other and reaches into the n⁻-type drift layer 1 is provided. The side surfaces and the bottom surface of the trench TR in the n⁻-type drift layer 1 are covered with the p-type barrier layer 152. The impurity concentration of the p-type barrier layer 152 is set to be equal to or lower than the impurity concentration of the p-type base layer 15.

The active trench gate 11 is provided so as to have a partial step such that the upper surface of the upper insulating film 11c has the same depth as the upper surface of the p-type barrier layer 152.

By forming the deep trench TR that reaches into the n⁻-type drift layer 1, the hole extraction effect at the time of turn-off when the RC-IGBT 1032 operates as an IGBT can be further improved.

In addition, by protecting the side surfaces and the bottom surface of the trench TR in the n⁻-type drift layer 1 with the p-type barrier layer 152, a trench contact that is deeper than the p-type base layer 15 can be realized. Thus, it is possible to provide a semiconductor device that has a high hole extraction effect and can optimize the capacitance characteristics as in the RC-IGBT 1001 according to the first preferred embodiment.

### Thirty-Third Preferred Embodiment

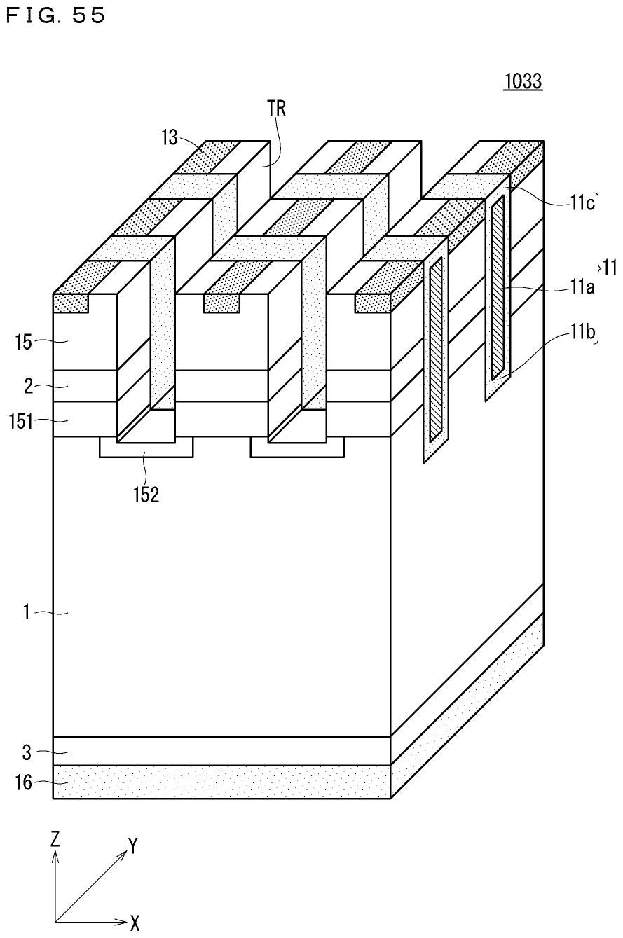

A configuration of an RC-IGBT 1033 according to a thirty-third preferred embodiment will be described with reference to FIG. 55. FIG. 55 is a cross-sectional perspective view corresponding to a region surrounded by a broken line X in FIG. 12. Note that, in FIG. 55, the same components as the components of the RC-IGBT 1032 described with reference to FIG. 54 are denoted by the same reference numerals, and redundant description is omitted.

In the RC-IGBT 1033 illustrated in FIG. 55, the n-type carrier accumulation layer 2 is provided under the p-type base layer 15, and the p-type bottom base layer 151 is provided under the n-type carrier accumulation layer 2. The trench TR penetrates the p-type base layer 15, the n-type carrier accumulation layer 2, and the p-type bottom base layer 151, and reaches into the n⁻-type drift layer 1. At least the bottom surface of the trench TR in the n⁻-type drift layer 1 is covered with the p-type barrier layer 152.

By providing the n-type carrier accumulation layer 2 having a higher impurity concentration on the n⁻-type drift layer 1, the carrier density on the emitter side increases due to the carrier accumulation effect of preventing holes from being extracted to the emitter side and accumulating holes. Thus, conductivity modulation is promoted, and the on-state voltage when the RC-IGBT 1033 operates as an IGBT can be lowered.

The impurity concentration of the p-type bottom base layer 151 is set to be equal to or lower than the impurity concentration of the p-type base layer 15. By providing the p-type bottom base layer 151, the withstand voltage of the RC-IGBT 1033 can be improved, and thus, the leakage current can be reduced.

By forming the deep trench TR that reaches into the n⁻-type drift layer 1, the hole extraction effect at the time of turn-off when the RC-IGBT 1033 operates as an IGBT can be further improved.

In addition, by protecting the side surfaces and the bottom surface of the trench TR in the n⁻-type drift layer 1 with the p-type barrier layer 152, a trench contact that is deeper than the p-type base layer 15 can be realized. Thus, it is possible to provide a semiconductor device that has a high hole extraction effect and can optimize the capacitance characteristics as in the RC-IGBT 1001 according to the first preferred embodiment.

### Thirty-Fourth Preferred Embodiment

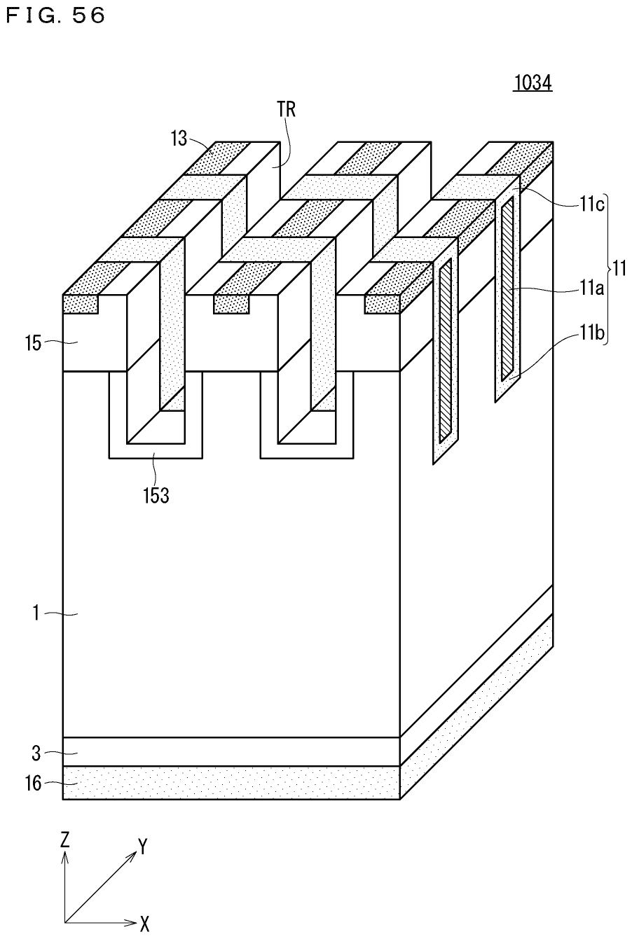

A configuration of an RC-IGBT 1034 according to a thirty-fourth preferred embodiment will be described with reference to FIG. 56. FIG. 56 is a cross-sectional perspective view corresponding to a region surrounded by a broken line X in FIG. 12. Note that, in FIG. 56, the same components as the components of the RC-IGBT 1032 described with reference to FIG. 54 are denoted by the same reference numerals, and redundant description is omitted.

In the RC-IGBT 1034 illustrated in FIG. 56, the side surfaces and the bottom surface of the trench TR in the n⁻-type drift layer 1 are covered with a p⁺-type barrier layer 153. The impurity concentration of the p⁺-type barrier layer 153 is set to be higher than the impurity concentration of the p-type base layer 15.

By forming the deep trench TR that reaches into the n⁻-type drift layer 1, the hole extraction effect at the time of turn-off when the RC-IGBT 1034 operates as an IGBT can be further improved.

In addition, by protecting the side surfaces and the bottom surface of the trench TR in the n⁻-type drift layer 1 with the p⁺-type barrier layer 153, a trench contact that is deeper than the p-type base layer 15 can be realized. Thus, it is possible to provide a semiconductor device that has a higher hole extraction effect and can optimize the capacitance characteristics as in the RC-IGBT 1001 according to the first preferred embodiment.

### Thirty-Fifth Preferred Embodiment

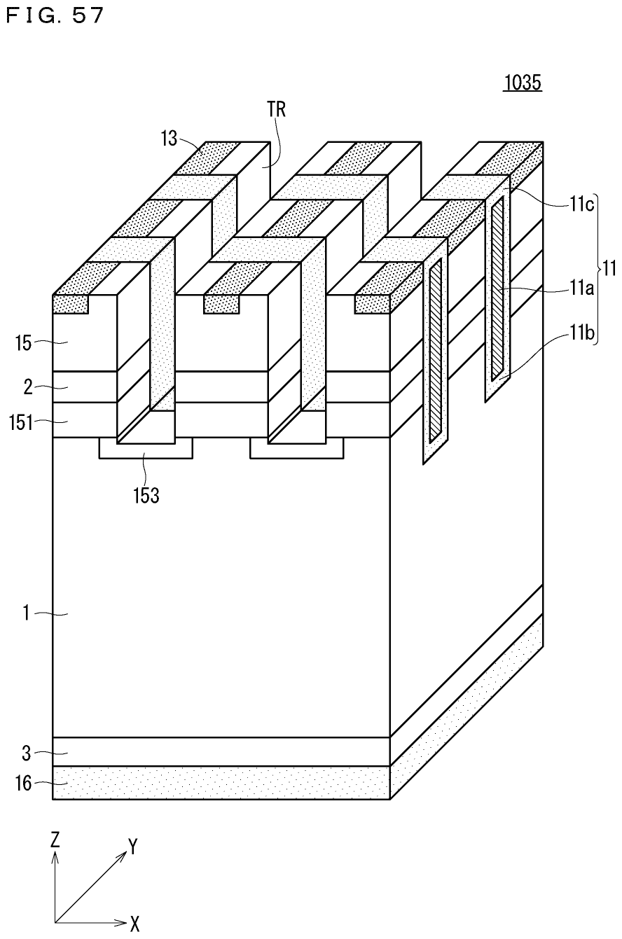

A configuration of an RC-IGBT 1035 according to a thirty-fifth preferred embodiment will be described with reference to FIG. 57. FIG. 57 is a cross-sectional perspective view corresponding to a region surrounded by a broken line X in FIG. 12. Note that, in FIG. 57, the same components as the components of the RC-IGBT 1032 described with reference to FIG. 54 are denoted by the same reference numerals, and redundant description is omitted.

In the RC-IGBT 1035 illustrated in FIG. 57, the n-type carrier accumulation layer 2 is provided under the p-type base layer 15, and the p-type bottom base layer 151 is provided under the n-type carrier accumulation layer 2. The trench TR penetrates the p-type bottom base layer 151 and reaches into the n⁻-type drift layer 1. The side surfaces and the bottom surface of the trench TR in the n⁻-type drift layer 1 are covered with a p⁺-type barrier layer 153. The impurity concentration of the p⁺-type barrier layer 153 is set to be higher than the impurity concentration of the p-type base layer 15.

By forming the deep trench TR that reaches into the n⁻-type drift layer 1, the hole extraction effect at the time of turn-off when the RC-IGBT 1035 operates as an IGBT can be further improved.

In addition, by protecting the side surfaces and the bottom surface of the trench TR in the n⁻-type drift layer 1 with the p⁺-type barrier layer 153, a trench contact that is deeper than the p-type base layer 15 can be realized. Thus, it is possible to provide a semiconductor device that has a higher hole extraction effect and can optimize the capacitance characteristics as in the RC-IGBT 1001 according to the first preferred embodiment.

### Thirty-Sixth Preferred Embodiment

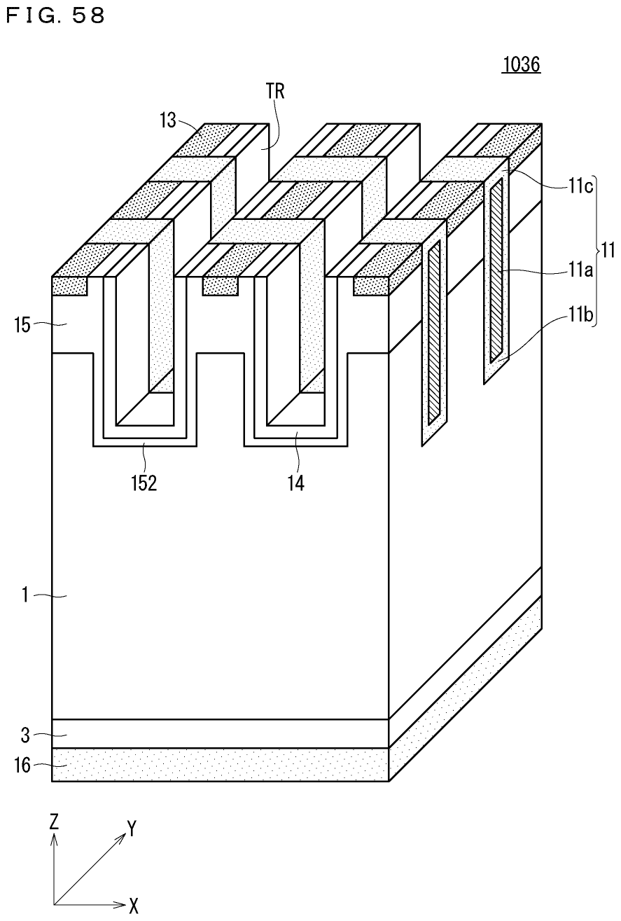

A configuration of an RC-IGBT 1036 according to a thirty-sixth preferred embodiment will be described with reference to FIG. 58. FIG. 58 is a cross-sectional perspective view corresponding to a region surrounded by a broken line X in FIG. 12. Note that, in FIG. 58, the same components as the components of the RC-IGBT 1032 described with reference to FIG. 54 are denoted by the same reference numerals, and redundant description is omitted.

In the RC-IGBT 1036 illustrated in FIG. 58, the trench TR that penetrates the p-type base layer 15 between the n⁺-type source layers 13 provided to be parallel to each other and reaches into the n⁻-type drift layer 1 is provided. The p⁺-type contact layer 14 is provided in the surface of the trench TR, and the side surfaces and the bottom surface of the p⁺-type contact layer 14 in the surface of the trench TR in the n⁻-type drift layer 1 are covered with the p-type barrier layer 152. The impurity concentration of the p-type barrier layer 152 is set to be equal to or lower than the impurity concentration of the p-type base layer 15.

By forming the deep trench TR that reaches into the n⁻-type drift layer 1, the hole extraction effect at the time of turn-off when the RC-IGBT 1035 operates as an IGBT can be further improved.

In addition, by covering the side surfaces and the bottom surface of the p⁺-type contact layer 14 in the n⁻-type drift layer 1 with the p-type barrier layer 152, the electric fields at the junction between the p-type layer and the n-type layer can be relaxed. That is, by stacking the p⁺-type contact layer 14 that is a p-type layer and the p-type barrier layer 152, the concentration gradient of the p-type impurities becomes gentle, and the electric fields generated at the junction with the n⁻-type drift layer 1 that is an n-type layer can be relaxed.

The configurations of the thirty-second to thirty-sixth preferred embodiments described above can be freely combined and used.

### Thirty-Seventh Preferred Embodiment

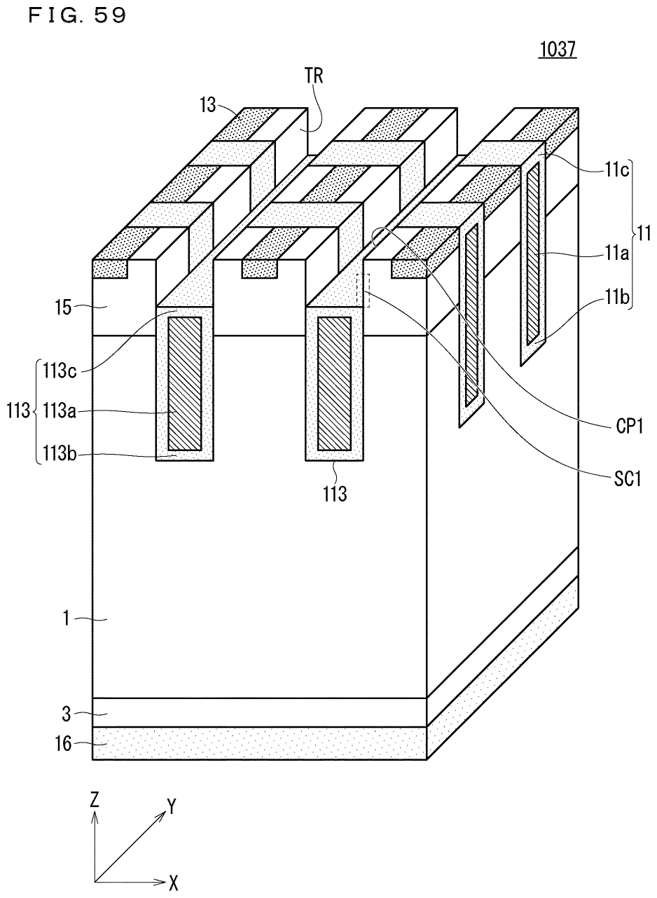

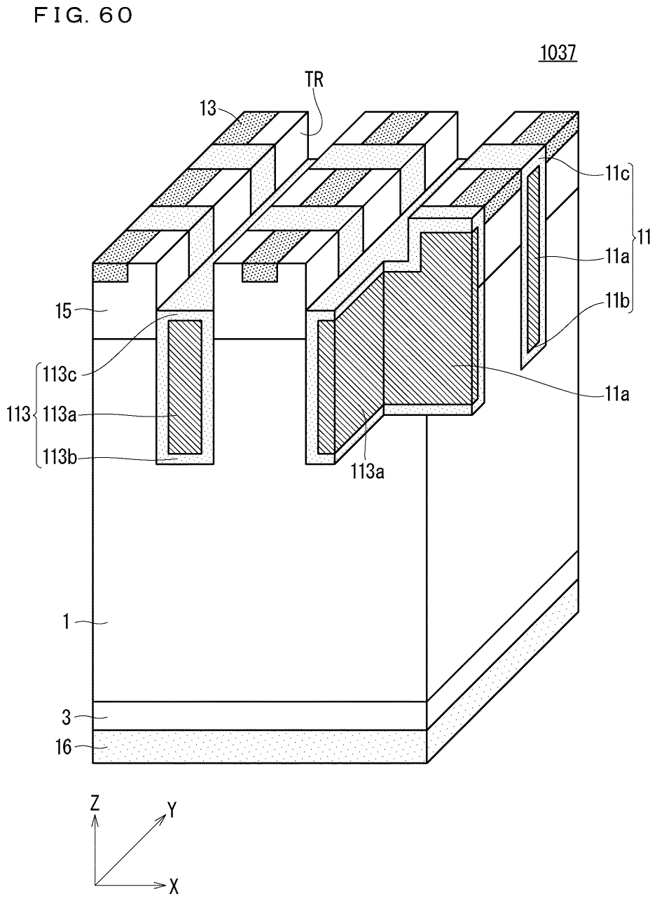

A configuration of an RC-IGBT 1037 according to a thirty-seventh preferred embodiment will be described with reference to FIG. 59 and FIG. 60. FIG. 59 is a cross-sectional perspective view corresponding to a region surrounded by a broken line X in FIG. 12. FIG. 60 is a cross-sectional perspective view along the extending direction of the active trench gate 11 and the extending direction of the trench electrode 113. Note that, in FIG. 60, the same components as the components of the RC-IGBT 1001 described with reference to FIG. 16 are denoted by the same reference numerals, and redundant description is omitted.

The RC-IGBT 1037 illustrated in FIG. 59 has a configuration in which a trench electrode 113 is embedded in the trench TR except for an upper portion of the trench TR, the TR being obtained by removing both the p-type base layer 15 and the n⁻-type drift layer 1 between the n⁺-type source layers 13 provided to be parallel to each other. The bottom portion of the trench TR reaches into the n⁻-type drift layer 1.

In the trench electrode 113, an electrode portion 113a is embedded in the trench TR via a trench insulating film 113b, and the electrode portion 113a is covered with a trench upper insulating film 113c. The electrode portion 113a faces the p-type base layer 15 and the n⁻-type drift layer 1 via the trench insulating film 113b.

The active trench gate 11 is provided so as to have a partial step in the trench TR such that the upper surface of the upper insulating film 11c has the same depth as the upper surface of the trench upper insulating film 113c of the trench electrode 113. As illustrated in FIG. 60, the gate trench electrode 11a intersects with the electrode portion 113a in the trench TR, and the gate trench electrode 11a and the electrode portion 113a have a mesh shape in plan view when viewed from above in the Z-axis direction.

A portion of the upper portion of the trench TR where the trench electrode 113 is not embedded forms a contact portion CP1, and the p-type base layer 15 on the side surface of the contact portion CP1 forms a side contact portion SC1. As illustrated in FIG. 59 and FIG. 60, the bottom surface of the contact portion CP1 is covered with the trench upper insulating film 113c and the upper insulating film 11c, and the holes cannot be extracted. However, the side contact portion SC1 is formed of the p-type base layer 15, and thus, the side contact portion SC1 has a function of extracting holes.

It is possible to control the gate capacitance ratio Cgc/Cge while improving an injection enhancement effect (IE effect) by the gate trench electrode 11a of the active trench gate 11. The IE effect refers to the same effect as the carrier accumulation effect.

In addition, by providing the trench electrode 113 in the trench TR, the IE effect can be improved by reducing a portion where the p-type base layer 15 is exposed in the contact portion CP1. That is, a portion where the p-type base layer 15 is exposed is reduced, and thus, a resistance component to the emitter electrode is increased, and the carrier accumulation effect (IE effect) is improved.

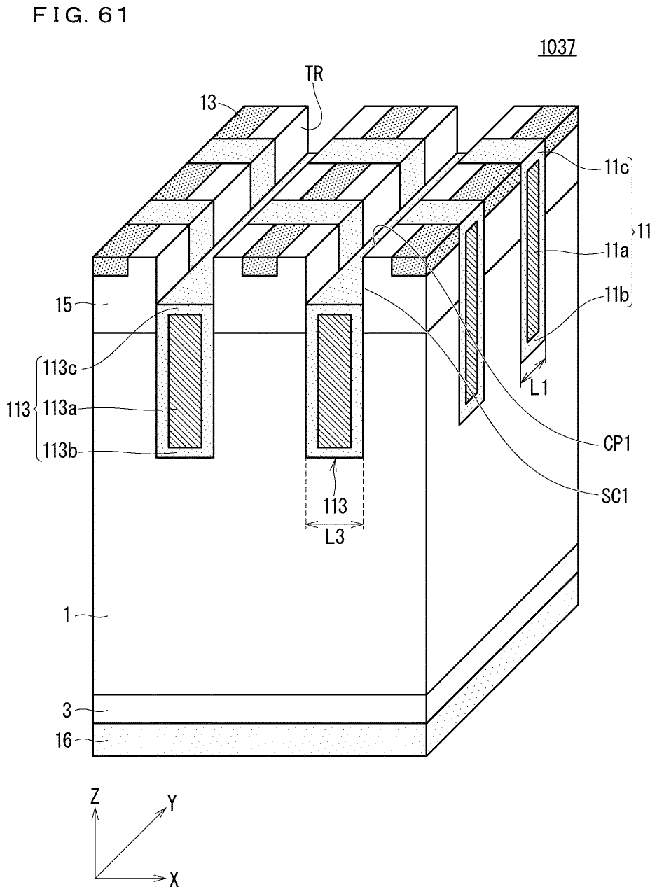

FIG. 61 is the same cross-sectional perspective view as FIG. 59, and the width L3, which is the length of the trench electrode 113 in the X-axis direction, is set to be wider than the width L1, which is the length of the active trench gate 11 in the Y-axis direction. However, the width L1 of the active trench gate 11 may be set to be wider than the width L3 of the trench electrode 113. The IE effect can be improved by increasing any one of the widths.

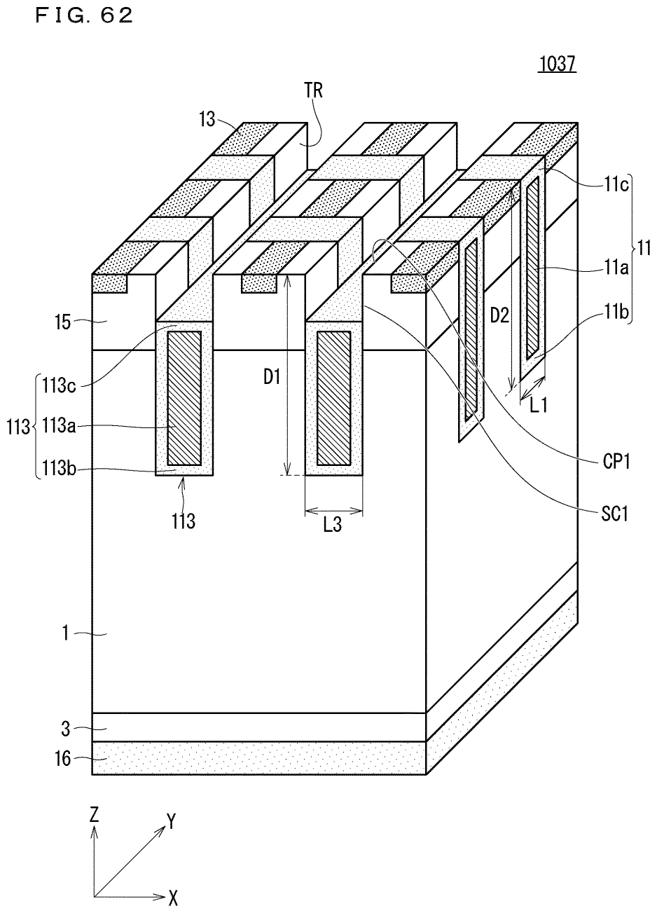

FIG. 62 is the same cross-sectional perspective view as FIG. 59, and a depth D1, which is a position of the bottom surface of the trench electrode 113 in the Z direction, is set to be deeper than a depth D2, which is a position of the bottom surface of the active trench gate 11 in the Z axis direction.

By increasing the trench depth of the wider trench in this manner, the electric fields at the bottom portion of the trench can be relaxed, and thus, the withstand voltage of the RC-IGBT 1037 can be improved. Thereby, the withstand voltage can be improved. That is, the bottom surface of the trench electrode 113 is larger than the bottom surface of the active trench gate 11, and thus, the cross-sectional shape is more rounded than the bottom portion of the active trench gate 11. Therefore, in the vicinity of the bottom portion of the trench electrode 113, the electric fields are relaxed, and the electric fields are made uniform. Thus, the withstand voltage can be improved.

In a case where the trench electrode 113 and the active trench gate 11 are simultaneously processed, an etching speed of the trench electrode 113 having a wider width is faster due to a micro-loading effect, and thus, the trench electrode 113 is deeper. Therefore, it is relatively easy to separately form the depths of the trench electrode 113 and the active trench gate 11.

### Thirty-Eighth Preferred Embodiment

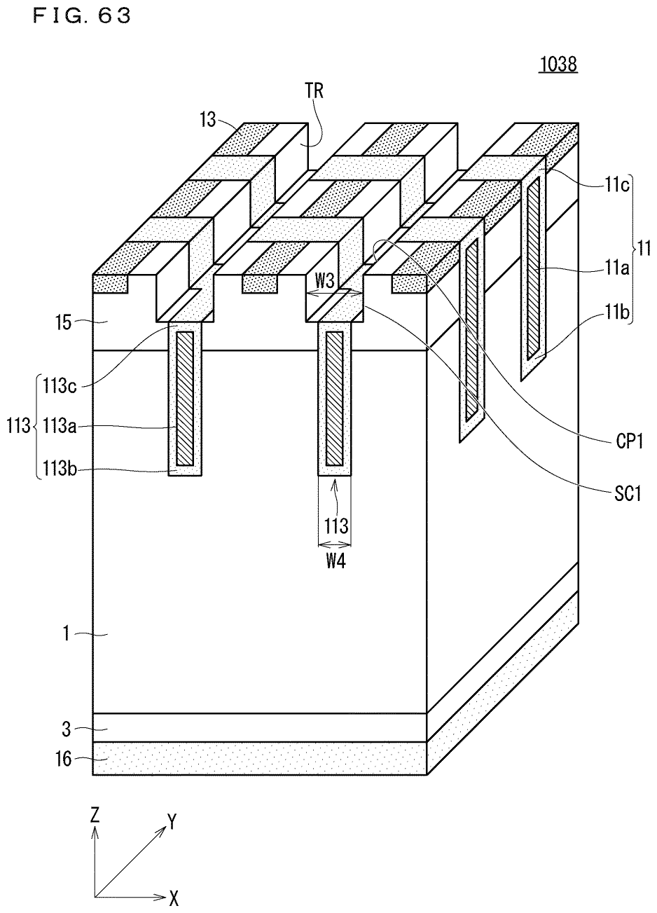

A configuration of an RC-IGBT 1038 according to a thirty-eighth preferred embodiment will be described with reference to FIG. 63. FIG. 63 is a cross-sectional perspective view corresponding to a region surrounded by a broken line X in FIG. 12. Note that, in FIG. 63, the same components as the components of the RC-IGBT 1032 described with reference to FIG. 54 are denoted by the same reference numerals, and redundant description is omitted.

In the RC-IGBT 1038 illustrated in FIG. 63, a width W3, which is the length of the trench TR in the X-axis direction is set to be wider than a width W4, which is the length of the trench electrode 113 in the X-axis direction.

Therefore, an area of the trench upper insulating film 113c on the bottom surface of the trench TR is reduced, and an area of the p-type base layer 15 is increased. Thus, the hole extraction effect at the time of turn-off when the RC-IGBT 1038 operates as an IGBT can be further improved.

That is, an area in which the barrier metal 5 and the emitter electrode 6 (not illustrated) are in contact with the p-type base layer 15 increases, and the hole extraction effect at the time of turn-off when the RC-IGBT 1038 operates as an IGBT can be improved. Further, it is possible to control the gate capacitance ratio Cgc/Cge while improving the IE effect by the gate trench electrode 11a of the active trench gate 11.

### Thirty-Ninth Preferred Embodiment

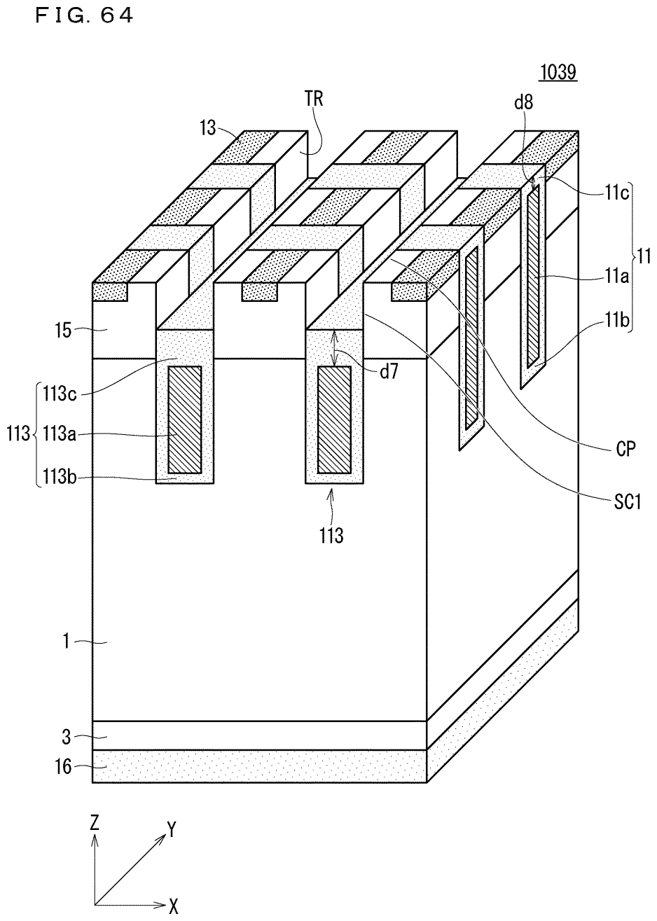

A configuration of an RC-IGBT 1039 according to a thirty-ninth preferred embodiment will be described with reference to FIG. 64. FIG. 64 is a cross-sectional perspective view corresponding to a region surrounded by a broken line X in FIG. 12. Note that, in FIG. 64, the same components as the components of the RC-IGBT 1032 described with reference to FIG. 54 are denoted by the same reference numerals, and redundant description is omitted.

In the RC-IGBT 1039 illustrated in FIG. 64, a thickness d7, which is a length of the trench upper insulating film 113c of the trench electrode 113 in the Z-axis direction, is set to be thicker than a thickness d8, which is a length of the upper insulating film 11c of the active trench gate 11 in the Z-axis direction.

Therefore, a volume of the electrode portion 113a of the trench electrode 113 can be reduced, and the gate charge amount Qg charged in the electrode portion 113a can be reduced. As the gate charge amount Qg decreases, the turn-on of the gate can be accelerated, and a switching speed of the active trench gate 11 can be accelerated.

The configurations of the thirty-seventh to thirty-ninth preferred embodiments described above can be freely combined and used. In addition, the contact portion CP1 according to the thirty-seventh preferred embodiment and the trench TR according to the eighteenth preferred embodiment have the same effect, and thus, the thirty-seventh preferred embodiment and the nineteenth to twenty-third preferred embodiments can be used in combination.

### Fortieth Preferred Embodiment

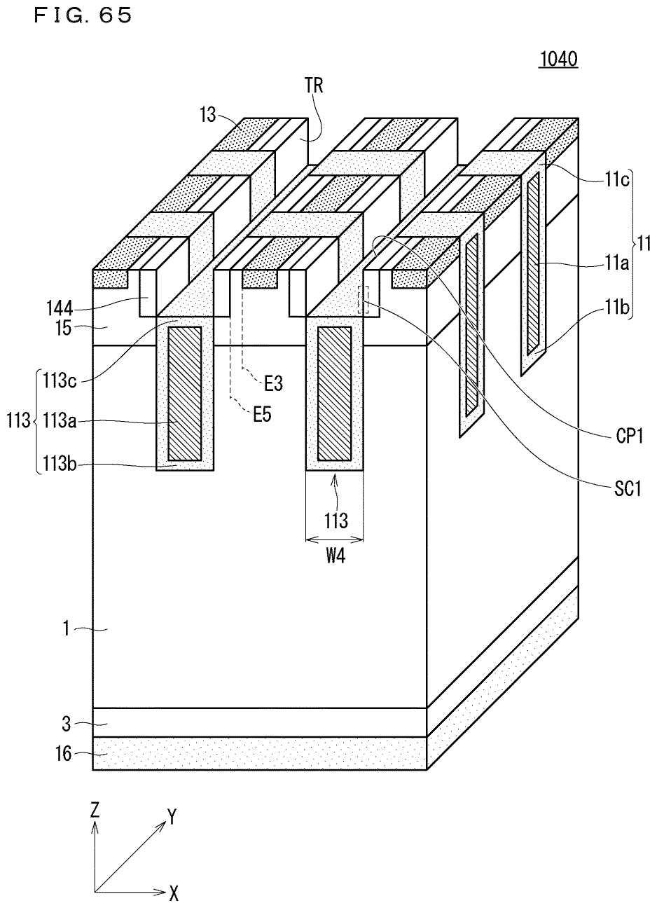

A configuration of an RC-IGBT 1040 according to a fortieth preferred embodiment will be described with reference to FIG. 65. FIG. 65 is a cross-sectional perspective view corresponding to a region surrounded by a broken line X in FIG. 12. Note that, in FIG. 65, the same components as the components of the RC-IGBT 1037 described with reference to FIG. 59 are denoted by the same reference numerals, and redundant description is omitted.

A portion of the upper portion of the trench TR where the trench electrode 113 is not embedded forms a contact portion CP1, a p⁺-type contact layer 144 is provided on a side surface of the contact portion CP1, and a portion of the p⁺-type contact layer 14 that is deeper than the n⁺-type source layer 13 forms a side contact portion SC1. The impurity concentration of the p⁺-type contact layer 144 is set to be higher than the impurity concentration of the p-type base layer 15.

As illustrated in FIG. 65, the bottom surface of the contact portion CP1 is covered with the trench upper insulating film 113c and the upper insulating film 11c, and the holes cannot be extracted. However, the side contact portion SC1 is formed of the p⁺-type contact layer 144, and thus, the side contact portion SC1 has a function of extracting the holes. By providing the p⁺-type contact layer 144, it is possible to improve the hole extraction effect at the time of turn-off when the RC-IGBT 1040 operates as an IGBT.

The gate trench electrode 11a intersects with the electrode portion 113a in the trench TR, and the gate trench electrode 11a and the electrode portion 113a have a mesh shape in plan view when viewed from above in the Z-axis direction.

It is possible to control the gate capacitance ratio Cgc/Cge while improving the IE effect by the gate trench electrode 11a of the active trench gate 11.

In addition, in a case where a position of one end portion of the n⁺-type source layer 13 in the horizontal direction (X-axis direction) is defined as a position E3 and a position of one end portion of the p⁺-type contact layer 144 that faces the position of the end portion of the n⁺-type source layer 13 in the horizontal direction is defined as a position E5, a distance from the n⁺-type source layer 13 to the position E5 is set to be 0.5 μm or shorter with reference to the position E3.

In a case where the distance between the end portion of the n⁺-type source layer 13 in the horizontal direction and the end portion of the p⁺-type contact layer 144 approaches a certain distance or shorter, the saturation current decreases depending on the width of the p⁺-type contact layer 144. That is, the saturation current can be regulated by bringing the p⁺-type contact layer 144 close to the n⁺-type source layer 13.

In addition, the contact portion CP1 according to the fortieth preferred embodiment and the trench TR according to the eighteenth preferred embodiment have the same effect, and thus, the fortieth preferred embodiment and the nineteenth to twenty-third preferred embodiments can be used in combination.

### Forty-first Preferred Embodiment

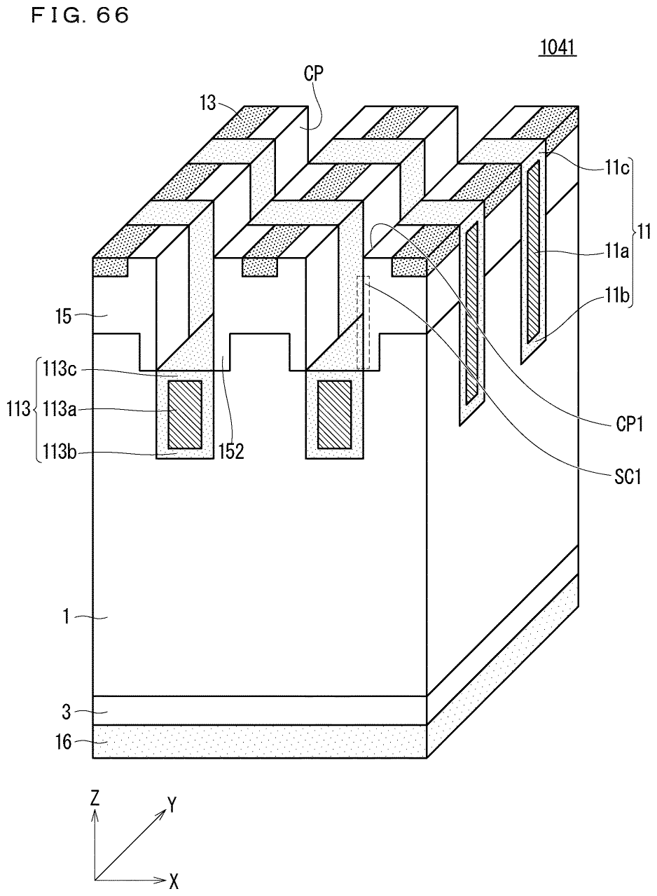

A configuration of an RC-IGBT 1041 according to a forty-first preferred embodiment will be described with reference to FIG. 66. FIG. 66 is a cross-sectional perspective view corresponding to a region surrounded by a broken line X in FIG. 12. Note that, in FIG. 66, the same components as the components of the RC-IGBT 1037 described with reference to FIG. 59 are denoted by the same reference numerals, and redundant description is omitted.

A portion of the upper portion of the trench TR where the trench electrode 113 is not embedded forms a contact portion CP1, and in the contact portion CP1, a side surface of the trench TR in the n⁻-type drift layer 1 that is lower than the bottom surface of the p-type base layer 15 is covered with the p-type barrier layer 152. The impurity concentration of the p-type barrier layer 152 is set to be equal to or lower than the impurity concentration of the p-type base layer 15.

The side surfaces of the p-type barrier layer 152 and the p-type base layer 15 that is provided above the p-type barrier layer 152 form a side contact portion SC1.

As illustrated in FIG. 66, the bottom surface of the contact portion CP1 is covered with the trench upper insulating film 113c and the upper insulating film 11c, and the holes cannot be extracted. However, the side contact portion SC1 is formed of the p-type base layer 15 and the p-type barrier layer 152, and thus, the side contact portion SC1 has a function of extracting the holes. By providing the p-type barrier layer 152, it is possible to improve the hole extraction effect at the time of turn-off when the RC-IGBT 1041 operates as an IGBT.

The gate trench electrode 11a intersects with the electrode portion 113a in the trench TR, and the gate trench electrode 11a and the electrode portion 113a have a mesh shape in plan view when viewed from above in the Z-axis direction.

It is possible to control the gate capacitance ratio Cgc/Cge while improving the IE effect by the gate trench electrode 11a of the active trench gate 11.

### Forty-Second Preferred Embodiment

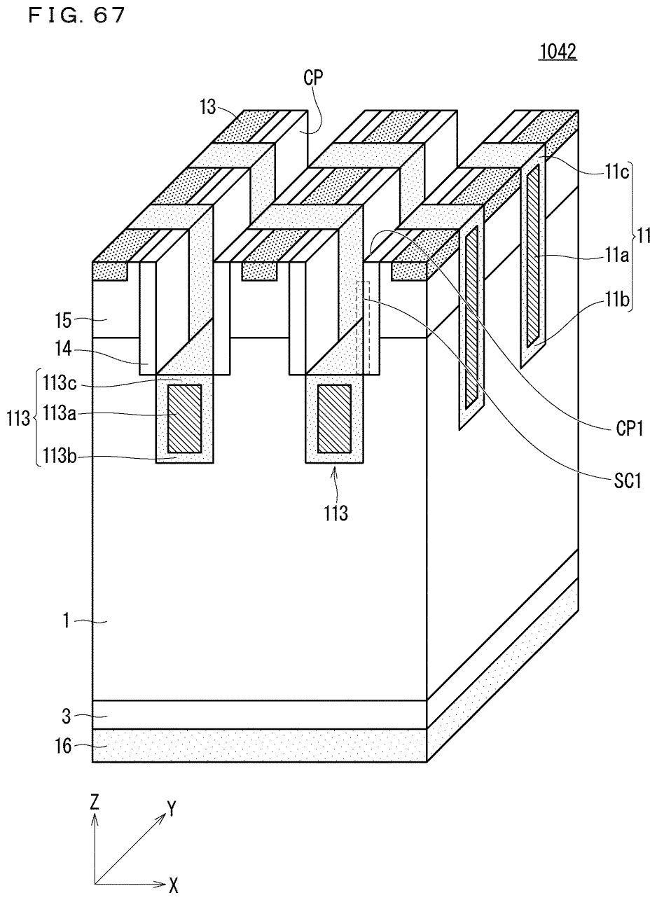

A configuration of an RC-IGBT 1042 according to a forty-second preferred embodiment will be described with reference to FIG. 67. FIG. 67 is a cross-sectional perspective view corresponding to a region surrounded by a broken line X in FIG. 12. Note that, in FIG. 67, the same components as the components of the RC-IGBT 1041 described with reference to FIG. 66 are denoted by the same reference numerals, and redundant description is omitted.

A portion of the upper portion of the trench TR where the trench electrode 113 is not embedded forms a contact portion CP1, and the p⁺-type contact layer 14 is provided in the surface of the side surface of the p-type base layer 15 of the contact portion CP1 and the side surface of the trench TR in the n⁻-type drift layer 1 that is lower than the bottom surface of the p-type base layer 15. The impurity concentration of the p⁺-type contact layer 14 is set to be higher than the impurity concentration of the p-type base layer 15, and the side surface of the p⁺-type contact layer 14 forms a side contact portion SC1.

As illustrated in FIG. 67, the bottom surface of the contact portion CP1 is covered with the trench upper insulating film 113c and the upper insulating film 11c, and the holes cannot be extracted. However, the side contact portion SC1 is formed of the p⁺-type contact layer 14, and thus, the side contact portion SC1 has a function of extracting the holes. By providing the p⁺-type contact layer 14, it is possible to improve the hole extraction effect at the time of turn-off when the RC-IGBT 1042 operates as an IGBT.

### Forty-Third Preferred Embodiment

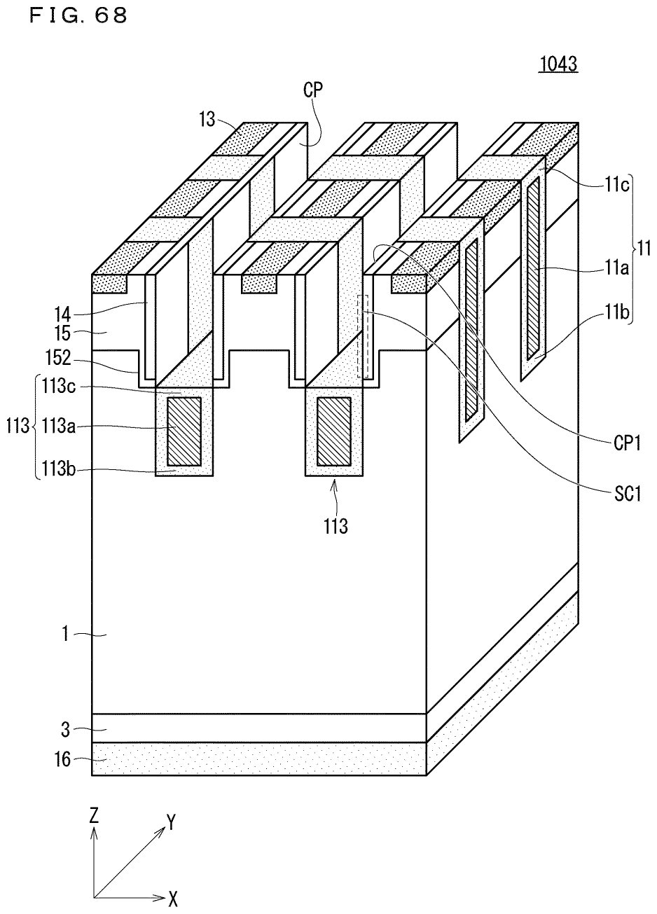

A configuration of an RC-IGBT 1043 according to a forty-third preferred embodiment will be described with reference to FIG. 68. FIG. 68 is a cross-sectional perspective view corresponding to a region surrounded by a broken line X in FIG. 12. Note that, in FIG. 68, the same components as the components of the RC-IGBT 1041 described with reference to FIG. 66 are denoted by the same reference numerals, and redundant description is omitted.

A portion of the upper portion of the trench TR where the trench electrode 113 is not embedded forms a contact portion CP1. In the contact portion CP1, the side surface of the trench TR in the n⁻-type drift layer 1 that is lower than the bottom surface of the p-type base layer 15 is covered with the p-type barrier layer 152, the p⁺-type contact layer 14 is provided in the surface of the side surface of the p-type base layer 15 of the contact portion CP1 and the side surface of the p-type barrier layer 152, and the side surface of the p⁺-type contact layer 14 forms a side contact portion SC1.

By providing the p-type barrier layer 152 that is lower than the bottom surface of the p-type base layer 15, the contact portion CP1 is deepened. By providing the p⁺-type contact layer 14 in the side contact portion SC1, the hole extraction effect at the time of turn-off when the RC-IGBT 1043 operates as an IGBT can be improved.

In addition, by covering the side surfaces of the p⁺-type contact layer 14 in the n⁻-type drift layer 1 with the p-type barrier layer 152, the electric fields at the junction between the p-type layer and the n-type layer can be relaxed. That is, by stacking the p⁺-type contact layer 14 that is a p-type layer and the p-type barrier layer 152, the concentration gradient of the p-type impurities becomes gentle, and the electric fields generated at the junction with the n⁻-type drift layer 1 that is an n-type layer can be relaxed.

The contact portion CP1 according to the forty-first and forty-second preferred embodiments and the trench TR according to the eighteenth preferred embodiment have the same effect, and thus, the forty-first and forty-second preferred embodiments and the nineteenth to twenty-third preferred embodiments can be used in combination.

### Forty-Fourth Preferred Embodiment

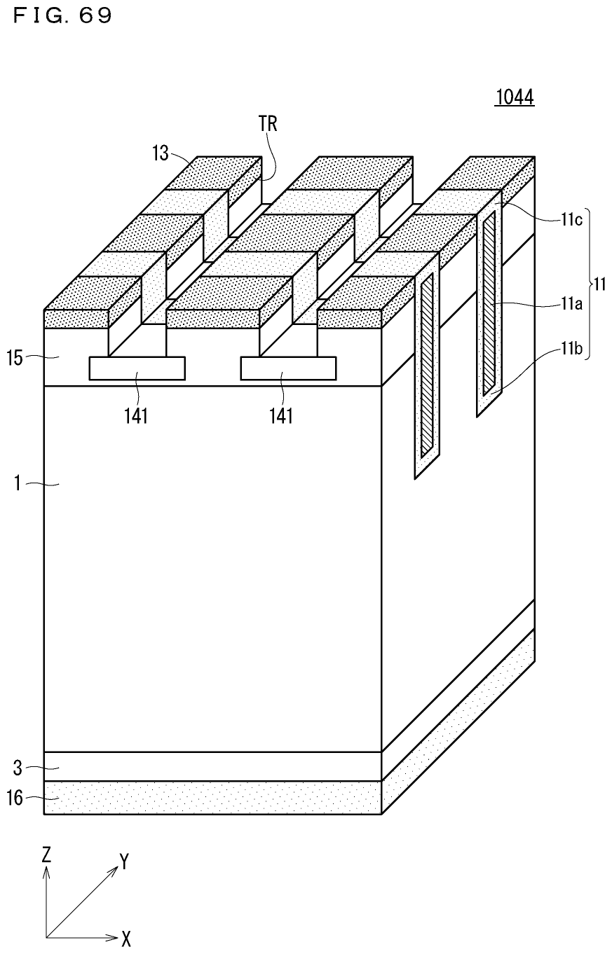

A configuration of an RC-IGBT 1044 according to a forty-fourth preferred embodiment will be described with reference to FIG. 69. FIG. 69 is a cross-sectional perspective view corresponding to FIG. 39 of the eighteenth preferred embodiment. In FIG. 69, the same components as the components of the RC-IGBT 1018 described with reference to FIG. 39 are denoted by the same reference numerals, and redundant description is omitted.

In the RC-IGBT 1044 illustrated in FIG. 69, the n⁺-type source layer 13 is provided on the entire upper layer of the mesa of the p-type base layer 15. Thereby, patterning of the n⁺-type source layer 13 becomes unnecessary, and the manufacturing cost can be reduced.

Further, in the RC-IGBT 1044 illustrated in FIG. 69, the p⁺-type contact layer 141 is provided at least at the bottom portion of the trench TR. Thereby, it is possible to increase the hole extraction efficiency at the time of turn-off when the RC-IGBT 1044 operates as an IGBT.

### Forty-Fifth Preferred Embodiment

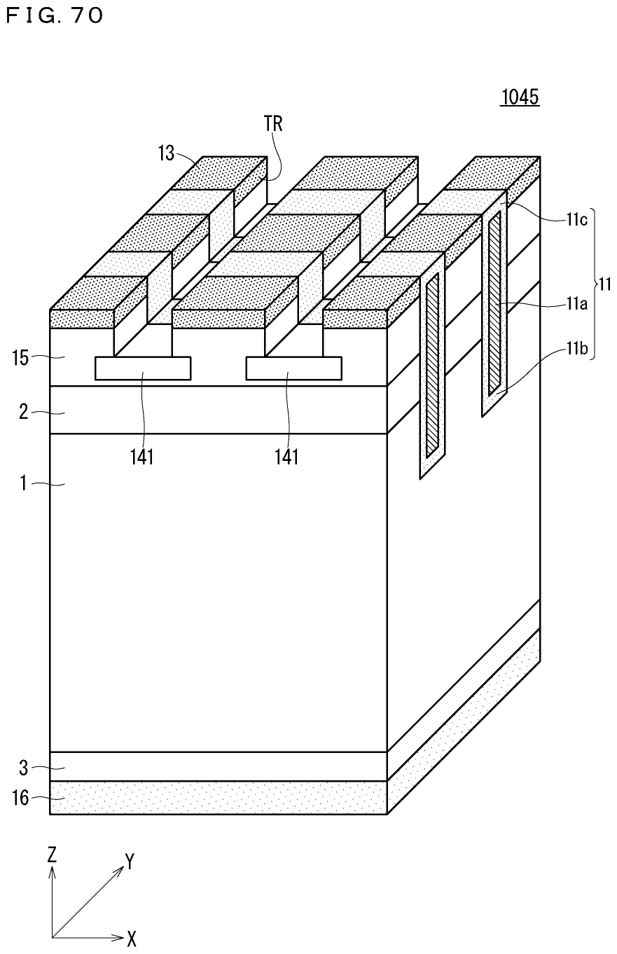

A configuration of an RC-IGBT 1045 according to a forty-fifth preferred embodiment will be described with reference to FIG. 70. FIG. 70 is a cross-sectional perspective view corresponding to FIG. 39 of the eighteenth preferred embodiment. In FIG. 70, the same components as the components of the RC-IGBT 1018 described with reference to FIG. 39 are denoted by the same reference numerals, and redundant description is omitted.

In the RC-IGBT 1045 illustrated in FIG. 70, the n⁺-type source layer 13 is provided on the entire upper layer of the mesa of the p-type base layer 15. Thereby, patterning of the n⁺-type source layer 13 becomes unnecessary, and the manufacturing cost can be reduced.

Further, in the RC-IGBT 1045 illustrated in FIG. 70, the p⁺-type contact layer 141 is provided at least at the bottom portion of the trench TR. Thereby, it is possible to increase the hole extraction efficiency at the time of turn-off when the RC-IGBT 1045 operates as an IGBT.

In the RC-IGBT 1045 illustrated in FIG. 70, the n-type carrier accumulation layer 2 is provided under the p-type base layer 15. By providing the n-type carrier accumulation layer 2 having a higher impurity concentration on the n⁻-type drift layer 1, the carrier density on the emitter side increases due to a carrier accumulation effect of preventing holes from being extracted to the emitter side and accumulating holes. Thus, conductivity modulation is promoted, and an on-state voltage when the RC-IGBT 1045 operates as an IGBT can be lowered.

### Forty-Sixth Preferred Embodiment

In the present preferred embodiment, the semiconductor device according to the first to forty-fifth preferred embodiments is applied to a power conversion apparatus. The semiconductor device according to the first to forty-fifth preferred embodiments is not limited to being applied to a specific power conversion apparatus, but a case where the semiconductor device is applied to a three-phase inverter will be described below as a forty-sixth preferred embodiment.

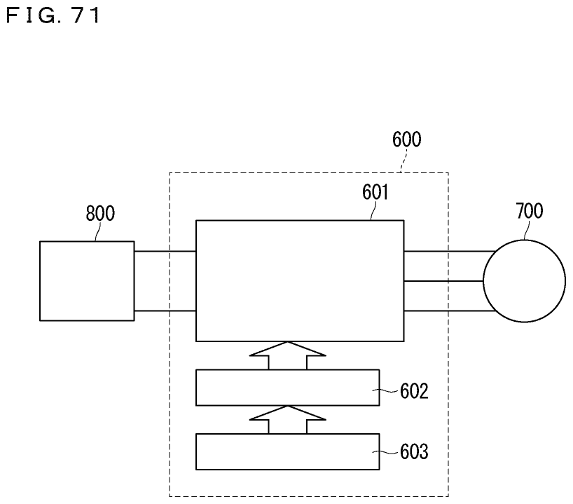

FIG. 71 is a block diagram illustrating a configuration of a power conversion system to which the power conversion apparatus according to the present preferred embodiment is applied.

The power conversion system illustrated in FIG. 71 includes a power supply 800, a power conversion apparatus 600, and a load 700. The power supply 800 is a DC power supply, and supplies DC power to the power conversion apparatus 600. The power supply 800 can include various components, and can include, for example, a DC system, a solar cell, and a storage battery, and may include a rectifier circuit or an AC/DC converter connected to an AC system. In addition, the power supply 800 may be configured by a DC/DC converter that converts DC power output from the DC system into predetermined power.

The power conversion apparatus 600 is a three-phase inverter connected between the power supply 800 and the load 700, converts DC power supplied from the power supply 800 into AC power, and supplies the AC power to the load 700. As illustrated in FIG. 71, the power conversion apparatus 600 includes a main conversion circuit 601 that converts DC power into AC power and outputs the AC power, a drive circuit 602 that outputs a drive signal for driving each switching element of the main conversion circuit 601, and a control circuit 603 that outputs a control signal for controlling the drive circuit 602 to the drive circuit 602.

The load 700 is a three-phase electric motor driven by the AC power supplied from the power conversion apparatus 600. The load 700 is not limited to a specific application, but is an electric motor mounted on various electric devices, and is used as, for example, an electric motor for a hybrid vehicle, an electric vehicle, a railway vehicle, an elevator, or an air conditioner.

Hereinafter, details of the power conversion apparatus 600 will be described. The main conversion circuit 601 includes a switching element and a free wheeling diode (not illustrated), converts DC power supplied from the power supply 800 into AC power by switching of the switching element, and supplies the AC power to the load 700. Although there are various specific circuit configurations of the main conversion circuit 601, the main conversion circuit 601 according to the present preferred embodiment is a two-level three-phase full bridge circuit, and can include six switching elements and six free wheeling diodes antiparallel to the respective switching elements. The semiconductor device according to any one of the first to forty-third preferred embodiments described above is applied to each switching element of the main conversion circuit 601. The six switching elements are connected in series for every two switching elements to configure upper and lower arms, and each of the upper and lower arms configures each phase (U-phase, V-phase, W-phase) of the full bridge circuit. The output terminals of the upper and lower arms, that is, the three output terminals of the main conversion circuit 601 are connected to the load 700.

The drive circuit 602 generates a drive signal for driving the switching element of the main conversion circuit 601, and supplies the drive signal to the control electrode of the switching element of the main conversion circuit 601. Specifically, in accordance with a control signal from the control circuit 603 to be described later, a drive signal for turning on the switching element and a drive signal for turning off the switching element are output to the control electrode of each switching element. In a case where the switching element is maintained in an on state, the drive signal is a voltage signal (on signal) equal to or higher than a threshold voltage of the switching element, and in a case where the switching element is maintained in an off state, the drive signal is a voltage signal (off signal) equal to or lower than the threshold voltage of the switching element.

The control circuit 603 controls the switching elements of the main conversion circuit 601 such that desired power is supplied to the load 700. Specifically, a time (on time) during which each switching element of the main conversion circuit 601 is to be turned on is calculated based on the power to be supplied to the load 700. For example, the main conversion circuit 601 can be controlled by PWM control that modulates the on time of the switching element according to the voltage to be output. Then, a control command (control signal) is output to the drive circuit 602 such that an on signal is output to the switching element to be turned on at each timing and an off signal is output to the switching element to be turned off at each timing. The drive circuit 602 outputs an on signal or an off signal as a drive signal to the control electrode of each switching element according to the control signal.

In the power conversion apparatus according to the present preferred embodiment, the semiconductor device according to any one of the first to forty-fifth preferred embodiments is applied as the switching element of the main conversion circuit 601. Thus, it is possible to provide a power conversion apparatus that improves reliability while achieving both avoidance of erroneous firing during reverse recovery of a free wheeling diode and noise reduction.

In the present preferred embodiment, the two-level three-phase inverter has been described as an example, but the present preferred embodiment is not limited thereto, and can be applied to various power conversion apparatuses. In the present preferred embodiment, the two-level power conversion apparatus is used, but a three-level or multi-level power conversion apparatus may be used, or a single-phase inverter may be used in a case where power is supplied to a single-phase load. Further, in a case where power is supplied to a DC load or the like, the present disclosure can be applied to a DC/DC converter or an AC/DC converter.

In addition, the load described above is not limited to the case of an electric motor, and can be used as, for example, a power supply apparatus of an electric discharge machine, a laser beam machine, an induction heating cooker, or a non-contact power feeding system, and can be further used as a power conditioner of a solar power generation system, a power storage system, or the like.

Note that, in the present disclosure, each preferred embodiment can be freely combined, and each preferred embodiment can be appropriately modified or omitted within the scope of the present disclosure.

The present disclosure described above will be collectively described as Appendixes.

### (Appendix 1)

A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode; and
a plurality of trench gates that are provided so as to penetrate the third semiconductor layer and the second semiconductor layer from the first main surface in a thickness direction and reach into the first semiconductor layer, wherein
the trench gate includes
a gate trench insulating film that covers an inner surface of a trench,
a gate trench electrode that is provided in the trench via the gate trench insulating film, and
an upper insulating film that covers the gate trench electrode,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer,
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where a size relationship between the distance E1d and the distance E2d corresponds to a predetermined case, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2.

### (Appendix 2)

The semiconductor device according to Appendix 1, wherein the distance E1d is longer than the distance E2d.

### (Appendix 3)

The semiconductor device according to Appendix 1, wherein the predetermined case is a case where the distance E1d is shorter than the distance E2d.

### (Appendix 4)

The semiconductor device according to Appendix 1, wherein a width W1 of the protrusion portion and a width W2 of the recess portion are set such that the width W2 is wider than the width W1.

### (Appendix 5)

The semiconductor device according to any one of Appendixes 1 to 4, wherein the third semiconductor layer is provided at a position corresponding to a position at which the protrusion portion is provided.

### (Appendix 6)

The semiconductor device according to any one of Appendixes 1 to 4, wherein the second semiconductor layer includes a region in which the third semiconductor layer is not provided in a region corresponding to a position at which the protrusion portion is provided.

### (Appendix 7)

The semiconductor device according to any one of Appendixes 1 to 4, wherein the second semiconductor layer includes a fourth semiconductor layer which has a second conductivity type and is provided in a region in which the third semiconductor layer is not provided.

### (Appendix 8)

The semiconductor device according to any one of Appendixes 1 to 4, wherein the second semiconductor layer includes a depression portion that is removed to a predetermined depth between the third semiconductor layers which are provided to be parallel to each other.

### (Appendix 9)

The semiconductor device according to Appendix 8, wherein the second semiconductor layer includes a fourth semiconductor layer that has a second conductivity type and is provided at least on a bottom portion of the depression portion.

### (Appendix 10)

The semiconductor device according to any one of Appendixes 1 to 4, wherein the third semiconductor layer and the second semiconductor layer between the trench gates which are provided to be parallel to each other include a trench contact that is removed along the trench gate and is parallel to the trench gate.

### (Appendix 11)

The semiconductor device according to Appendix 10, wherein the second semiconductor layer includes a fourth semiconductor layer that has a second conductivity type and is provided at least on a bottom portion of the trench contact.

### (Appendix 12)

The semiconductor device according to any one of Appendixes 1 to 4, further comprising a fifth semiconductor layer that has a first conductivity type and is provided on a lower portion of the second semiconductor layer.

### (Appendix 13)

The semiconductor device according to Appendix 12, further comprising a sixth semiconductor layer that has a second conductivity type and is provided on a lower portion of the fifth semiconductor layer.

### (Appendix 14)

The semiconductor device according to any one of Appendixes 1 to 4, further comprising a seventh semiconductor layer that has a second conductivity type, is selectively provided on a lower portion of a bottom surface of the trench gate, and covers at least the bottom surface.

### (Appendix 15)

The semiconductor device according to any one of Appendixes 1 to 4, further comprising a dummy trench gate that is provided so as to penetrate the third semiconductor layer and the second semiconductor layer from the first main surface in the thickness direction and reach into the first semiconductor layer, wherein
the dummy trench gate includes
a dummy trench insulating film that covers an inner surface of a dummy trench,
a dummy trench electrode that is provided in the dummy trench via the dummy trench insulating film, and
a dummy upper insulating film that covers the dummy trench electrode, and
the dummy trench electrode is electrically connected to the first main electrode.

### (Appendix 16)

The semiconductor device according to any one of Appendixes 1 to 4, further comprising a dummy trench gate that is provided so as to penetrate the third semiconductor layer and the second semiconductor layer from the first main surface in the thickness direction and reach into the first semiconductor layer, wherein
the dummy trench gate includes
a dummy trench insulating film that covers an inner surface of a dummy trench,
a dummy trench electrode that is provided in the dummy trench via the dummy trench insulating film, and
a dummy upper insulating film that covers the dummy trench electrode, and
the dummy trench electrode is electrically floating.

### (Appendix 17)

The semiconductor device according to any one of Appendixes 1 to 4, further comprising a dummy trench gate that is provided so as to penetrate the third semiconductor layer and the second semiconductor layer from the first main surface in the thickness direction and reach into the first semiconductor layer, wherein
the dummy trench gate includes
a dummy trench insulating film that covers an inner surface of a dummy trench,
a dummy trench electrode that is provided in the dummy trench via the dummy trench insulating film, and
a dummy upper insulating film that covers the dummy trench electrode, and
a control gate potential is supplied to the dummy trench electrode.

### (Appendix 18)

The semiconductor device according to Appendix 17, wherein
a gate potential is supplied to the gate trench electrode of the trench gate from a first gate driver via a first resistor,
a control gate potential is supplied to the dummy trench electrode of the dummy trench gate from a second gate driver via a second resistor, and
the first resistor and the second resistor have different resistance values.

### (Appendix 19)

The semiconductor device according to any one of Appendixes 1 to 4, wherein
the gate trench electrode has a protrusion shape in which a gate width on a lower side which is the second main surface side is narrower than a gate width on an upper side which is the first main surface side in a cross-sectional view in a second direction intersecting with the first direction, and
a thickness of the gate trench insulating film is set to be thicker on the lower side by an amount by which the gate width on the lower side is narrowed.

### (Appendix 20)

A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode; and
a plurality of trench gates that are provided so as to penetrate the third semiconductor layer and the second semiconductor layer from the first main surface in a thickness direction and reach into the first semiconductor layer, wherein
the trench gate includes
a gate trench insulating film that covers an inner surface of a trench,
a gate trench electrode that is provided in the trench via the gate trench insulating film, and
an upper insulating film that covers the gate trench electrode,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer,
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2, and
in a case where a position of one end portion of the third semiconductor layer in the first direction is defined as a position E3 and a position of an end portion of the protrusion portion in the first direction that faces the position of the end portion of the third semiconductor layer is defined as a position E4, a distance from the position E3 to the position E4 is set to be 0.5 μm or shorter.

### (Appendix 21)

The semiconductor device according to Appendix 20, wherein
the second semiconductor layer includes a fourth semiconductor layer that has a second conductivity type, is provided between the third semiconductor layers which are provided to be parallel to each other, and is thicker than the third semiconductor layers, and
in a case where a position of an end portion of the fourth semiconductor layer in the first direction that faces the position of the end portion of the third semiconductor layer is defined as a position E5, a distance from the position E3 to the position E5 is set to be 0.5 μm or shorter.

### (Appendix 22)

A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is provided by removing at least the second semiconductor layer to a predetermined depth and providing the trench gate so as to have a partial step such that the upper insulating film has the same depth as a bottom surface of the trench,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2.

### (Appendix 23)

The semiconductor device according to Appendix 22, wherein a thickness d2 of the upper insulating film that covers side surfaces of the protrusion portion of the gate trench electrode is set to be thicker than a thickness d1 of the upper insulating film that covers an upper surface of the protrusion portion.

### (Appendix 24)

The semiconductor device according to Appendix 22, wherein a thickness d3 of the upper insulating film that covers the recess portion of the gate trench electrode is set to be thicker than a thickness d1 of the upper insulating film that covers an upper surface of the protrusion portion.

### (Appendix 25)

The semiconductor device according to any one of Appendixes 22 to 24, wherein the trench gate has a width L1 in a cross-sectional view in a second direction intersecting with the first direction, the width L1 being set to be wider than a width L2 of the trench in a cross-sectional view in the first direction.

### (Appendix 26)

The semiconductor device according to any one of Appendixes 22 to 24, wherein the trench has a width L2 in a cross-sectional view in the first direction, the width L2 being set to be wider than a width L1 of the trench gate in a cross-sectional view in a second direction intersecting with the first direction.

### (Appendix 27)

The semiconductor device according to any one of Appendixes 22 to 24, wherein the second semiconductor layer includes a region in which the third semiconductor layer is not provided in a region corresponding to a position at which the protrusion portion is provided.

### (Appendix 28)

The semiconductor device according to any one of Appendixes 22 to 24, wherein another trench that has a width L3 narrower than a width L2 of the trench in a cross-sectional view in the first direction is provided.

### (Appendix 29)

The semiconductor device according to any one of Appendixes 22 to 24, wherein the third semiconductor layer is provided over the entire upper layer portion of the second semiconductor layer between the trenches that are provided to be parallel to each other.

### (Appendix 30)

The semiconductor device according to any one of Appendixes 22 to 24, wherein the second semiconductor layer includes a fourth semiconductor layer that has a second conductivity type and is provided at least on a bottom portion of the trench.

### (Appendix 31)

The semiconductor device according to any one of Appendixes 22 to 24, further comprising:
a fifth semiconductor layer that has a first conductivity type and is provided on a lower portion of the second semiconductor layer; and
a sixth semiconductor layer that has a second conductivity type and is provided on a lower portion of the fifth semiconductor layer, wherein
a bottom surface of the trench reaches an inner portion of the sixth semiconductor layer.

### (Appendix 32)

A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a lower electrode that extends from a position lower than the second semiconductor layer to the second main surface side and is provided via the gate trench insulating film, and an upper electrode that extends from a position higher than the lower electrode to the first main surface side,
an intermediate insulating film that is provided between the lower electrode and the upper electrode, and
an upper insulating film that covers the upper electrode,
the trench is provided by removing the second semiconductor layer to a predetermined depth and providing the trench gate so as to have a partial step such that the upper insulating film has the same depth as an upper surface of the removed second semiconductor layer,
the upper electrode has a comb shape in which a recess portion that is recessed toward the first semiconductor layer and a protrusion portion that protrudes toward the first main electrode are alternately provided in a cross-sectional view along a first direction which is an extending direction of the upper electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the upper electrode formed in a region of the area S1 is defined as an area S2,
a gate capacitance ratio is linearly controlled by changing the area S2.

### (Appendix 33)

The semiconductor device according to Appendix 32, wherein
a gate potential is supplied to the upper electrode, and
a first main electrode potential is supplied to the lower electrode.

### (Appendix 34)

The semiconductor device according to Appendix 32, wherein a gate potential is supplied to the upper electrode and the lower electrode.

### (Appendix 35)

The semiconductor device according to any one of Appendixes 32 to 34, further comprising a dummy trench gate that is provided so as to penetrate the third semiconductor layer and the second semiconductor layer from the first main surface in the thickness direction and reach into the first semiconductor layer, wherein
the dummy trench gate includes
a dummy trench insulating film that covers an inner surface of a dummy trench,
a dummy lower electrode that extends from a position lower than the second semiconductor layer to the second main surface side and is provided via the dummy trench insulating film, and a dummy upper electrode that extends from a position higher than the dummy lower electrode to the first main surface side,
a dummy intermediate insulating film that is provided between the dummy lower electrode and the upper electrode, and
a dummy upper insulating film that covers the dummy upper electrode,
a control gate potential is supplied to the dummy upper electrode, and
a first main electrode potential or a gate potential is supplied to the dummy lower electrode.

### (Appendix 36)

The semiconductor device according to any one of Appendixes 32 to 34, wherein a thickness d5 of the gate trench insulating film in contact with the lower electrode is set to be thicker than a thickness d4 of the gate trench insulating film in contact with the upper electrode.

### (Appendix 37)

The semiconductor device according to Appendix 35, wherein
a thickness of the gate trench insulating film in contact with the lower electrode is set to be thicker than a thickness of the gate trench insulating film in contact with the upper electrode, and
a thickness of the dummy trench insulating film in contact with the dummy lower electrode is set to be thicker than a thickness of the dummy trench insulating film in contact with the dummy upper electrode.

### (Appendix 38)

The semiconductor device according to any one of Appendixes 32 to 34, wherein a thickness d6 of the intermediate insulating film is set to be thicker than a thickness d4 of the gate trench insulating film.

### (Appendix 39)

The semiconductor device according to Appendix 35, wherein
a thickness of the intermediate insulating film is set to be thicker than a thickness of the gate trench insulating film, and
a thickness of the dummy intermediate insulating film is set to be thicker than a thickness of the dummy trench insulating film.

### (Appendix 40)

A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a third semiconductor layer that has a first conductivity type, is provided on an upper layer portion of the second semiconductor layer, and is electrically connected to the first main electrode;
a fourth semiconductor layer that has a second conductivity type and is provided on the upper layer portion of the second semiconductor layer in parallel with the third semiconductor layer;
a plurality of trench gates that are provided so as to penetrate the third semiconductor layer, the fourth semiconductor layer, and the second semiconductor layer from the first main surface in a thickness direction and reach into the first semiconductor layer; and
a trench that is provided so as to intersect with the trench gates 11 in a region in which the fourth semiconductor layer is provided, wherein
the trench gate includes
a gate trench insulating film that covers an inner surface of a trench,
a gate trench electrode that is provided in the trench via the gate trench insulating film, and
an upper insulating film that covers the gate trench electrode,
the fourth semiconductor layer is provided on the upper layer portion of the second semiconductor layer in a state where the second semiconductor layer is removed to a predetermined depth,
the trench gate is provided so as to have a partial step such that the upper insulating film has the same depth as an upper surface of the fourth semiconductor layer on a bottom surface of the trench,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2, and in a case where a position of one end portion of the third semiconductor layer in the first direction is defined as a position E3 and a position of an end portion of the fourth semiconductor layer included in the trench in the first direction is defined as a position E6, a distance from the position E3 to the position E6 is set to be 0.5 μm or shorter.

### (Appendix 41)

The semiconductor device according to Appendix 40, further comprising:
a fifth semiconductor layer that has a first conductivity type and is provided on a lower portion of the second semiconductor layer; and
a sixth semiconductor layer that has a second conductivity type and is provided on a lower portion of the fifth semiconductor layer, wherein
the fourth semiconductor layer included in the trench reaches an inner portion of the sixth semiconductor layer.

### (Appendix 42)

A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach an inner portion of the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is provided so as to penetrate at least the second semiconductor layer and reach into the first semiconductor layer, and the trench gate is provided so as to have a partial step such that the upper insulating film has the same depth as a bottom surface of the trench,
the trench is covered with a seventh semiconductor layer that has a second conductivity type at least in the inner portion of the first semiconductor layer,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2.

### (Appendix 43)

The semiconductor device according to Appendix 42, further comprising:
a fifth semiconductor layer that has a first conductivity type and is provided on a lower portion of the second semiconductor layer; and
a sixth semiconductor layer that has a second conductivity type and is provided on a lower portion of the fifth semiconductor layer, wherein
the trench penetrates the second semiconductor layer, the fifth semiconductor layer, and the sixth semiconductor layer and reaches an inner portion of the first semiconductor layer, and
at least the bottom surface of the trench in the inner portion of the first semiconductor layer is covered with the seventh semiconductor layer.

### (Appendix 44)

The semiconductor device according to Appendix 42, wherein
a fourth semiconductor layer that has a second conductivity type is provided in a surface of the trench, and
side surfaces and a bottom surface of the fourth semiconductor layer on the surface of the trench in the inner portion of the first semiconductor layer are covered with the seventh semiconductor layer.

### (Appendix 45)

The semiconductor device according to any one of Appendixes 42 to 44, wherein the seventh semiconductor layer is set to have a higher impurity concentration than the second semiconductor layer.

### (Appendix 46)

A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is formed by removing the second semiconductor layer and the first semiconductor layer to a predetermined depth and embedding a trench electrode in the trench except for an upper portion of the trench,
the trench electrode includes an electrode portion that is embedded in the trench via a trench insulating film and a trench upper insulating film that covers the electrode portion,
the trench gate is provided so as to have a partial step such that an upper surface of the upper insulating film in the trench has the same depth as an upper surface of the trench upper insulating film of the trench electrode,
the gate trench electrode intersects with the electrode portion in the trench to form a mesh shape in a plan view,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2.

### (Appendix 47)

The semiconductor device according to Appendix 46, wherein a width L1 of the trench gate in a cross-sectional view in a second direction intersecting with the first direction and a width L2 of the trench in a cross-sectional view in the first direction are set such that one of the width L1 and the width L2 is wider than the other.

### (Appendix 48)

The semiconductor device according to Appendix 47, wherein in the gate trench and the trench, a trench depth of one having a wider width is set to be deeper than a trench depth of the other having a narrower width.

### (Appendix 49)

The semiconductor device according to any one of Appendixes 46 to 48, wherein a width W3 of the trench in a cross-sectional view in the first direction is set to be wider than a width W4 of the trench electrode in a cross-sectional view in the first direction.

### (Appendix 50)

The semiconductor device according to any one of Appendixes 46 to 48, wherein a thickness d7 of the trench upper insulating film of the trench electrode is set to be thicker than a thickness d8 of the upper insulating film of the trench gate.

### (Appendix 51)

A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is formed by removing the second semiconductor layer and the first semiconductor layer to a predetermined depth and embedding a trench electrode in the trench except for an upper portion of the trench,
the trench electrode includes an electrode portion that is embedded in the trench via a trench insulating film and a trench upper insulating film that covers the electrode portion,
the trench gate is provided so as to have a partial step such that an upper surface of the upper insulating film in the trench has the same depth as an upper surface of the trench upper insulating film of the trench electrode,
the gate trench electrode intersects with the electrode portion in the trench to form a mesh shape in a plan view,
the upper portion of the trench forms a contact portion,
a fourth semiconductor layer that has a second conductivity type is provided on a side surface of the contact portion, and a portion of the fourth semiconductor layer that is deeper than the third semiconductor layer forms a side contact portion,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer,
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2, and
in a case where a position of one end portion of the third semiconductor layer in the first direction is defined as a position E3, and
in a case where a position of an end portion of the fourth semiconductor layer in the first direction that faces the position of the end portion of the third semiconductor layer is defined as a position E5, a distance from the position E3 to the position E5 is set to be 0.5 μm or shorter.

### (Appendix 52)

A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach an inner portion of the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is formed by removing the second semiconductor layer and the first semiconductor layer to a predetermined depth and embedding a trench electrode in the trench except for an upper portion of the trench,
the trench electrode includes an electrode portion that is embedded in the trench via a trench insulating film and a trench upper insulating film that covers the electrode portion,
the trench gate is provided so as to have a partial step such that an upper surface of the upper insulating film in the trench has the same depth as an upper surface of the trench upper insulating film of the trench electrode,
the gate trench electrode intersects with the electrode portion in the trench to form a mesh shape in a plan view,
the upper portion of the trench forms a contact portion,
a portion of a side surface of the trench is covered with a seventh semiconductor layer that has a second conductivity type at least in the inner portion of the first semiconductor layer,
the seventh semiconductor layer and a side surface of the second semiconductor layer provided on the seventh semiconductor layer form a side contact portion,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2.

### (Appendix 53)

The semiconductor device according to Appendix 52, wherein a fourth semiconductor layer that has a second conductivity type is provided in a surface of the seventh semiconductor layer and on a surface of the side surface of the second semiconductor layer provided on the seventh semiconductor layer.

### (Appendix 54)

The semiconductor device according to Appendix 52, wherein
a fourth semiconductor layer that has a second conductivity type is provided on a surface of the seventh semiconductor layer and in a surface of the side surface of the second semiconductor layer provided on the seventh semiconductor layer, and
the fourth semiconductor layer is provided such that the fourth semiconductor layer is covered with the seventh semiconductor layer in the surface of the seventh semiconductor layer.

### (Appendix 55)

A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is provided by removing the second semiconductor layer to a predetermined depth and providing the trench gate so as to have a partial step such that the upper insulating film has the same depth as a bottom surface of the trench,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer,
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2,
the third semiconductor layer is provided over the entire upper layer portion of the second semiconductor layer between the trenches that are provided to be parallel to each other, and
the second semiconductor layer includes a fourth semiconductor layer that has a second conductivity type and is provided at least on a bottom portion of the trench.

### (Appendix 56)

The semiconductor device according to Appendix 55, further comprising
a fifth semiconductor layer that has a first conductivity type and is provided on a lower portion of the second semiconductor layer.

### (Appendix 57)

A power conversion apparatus comprising:
a main conversion circuit that includes the semiconductor device according to any one of Appendixes 1 to 56, converts input power, and outputs the converted power;
a driving circuit that outputs a driving signal for driving the semiconductor device to the semiconductor device; and
a control circuit that outputs a control signal for controlling the driving circuit to the driving circuit.

While the disclosure has been shown and described in detail, the foregoing description is in all aspects illustrative and not restrictive. It is therefore understood that numerous modifications and variations can be devised.

What is claimed is:

1. A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode; and
a plurality of trench gates that are provided so as to penetrate the third semiconductor layer and the second semiconductor layer from the first main surface in a thickness direction and reach into the first semiconductor layer, wherein
the trench gate includes
a gate trench insulating film that covers an inner surface of a trench,
a gate trench electrode that is provided in the trench via the gate trench insulating film, and
an upper insulating film that covers the gate trench electrode,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer,
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where a size relationship between the distance E1d and the distance E2d corresponds to a predetermined case, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2.

2. The semiconductor device according to claim 1, wherein the predetermined case is a case where the distance E1d is longer than the distance E2d.

3. The semiconductor device according to claim 1, wherein the predetermined case is a case where the distance E1d is shorter than the distance E2d.

4. The semiconductor device according to claim 1, wherein a width W1 of the protrusion portion and a width W2 of the recess portion are set such that the width W2 is wider than the width W1.

5. The semiconductor device according to claim 1, wherein the third semiconductor layer is provided at a position corresponding to a position at which the protrusion portion is provided.

6. The semiconductor device according to claim 1, wherein the second semiconductor layer includes a region in which the third semiconductor layer is not provided in a region corresponding to a position at which the protrusion portion is provided.

7. The semiconductor device according to claim 1, wherein the second semiconductor layer includes a fourth semiconductor layer which has a second conductivity type and is provided in a region in which the third semiconductor layer is not provided.

8. The semiconductor device according to claim 1, wherein the second semiconductor layer includes a depression portion that is removed to a predetermined depth between the third semiconductor layers which are provided to be parallel to each other.

9. The semiconductor device according to claim 8, wherein the second semiconductor layer includes a fourth semiconductor layer that has a second conductivity type and is provided at least on a bottom portion of the depression portion.

10. The semiconductor device according to claim 1, wherein the third semiconductor layer and the second semiconductor layer between the trench gates which are provided to be parallel to each other include a trench contact that is removed along the trench gate and is parallel to the trench gate.

11. The semiconductor device according to claim 10, wherein the second semiconductor layer includes a fourth semiconductor layer that has a second conductivity type and is provided at least on a bottom portion of the trench contact.

12. The semiconductor device according to claim 1, further comprising a fifth semiconductor layer that has a first conductivity type and is provided on a lower portion of the second semiconductor layer.

13. The semiconductor device according to claim 12, further comprising a sixth semiconductor layer that has a second conductivity type and is provided on a lower portion of the fifth semiconductor layer.

14. The semiconductor device according to claim 1, further comprising a seventh semiconductor layer that has a second conductivity type, is selectively provided on a lower portion of a bottom surface of the trench gate, and covers at least the bottom surface.

15. The semiconductor device according to claim 1, further comprising a dummy trench gate that is provided so as to penetrate the third semiconductor layer and the second semiconductor layer from the first main surface in the thickness direction and reach into the first semiconductor layer, wherein
the dummy trench gate includes
a dummy trench insulating film that covers an inner surface of a dummy trench,
a dummy trench electrode that is provided in the dummy trench via the dummy trench insulating film, and
a dummy upper insulating film that covers the dummy trench electrode, and
the dummy trench electrode is electrically connected to the first main electrode.

16. The semiconductor device according to claim 1, further comprising a dummy trench gate that is provided so as to penetrate the third semiconductor layer and the second semiconductor layer from the first main surface in the thickness direction and reach into the first semiconductor layer, wherein
the dummy trench gate includes
a dummy trench insulating film that covers an inner surface of a dummy trench,
a dummy trench electrode that is provided in the dummy trench via the dummy trench insulating film, and
a dummy upper insulating film that covers the dummy trench electrode, and
the dummy trench electrode is electrically floating.

17. The semiconductor device according to claim 1, further comprising a dummy trench gate that is provided so as to penetrate the third semiconductor layer and the second semiconductor layer from the first main surface in the thickness direction and reach into the first semiconductor layer, wherein
the dummy trench gate includes
a dummy trench insulating film that covers an inner surface of a dummy trench,
a dummy trench electrode that is provided in the dummy trench via the dummy trench insulating film, and
a dummy upper insulating film that covers the dummy trench electrode, and
a control gate potential is supplied to the dummy trench electrode.

18. The semiconductor device according to claim 17, wherein
a gate potential is supplied to the gate trench electrode of the trench gate from a first gate driver via a first resistor,
a control gate potential is supplied to the dummy trench electrode of the dummy trench gate from a second gate driver via a second resistor, and
the first resistor and the second resistor have different resistance values.

19. The semiconductor device according to claim 1, wherein
the gate trench electrode has a protrusion shape in which a gate width on a lower side which is the second main surface side is narrower than a gate width on an upper side which is the first main surface side in a cross-sectional view in a second direction intersecting with the first direction, and
a thickness of the gate trench insulating film is set to be thicker on the lower side by an amount by which the gate width on the lower side is narrowed.

20. A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode; and
a plurality of trench gates that are provided so as to penetrate the third semiconductor layer and the second semiconductor layer from the first main surface in a thickness direction and reach into the first semiconductor layer, wherein
the trench gate includes
a gate trench insulating film that covers an inner surface of a trench,
a gate trench electrode that is provided in the trench via the gate trench insulating film, and
an upper insulating film that covers the gate trench electrode,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer,
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2, and
in a case where a position of one end portion of the third semiconductor layer in the first direction is defined as a position E3 and a position of an end portion of the protrusion portion in the first direction that faces the position of the end portion of the third semiconductor layer is defined as a position E4, a distance from the position E3 to the position E4 is set to be 0.5 μm or shorter.

21. The semiconductor device according to claim 20, wherein
the second semiconductor layer includes a fourth semiconductor layer that has a second conductivity type, is provided between the third semiconductor layers which are provided to be parallel to each other, and is thicker than the third semiconductor layers, and
in a case where a position of an end portion of the fourth semiconductor layer in the first direction that faces the position of the end portion of the third semiconductor layer is defined as a position E5, a distance from the position E3 to the position E5 is set to be 0.5 μm or shorter.

22. A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is provided by removing at least the second semiconductor layer to a predetermined depth and providing the trench gate so as to have a partial step such that the upper insulating film has the same depth as a bottom surface of the trench,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2.

23. The semiconductor device according to claim 22, wherein a thickness d2 of the upper insulating film that covers side surfaces of the protrusion portion of the gate trench electrode is set to be thicker than a thickness d1 of the upper insulating film that covers an upper surface of the protrusion portion.

24. The semiconductor device according to claim 22, wherein a thickness d3 of the upper insulating film that covers the recess portion of the gate trench electrode is set to be thicker than a thickness d1 of the upper insulating film that covers an upper surface of the protrusion portion.

25. The semiconductor device according to claim 22, wherein the trench gate has a width L1 in a cross-sectional view in a second direction intersecting with the first direction, the width L1 being set to be wider than a width L2 of the trench in a cross-sectional view in the first direction.

26. The semiconductor device according to claim 22, wherein the trench has a width L2 in a cross-sectional view in the first direction, the width L2 being set to be wider than a width L1 of the trench gate in a cross-sectional view in a second direction intersecting with the first direction.

27. The semiconductor device according to claim 22, wherein the second semiconductor layer includes a region in which the third semiconductor layer is not provided in a region corresponding to a position at which the protrusion portion is provided.

28. The semiconductor device according to claim 22, wherein another trench that has a width L3 narrower than a width L2 of the trench in a cross-sectional view in the first direction is provided.

29. The semiconductor device according to claim 22, wherein the third semiconductor layer is provided over the entire upper layer portion of the second semiconductor layer between the trenches that are provided to be parallel to each other.

30. The semiconductor device according to claim 22, wherein the second semiconductor layer includes a fourth semiconductor layer that has a second conductivity type and is provided at least on a bottom portion of the trench.

31. The semiconductor device according to claim 22, further comprising:
a fifth semiconductor layer that has a first conductivity type and is provided on a lower portion of the second semiconductor layer; and
a sixth semiconductor layer that has a second conductivity type and is provided on a lower portion of the fifth semiconductor layer, wherein
a bottom surface of the trench reaches an inner portion of the sixth semiconductor layer.

32. A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a lower electrode that extends from a position lower than the second semiconductor layer to the second main surface side and is provided via the gate trench insulating film, and an upper electrode that extends from a position higher than the lower electrode to the first main surface side,
an intermediate insulating film that is provided between the lower electrode and the upper electrode, and
an upper insulating film that covers the upper electrode,
the trench is provided by removing the second semiconductor layer to a predetermined depth and providing the trench gate so as to have a partial step such that the upper insulating film has the same depth as an upper surface of the removed second semiconductor layer,
the upper electrode has a comb shape in which a recess portion that is recessed toward the first semiconductor layer and a protrusion portion that protrudes toward the first main electrode are alternately provided in a cross-sectional view along a first direction which is an extending direction of the upper electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the upper electrode formed in a region of the area S1 is defined as an area S2,
a gate capacitance ratio is linearly controlled by changing the area S2.

33. The semiconductor device according to claim 32, wherein
a gate potential is supplied to the upper electrode, and
a first main electrode potential is supplied to the lower electrode.

34. The semiconductor device according to claim 32, wherein a gate potential is supplied to the upper electrode and the lower electrode.

35. The semiconductor device according to claim 32, further comprising a dummy trench gate that is provided so as to penetrate the third semiconductor layer and the second semiconductor layer from the first main surface in the thickness direction and reach into the first semiconductor layer, wherein
the dummy trench gate includes
a dummy trench insulating film that covers an inner surface of a dummy trench,
a dummy lower electrode that extends from a position lower than the second semiconductor layer to the second main surface side and is provided via the dummy trench insulating film, and a dummy upper electrode that extends from a position higher than the dummy lower electrode to the first main surface side,
a dummy intermediate insulating film that is provided between the dummy lower electrode and the upper electrode, and
a dummy upper insulating film that covers the dummy upper electrode,
a control gate potential is supplied to the dummy upper electrode, and
a first main electrode potential or a gate potential is supplied to the dummy lower electrode.

36. The semiconductor device according to claim 32, wherein a thickness d5 of the gate trench insulating film in contact with the lower electrode is set to be thicker than a thickness d4 of the gate trench insulating film in contact with the upper electrode.

37. The semiconductor device according to claim 35, wherein
a thickness of the gate trench insulating film in contact with the lower electrode is set to be thicker than a thickness of the gate trench insulating film in contact with the upper electrode, and
a thickness of the dummy trench insulating film in contact with the dummy lower electrode is set to be thicker than a thickness of the dummy trench insulating film in contact with the dummy upper electrode.

38. The semiconductor device according to claim 32, wherein a thickness d6 of the intermediate insulating film is set to be thicker than a thickness d4 of the gate trench insulating film.

39. The semiconductor device according to claim 35, wherein
a thickness of the intermediate insulating film is set to be thicker than a thickness of the gate trench insulating film, and
a thickness of the dummy intermediate insulating film is set to be thicker than a thickness of the dummy trench insulating film.

40. A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a third semiconductor layers that has a first conductivity type, is provided on an upper layer portion of the second semiconductor layer, and is electrically connected to the first main electrode;
a fourth semiconductor layer that has a second conductivity type and is provided on the upper layer portion of the second semiconductor layer in parallel with the third semiconductor layer;
a plurality of trench gates that are provided so as to penetrate the third semiconductor layer, the fourth semiconductor layer, and the second semiconductor layer from the first main surface in a thickness direction and reach into the first semiconductor layer; and
a trench that is provided so as to intersect with the trench gates in a region in which the fourth semiconductor layer is provided, wherein
the trench gate includes
a gate trench insulating film that covers an inner surface of a trench,
a gate trench electrode that is provided in the trench via the gate trench insulating film, and
an upper insulating film 11c that covers the gate trench electrode,
the fourth semiconductor layer is provided on the upper layer portion of the second semiconductor layer in a state where the second semiconductor layer is removed to a predetermined depth,
the trench gate is provided so as to have a partial step such that the upper insulating film has the same depth as an upper surface of the fourth semiconductor layer on a bottom surface of the trench,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2, and
in a case where a position of one end portion of the third semiconductor layer in the first direction is defined as a position E3 and a position of an end portion of the fourth semiconductor layer included in the trench in the first direction is defined as a position E6, a distance from the position E3 to the position E6 is set to be 0.5 μm or shorter.

41. The semiconductor device according to claim 40, further comprising:
a fifth semiconductor layer that has a first conductivity type and is provided on a lower portion of the second semiconductor layer; and
a sixth semiconductor layer that has a second conductivity type and is provided on a lower portion of the fifth semiconductor layer, wherein
the fourth semiconductor layer included in the trench reaches an inner portion of the sixth semiconductor layer.

42. A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is provided so as to penetrate at least the second semiconductor layer and reach an inner portion of the first semiconductor layer, and the trench gate is provided so as to have a partial step such that the upper insulating film has the same depth as a bottom surface of the trench,
the trench is covered with a seventh semiconductor layer that has a second conductivity type at least in the inner portion of the first semiconductor layer,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2.

43. The semiconductor device according to claim 42, further comprising:
a fifth semiconductor layer that has a first conductivity type and is provided on a lower portion of the second semiconductor layer; and
a sixth semiconductor layer that has a second conductivity type and is provided on a lower portion of the fifth semiconductor layer, wherein
the trench penetrates the second semiconductor layer, the fifth semiconductor layer, and the sixth semiconductor layer and reaches an inner portion of the first semiconductor layer, and
at least the bottom surface of the trench in the inner portion of the first semiconductor layer is covered with the seventh semiconductor layer.

44. The semiconductor device according to claim 42, wherein
a fourth semiconductor layer that has a second conductivity type is provided in a surface of the trench, and
side surfaces and a bottom surface of the fourth semiconductor layer on the surface of the trench in the inner portion of the first semiconductor layer are covered with the seventh semiconductor layer.

45. The semiconductor device according to claim 42, wherein the seventh semiconductor layer is set to have a higher impurity concentration than the second semiconductor layer.

46. A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is formed by removing the second semiconductor layer and the first semiconductor layer to a predetermined depth and embedding a trench electrode in the trench except for an upper portion of the trench,
the trench electrode includes an electrode portion that is embedded in the trench via a trench insulating film and a trench upper insulating film that covers the electrode portion,
the trench gate is provided so as to have a partial step such that an upper surface of the upper insulating film in the trench has the same depth as an upper surface of the trench upper insulating film of the trench electrode,
the gate trench electrode intersects with the electrode portion in the trench to form a mesh shape in a plan view,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2.

47. The semiconductor device according to claim 46, wherein a width L1 of the trench gate in a cross-sectional view in a second direction intersecting with the first direction and a width L3 of the trench in a cross-sectional view in the first direction are set such that one of the width L1 and the width L3 is wider than the other.

48. The semiconductor device according to claim 47, wherein in the gate trench and the trench, a trench depth of one having a wider width is set to be deeper than a trench depth of the other having a narrower width.

49. The semiconductor device according to claim 46, wherein a width W3 of the trench in a cross-sectional view in the first direction is set to be wider than a width W4 of the trench electrode in a cross-sectional view in the first direction.

50. The semiconductor device according to claim 46, wherein a thickness d7 of the trench upper insulating film of the trench electrode is set to be thicker than a thickness d8 of the upper insulating film of the trench gate.

51. A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is formed by removing the second semiconductor layer and the first semiconductor layer to a predetermined depth and embedding a trench electrode in the trench except for an upper portion of the trench,
the trench electrode includes an electrode portion that is embedded in the trench via a trench insulating film and a trench upper insulating film that covers the electrode portion,
the trench gate is provided so as to have a partial step such that an upper surface of the upper insulating film in the trench has the same depth as an upper surface of the trench upper insulating film of the trench electrode,
the gate trench electrode intersects with the electrode portion in the trench to form a mesh shape in a plan view,
the upper portion of the trench forms a contact portion,
a fourth semiconductor layer that has a second conductivity type is provided on a side surface of the contact portion, and a portion of the fourth semiconductor layer that is deeper than the third semiconductor layer forms a side contact portion,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer,
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2, and
in a case where a position of one end portion of the third semiconductor layer in the first direction is defined as a position E3, and
in a case where a position of an end portion of the fourth semiconductor layer in the first direction that faces the position of the end portion of the third semiconductor layer is defined as a position E5, a distance from the position E3 to the position E5 is set to be 0.5 μm or shorter.

52. A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is formed by removing the second semiconductor layer and the first semiconductor layer to a predetermined depth and embedding a trench electrode in the trench except for an upper portion of the trench,
the trench electrode includes an electrode portion that is embedded in the trench via a trench insulating film and a trench upper insulating film that covers the electrode portion,
the trench gate is provided so as to have a partial step such that an upper surface of the upper insulating film in the trench has the same depth as an upper surface of the trench upper insulating film of the trench electrode,
the gate trench electrode intersects with the electrode portion in the trench to form a mesh shape in a plan view,
the upper portion of the trench forms a contact portion,
a portion of a side surface of the trench is covered with a seventh semiconductor layer that has a second conductivity type at least in the inner portion of the first semiconductor layer,
the seventh semiconductor layer and a side surface of the second semiconductor layer provided on the seventh semiconductor layer form a side contact portion SC1,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer, and
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2.

53. The semiconductor device according to claim 52, wherein a fourth semiconductor layer that has a second conductivity type is provided in a surface of the seventh semiconductor layer and on a surface of the side surface of the second semiconductor layer provided on the seventh semiconductor layer.

54. The semiconductor device according to claim 52, wherein
a fourth semiconductor layer that has a second conductivity type is provided on a surface of the seventh semiconductor layer and in a surface of the side surface of the second semiconductor layer provided on the seventh semiconductor layer, and
the fourth semiconductor layer is provided such that the fourth semiconductor layer is covered with the seventh semiconductor layer in the surface of the seventh semiconductor layer.

55. A semiconductor device in which a transistor is formed on a semiconductor substrate having a first main surface and a second main surface, the semiconductor device comprising:
a first main electrode that is electrically connected to the first main surface;
a second main electrode that is electrically connected to the second main surface;
a first semiconductor layer that has a first conductivity type;
a second semiconductor layer that has a second conductivity type and is provided on an upper layer portion of the first semiconductor layer;
a plurality of third semiconductor layers that have a first conductivity type, are selectively provided on an upper layer portion of the second semiconductor layer, and are electrically connected to the first main electrode;
a plurality of trench gates that are provided so as to penetrate the third semiconductor layer and the second semiconductor layer from the first main surface in a thickness direction and reach into the first semiconductor layer; and
a trench that is provided between the third semiconductor layers which are provided to be parallel to each other, wherein
the trench gate includes
a gate trench insulating film that covers an inner surface of a trench,
a gate trench electrode that is provided in the trench via the gate trench insulating film, and
an upper insulating film that covers the gate trench electrode,
the trench is provided by removing the second semiconductor layer to a predetermined depth and providing the trench gate so as to have a partial step such that the upper insulating film has the same depth as a bottom surface of the trench,
the gate trench electrode has a comb shape in which a recess portion that is recessed toward the first semiconductor layer and a protrusion portion that protrudes toward the first main electrode are alternately provided in a cross-sectional view along a first direction which is an extending direction of the gate trench electrode,
an upper end of the protrusion portion is located at a position higher than a lower end of the third semiconductor layer,
a lower end of the recess portion is located at a position lower than the lower end of the third semiconductor layer,
in a case where a lower end position of the second semiconductor layer is defined as a position E1 and a lower end position of the recess portion is defined as a position E2, in a case where a distance from the first main surface to the position E1 is defined as a distance E1d and a distance from the first main surface to the position E2 is defined as a distance E2d, in a case where the distance E1d is longer than the distance E2d, in a case where an area of the second semiconductor layer in a range from the lower end of the third semiconductor layer to the position E1 is defined as an area S1, and in a case where an area of the recess portion of the gate trench electrode formed in a region of the area S1 is defined as an area S2,
a gate capacitance ratio is linearly controlled by changing the area S2,
the third semiconductor layer is provided over the entire upper layer portion of the second semiconductor layer between the trenches that are provided to be parallel to each other, and
the second semiconductor layer includes a fourth semiconductor layer that has a second conductivity type and is provided at least on a bottom portion of the trench.

56. The semiconductor device according to claim 55, further comprising
a fifth semiconductor layer that has a first conductivity type and is provided on a lower portion of the second semiconductor layer.

57. A power conversion apparatus comprising:
a main conversion circuit that includes the semiconductor device according to claim 1, converts input power, and outputs the converted power;
a driving circuit that outputs a driving signal for driving the semiconductor device to the semiconductor device; and
a control circuit that outputs a control signal for controlling the driving circuit to the driving circuit.

58. A power conversion apparatus comprising:
a main conversion circuit that includes the semiconductor device according to claim 20, converts input power, and outputs the converted power;
a driving circuit that outputs a driving signal for driving the semiconductor device to the semiconductor device; and
a control circuit that outputs a control signal for controlling the driving circuit to the driving circuit.

59. A power conversion apparatus comprising:
a main conversion circuit that includes the semiconductor device according to claim 22, converts input power, and outputs the converted power;
a driving circuit that outputs a driving signal for driving the semiconductor device to the semiconductor device; and
a control circuit that outputs a control signal for controlling the driving circuit to the driving circuit.

60. A power conversion apparatus comprising:
a main conversion circuit that includes the semiconductor device according to claim 32, converts input power, and outputs the converted power;
a driving circuit that outputs a driving signal for driving the semiconductor device to the semiconductor device; and
a control circuit that outputs a control signal for controlling the driving circuit to the driving circuit.

61. A power conversion apparatus comprising:
a main conversion circuit that includes the semiconductor device according to claim 40, converts input power, and outputs the converted power;
a driving circuit that outputs a driving signal for driving the semiconductor device to the semiconductor device; and
a control circuit that outputs a control signal for controlling the driving circuit to the driving circuit.

62. A power conversion apparatus comprising:
a main conversion circuit that includes the semiconductor device according to claim 42, converts input power, and outputs the converted power;
a driving circuit that outputs a driving signal for driving the semiconductor device to the semiconductor device; and
a control circuit that outputs a control signal for controlling the driving circuit to the driving circuit.

63. A power conversion apparatus comprising:
a main conversion circuit that includes the semiconductor device according to claim 46, converts input power, and outputs the converted power;
a driving circuit that outputs a driving signal for driving the semiconductor device to the semiconductor device; and
a control circuit that outputs a control signal for controlling the driving circuit to the driving circuit.

64. A power conversion apparatus comprising:
a main conversion circuit that includes the semiconductor device according to claim 51, converts input power, and outputs the converted power;
a driving circuit that outputs a driving signal for driving the semiconductor device to the semiconductor device; and
a control circuit that outputs a control signal for controlling the driving circuit to the driving circuit.

65. A power conversion apparatus comprising:
a main conversion circuit that includes the semiconductor device according to claim 52, converts input power, and outputs the converted power;
a driving circuit that outputs a driving signal for driving the semiconductor device to the semiconductor device; and
a control circuit that outputs a control signal for controlling the driving circuit to the driving circuit.

66. A power conversion apparatus comprising:
a main conversion circuit that includes the semiconductor device according to claim 55, converts input power, and outputs the converted power;
a driving circuit that outputs a driving signal for driving the semiconductor device to the semiconductor device; and
a control circuit that outputs a control signal for controlling the driving circuit to the driving circuit.
